(19) United States
(12) Patent Application Publication
(10) Pub. No.: US 2026/0182134 A1
(43) Pub. Date: Jun. 25, 2026

(54) CHARGE-TRANSPORTING COMPOSITION

(71) Applicant: NISSAN CHEMICAL CORPORATION, Tokyo (JP)

(72) Inventors: Ryoichi ASHIZAWA, Funabashi-shi (JP); Shinichi MAEDA, Funabashi-shi (JP); Shun YAMAGUCHI, Funabashi-shi (JP)

(73) Assignee: NISSAN CHEMICAL CORPORATION, Tokyo (JP)

(21) Appl. No.: 19/124,057

(22) PCT Filed: Oct. 23, 2023
(86) PCT No.: PCT/JP2023/038116

§ 371 Date: Apr. 24, 2025

(30) Foreign Application Priority Data
Oct. 25, 2022 (JP) 2022-170503

(51) Int. Cl. H10K 30/20

(52) U.S. Cl. CPC H10K 30/20

(57) ABSTRACT

As a charge-transporting composition which can greatly improve the dark current properties of an organic photoelectric conversion element when the composition is used in the element, a charge-transporting composition for forming a charge-transporting thin film in an organic photoelectric conversion element is provided. The charge-transporting composition comprises a charge-transporting substance and an organic solvent, in which the charge-transporting substance comprises at least one polyimide-based polymer selected from the group consisting of a polyimide precursor produced from a diamine component having a structure represented by formula (1) or (2) and a tetracarboxylic acid component, an ester of the polyimide precursor, and an imidized product of the polyimide precursor.

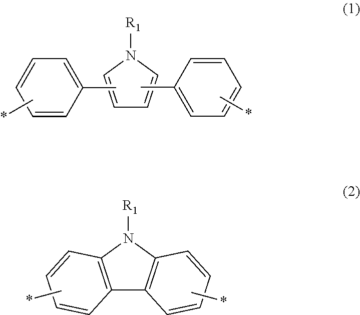

(In the formulae, R¹ represents a hydrogen atom or a monovalent organic group; * indicates a position at which another group is bound; and an arbitrary hydrogen atom forming a benzene ring may be substituted by a monovalent organic group.)

### TECHNICAL FIELD

The present invention relates to a charge transporting composition. More particularly, the invention relates to a charge transporting composition for forming a charge transporting thin film that can be used in an organic photoelectric conversion device.

### BACKGROUND ART

Organic photoelectric conversion devices are devices which use an organic semiconductor to convert light energy into electrical energy. Examples of such devices include optical sensors, organic solar cells and perovskite solar cells.

Hitherto used optical sensors include photomultiplier tubes that utilize the photoelectric effect and photodiodes that utilize a pn junction. Applications are not limited only to optical sensing, with optical sensors being widely used also as solid-state image sensors, including consumer-grade image sensors, and in on-board vehicular applications.

In recent years, organic optical sensors which use organic materials in the photoelectric conversion layer to achieve size and weight reductions, low cost and designability are being developed and are garnering attention.

Organic optical sensors are constructed of, for example, a photoelectric conversion layer, charge (hole, electron) collecting layers, electrodes (anode, cathode) and an optical filter.

Of these, the photoelectric conversion layer and the charge collecting layers are generally formed by vacuum deposition. However, drawbacks of vacuum deposition include the complexity associated with mass production processes, the high cost of the equipment and the efficiency of material utilization.

There are also cases in which, for these reasons, a water-dispersible polymeric organic conductive material such as PEDOT/PSS is used as the coating material for the hole collecting layer. However, because this is a water dispersion, complete removal of the water and moisture re-absorption control are difficult, allowing deterioration of the device to accelerate.

Moreover, because the solids in an aqueous PEDOT/PSS dispersion have a tendency to agglomerate, coating film defects readily arise and clogging or corrosion of the coating equipment tends to occur, in addition to which the heat resistance is inadequate. Hence, the use of this material in mass production presents a number of challenges.

Also, in optical sensors, given the need to maximize the light-receiving characteristics, an external electrical field is commonly applied (see Patent Document 1).

With the application of an external electrical field, one can expect improvements in the light sensitivity and the response rate, but hole and electron injection from the electrodes arises, along with which the dark current increases.

Because this increase in the dark current causes a decrease in the detection sensitivity, in order to fabricate a device having a high light sensitivity, it is important to suppress the dark current while achieving a high photoelectric conversion efficiency.

An organic solar cell is a solar cell in which an organic compound is used as an active layer or a charge transporting substance. The dye-sensitized solar cells developed by M. Grätzel and the organic thin-film solar cells developed by C. W. Tang are well known (Non-Patent Documents 1 and 2).

Because both have characteristics differing from the inorganic solar cells that currently predominate, such as the fact that they are thin, lightweight films which can be made flexible and the fact that roll-to-roll production is possible, they are expected to lead to the creation of new markets.

Also, organic thin-film solar cells, when compared with existing photoelectric conversion devices that use silicon-based materials, exhibit a high photoelectric conversion efficiency even under low levels of illumination, enable thinner devices and smaller pixels to be achieved and are capable of having also the attributes of a color filter, making them of interest not only in solar cell applications, but also in image sensors and other optical sensors (Patent Documents 2 and 3, Non-Patent Document 3).

In addition, recently reported research findings indicate that solar cells which use, as compounds having a perovskite crystal structure (referred to below as “perovskite semiconductor compounds”), metal halides are capable of achieving a relatively high photoelectric conversion efficiency. For example, Patent Document 4 describes a photoelectric conversion device and a solar cell which have a perovskite semiconductor compound-containing active layer.

Organic photoelectric conversion devices are constructed of, for example, an active layer (photoelectric conversion layer), charge (hole, electron) collecting layers and electrodes (anode, cathode). Of these, the role of the hole collecting layer is to extract holes that have formed in the active layer to the electrodes. This can be effectively carried out by making the energy barrier between the active layer and the hole collecting layer small.

### PRIOR ART DOCUMENTS

### Patent Documents

Patent Document 1: JP-A 2002-83946
Patent Document 2: JP-A 2003-234460
Patent Document 3: JP-A 2008-258474
Patent Document 4: JP-A 2016-178193

### Non-Patent Documents

Non-Patent Document 1: Nature, Vol. 353, 737-740 (1991)
Non-Patent Document 2: Appl. Phys. Lett., Vol. 48, 183-185 (1986)
Non-Patent Document 3: Scientific Reports, Vol. 5: 7708, 1-7 (2015)

### SUMMARY OF INVENTION

### Technical Problem

The present invention was arrived at in light of the above circumstances. An object of the invention is to provide a charge transporting composition which is suitable for forming a charge transporting thin film in a photoelectric conversion device and which, particularly when used as the hole collecting layer in an optical sensor, is able to greatly enhance the dark current properties of the resulting device.

### Solution to Problem

In the course of intensive investigations aimed at achieving the above object, the inventors have found that a charge transporting composition which includes a charge transporting substance and an organic solvent, the charge transporting substance being a polyimide polymer obtained using a diamine component having a specific structure, is suitable for forming a charge transporting thin film in an organic photoelectric conversion device and, particularly when used as the hole collecting layer in an optical sensor, is able to greatly enhance the dark current properties of the resulting device. This discovery ultimately led to the present invention. The gist of the invention, which is based on these findings, is described below.

Accordingly, the invention provides the following charge transporting composition.
1. A charge transporting composition for forming a charge transporting thin film in an organic photoelectric conversion device,
which composition includes a charge transporting substance and an organic solvent, wherein the charge transporting substance includes at least one type of polyimide polymer selected from the group consisting of polyimide precursors obtained from a diamine component having a structure of formula (1) or (2) below

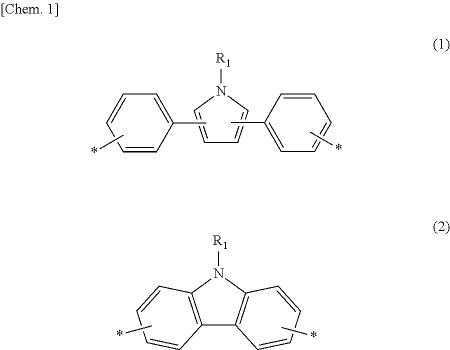

(wherein R¹ is a hydrogen atom or a monovalent organic group, _{*} represents a site that bonds with another group, and any hydrogen atom forming the benzene ring may be substituted with a monovalent organic group) and a tetracarboxylic acid component, esters of the polyimide precursor, and imidization products of the polyimide precursor.
2. The charge transporting composition of 1 above, wherein R¹ is a hydrogen atom, an alkyl group of 1 to 5 carbon atoms, a fluoroalkyl group of 1 to 5 carbon atoms or a tert-butoxycarbonyl group.
3. The charge transporting composition of 1 or 2 above, further including a charge transporting substance other than the polyimide polymer.
4. The charge transporting composition of 3 above, wherein the other charge transporting substance is of at least one type selected from the group consisting of polythiophene derivatives and polyaniline derivatives.
5. The charge transporting composition of 4 above, wherein the other charge transporting substance is of at least one type selected from the group consisting of polythiophene derivatives containing recurring units of formula (3) below and polyaniline derivatives containing recurring units of formula (4) below

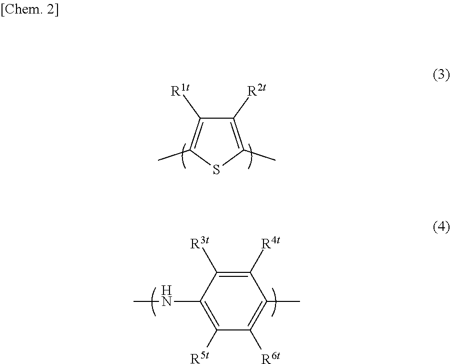

(wherein R^{1t} and R^{2t} are each independently a hydrogen atom, an alkyl group of 1 to 40 carbon atoms, a fluoroalkyl group of 1 to 40 carbon atoms, an alkoxy group of 1 to 40 carbon atoms, a fluoroalkoxy group of 1 to 40 carbon atoms, an aryloxy group of 6 to 20 carbon atoms, —O—[Z—O]ₚ—R^{e}, a sulfonic acid group, a sulfonate group or a sulfonic ester group, or R² and R³ are mutually bonded, forming —O—Y—O— in which Y is an alkylene group of 1 to 40 carbon atoms that may include an ether bond and may be substituted with a sulfonic group, a sulfonate group or a sulfonic ester group; Z is an alkylene group of 1 to 40 carbon atoms which may be substituted with a halogen atom, p is an integer of 1 or more, and R^{e} is a hydrogen atom, an alkyl group of 1 to 40 carbon atoms, a fluoroalkyl group of 1 to 40 carbon atoms or an aryl group of 6 to 20 carbon atoms; and
   R^{3t} to R^{6t} are each independently a hydrogen atom, an alkyl group of 1 to 40 carbon atoms, a fluoroalkyl group of 1 to 40 carbon atoms, an alkoxy group of 1 to 40 carbon atoms, a fluoroalkoxy group of 1 to 40 carbon atoms, a hydroxyl group, a carboxyl group, a sulfonic group, a sulfonate group or a sulfonic ester group).
6. The charge transporting composition of any of 1 to 5 above for use as a hole collecting layer in an organic photoelectric conversion device.
7. The charge transporting composition of 6 above, wherein the organic photoelectric conversion device is an organic thin-film solar cell, a perovskite solar cell, a dye-sensitized solar cell or an optical sensor.
8. A charge transporting thin film obtained from the charge transporting composition of any one of 1 to 7 above.
9. The charge transporting thin film of 8 above, which charge transporting thin film is a hole collecting layer in an organic photoelectric conversion device.
10. An organic photoelectric conversion device having the charge transporting thin film of 8 or 9 above.
11. The organic photoelectric conversion device of 10 above, which organic photoelectric conversion device is an organic thin film solar cell, a perovskite solar cell, a dye-sensitized solar cell or an optical sensor.

### Advantageous Effects of Invention

By using the charge transporting composition of the invention in an organic photoelectric conversion device, the dark current properties of the resulting device are greatly enhanced and light leakage from neighboring pixels, etc. is suppressed, enabling an optical sensor having an excellent signal-to-noise ratio (S/N) to be provided. That is, the inventive charge transporting composition and image sensor make it possible to provide, in response to the need in recent years for higher performance in image sensors, an organic image sensor in which a residual image does not readily arise and which is thus capable of producing a clean, sharp image.

### DESCRIPTION OF EMBODIMENTS

The invention is described below in greater detail.

The charge transporting composition of the invention is a charge transporting composition for forming a charge transporting thin film in an organic photoelectric conversion device and is characterized by including a charge transporting substance and an organic solvent, which charge transporting substance includes at least one type of polyimide polymer selected from the group consisting of polyimide precursors obtained from a diamine component having a structure of formula (1) or (2) below and a tetracarboxylic acid component, esters of the polyimide precursor, and imidization products of the polyimide precursor.

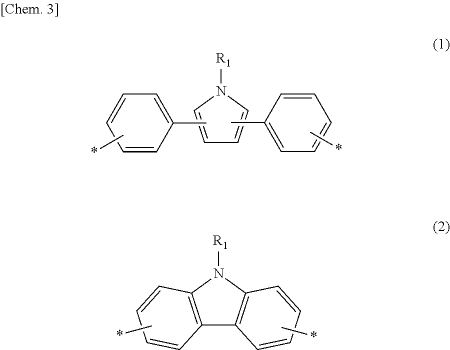

In the formulas, R¹ is a hydrogen atom or a monovalent organic group, _{*} is a site that bonds with an amino group or with another group, and any hydrogen atom forming the benzene ring may be substituted with a monovalent organic group.

The diamine having a structure of formula (1) or (2) is sometimes referred to below as “the specific diamine.” The polymer of the invention in which the specific diamine has been included is sometimes referred to as “the specific polymer.”

### <Specific Diamine>

The specific diamine has a structure of formula (1) or (2) below.

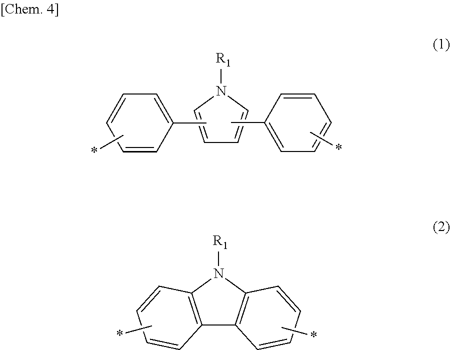

In formulas (1) and (2), R¹ represents a hydrogen atom or a monovalent organic group, _{*} represents a site that bonds with an amino group or with another group, and any hydrogen atom forming the benzene ring may be substituted with a monovalent organic group. The monovalent organic group here is exemplified by alkyl groups of 1 to 10 carbon atoms, alkenyl groups of 2 to 10 carbon atoms, alkoxy groups of 1 to 10 carbon atoms, fluoroalkyl groups of 1 to 10 carbon atoms, fluoroalkenyl groups of 2 to 10 carbon atoms, fluoroalkoxy groups of 1 to 10 carbon atoms and the tert-butoxycarbonyl group.

Examples of alkyl groups of 1 to 10 carbon atoms include methyl, ethyl, n-propyl, isopropyl, n-butyl, i-butyl, s-butyl, t-butyl, n-pentyl, n-hexyl, n-heptyl, n-octyl, n-nonyl and n-decyl groups.

Examples of alkenyl groups of 2 to 10 carbon atoms include ethenyl, n-1-propenyl, n-2-propenyl, 1-methylethenyl, n-1-butenyl, n-2-butenyl, n-3-butenyl, 2-methyl-1-propenyl, 2-methyl-2-propenyl, 1-ethylethenyl, 1-methyl-1-propenyl, 1-methyl-2-propenyl, n-1-pentenyl and n-1-decenyl groups.

Examples of alkoxy groups of 1 to 10 carbon atoms include methoxy, ethoxy, n-propoxy, i-propoxy, n-butoxy, i-butoxy, s-butoxy, t-butoxy, n-pentoxy, n-hexyloxy, n-heptyloxy, n-octyloxy, n-nonyloxy and n-decyloxy groups.

The fluoroalkyl groups of 1 to 10 carbon atoms are not particularly limited so long as they are alkyl groups of 1 to 10 carbon atoms in which at least one hydrogen atom on a carbon atom is substituted with a fluorine atom. Specific examples include fluoromethyl, difluoromethyl, perfluoromethyl, 1-fluoroethyl, 2-fluoroethyl, 1,2-difluoroethyl, 1,1-difluoroethyl, 2,2-difluoroethyl, 1,1,2-trifluoroethyl, 1,2,2-trifluoroethyl, 2,2,2-trifluoroethyl, 1,1,2,2-tetrafluoroethyl, 1,2,2,2-tetrafluoroethyl, perfluoroethyl, 1-fluoropropyl, 2-fluoropropyl, 3-fluoropropyl, 1,1-difluoropropyl, 1,2-difluoropropyl, 1,3-difluoropropyl, 2,2-difluoropropyl, 2,3-difluoropropyl, 3,3-difluoropropyl, 1,1,2-trifluoropropyl, 1,1,3-trifluoropropyl, 1,2,3-trifluoropropyl, 1,3,3-trifluoropropyl, 2,2,3-trifluoropropyl, 2,3,3-trifluoropropyl, 3,3,3-trifluoropropyl, 1,1,2,2-tetrafluoropropyl, 1,1,2,3-tetrafluoropropyl, 1,2,2,3-tetrafluoropropyl, 1,3,3,3-tetrafluoropropyl, 2,2,3,3-tetrafluoropropyl, 2,3,3,3-tetrafluoropropyl, 1,1,2,2,3-pentafluoropropyl, 1,2,2,3,3-pentafluoropropyl, 1,1,3,3,3-pentafluoropropyl, 1,2,3,3,3-pentafluoropropyl, 2,2,3,3,3-pentafluoropropyl, perfluoropropyl, perfluorobutyl, perfluoropentyl, perfluorohexyl, perfluoroheptyl and perfluorooctyl groups.

The fluoroalkenyl groups of 2 to 10 carbon atoms are not particularly limited so long as they are fluoroalkenyl groups of 2 to 10 carbon atoms in which at least one hydrogen atom on a carbon atom is substituted with a fluorine atom. Specific examples include 2-fluoroethenyl, 2,2-difluoroethenyl, 2-fluoro-2-propenyl, 3,3-difluoro-2-propenyl, 2,3-difluoro-2-propenyl, 3,3-difluoro-2-methyl-2-propenyl, 3-fluoro-2-butenyl, perfluorovinyl, perfluoropropenyl and perfluorobutenyl groups.

The fluoroalkoxy groups of 1 to 10 carbon atoms are not particularly limited so long as they are alkoxy groups of 1 to 10 carbon atoms in which at least one hydrogen atom on a carbon atom is substituted with a fluorine atom. Specific examples include fluoromethoxy, difluoromethoxy, perfluoromethoxy, 1-fluoroethoxy, 2-fluoroethoxy, 1,2-difluoroethoxy, 1,1-difluoroethoxy, 2,2-difluoroethoxy, 1,1,2-trifluoroethoxy, 1,2,2-trifluoroethoxy, 2,2,2-trifluoroethoxy, 1,1,2,2-tetrafluoroethoxy, 1,2,2,2-tetrafluoroethoxy, perfluoroethoxy, 1-fluoropropoxy, 2-fluoropropoxy, 3-fluoropropoxy, 1,1-difluoropropoxy, 1,2-difluoropropoxy, 1,3-difluoropropoxy, 2,2-difluoropropoxy, 2,3-difluoropropoxy, 3,3-difluoropropoxy, 1,1,2-trifluoropropoxy, 1,1,3-trifluoropropoxy, 1,2,3-trifluoropropoxy, 1,3,3-trifluoropropoxy, 2,2,3-trifluoropropoxy, 2,3,3-trifluoropropoxy, 3,3,3-trifluoropropoxy, 1,1,2,2-tetrafluoropropoxy, 1,1,2,3-tetrafluoropropoxy, 1,2,2,3-tetrafluoropropoxy, 1,3,3,3-tetrafluoropropoxy, 2,2,3,3-tetrafluoropropoxy, 2,3,3,3-tetrafluoropropoxy, 1,1,2,2,3-pentafluoropropoxy, 1,2,2,3,3-pentafluoropropoxy, 1,1,3,3,3-pentafluoropropoxy, 1,2,3,3,3-pentafluoropropoxy, 2,2,3,3,3-pentafluoropropoxy and perfluoropropoxy groups.

R¹ above is preferably a hydrogen atom, an alkyl group of 1 to 3 carbon atoms, an alkenyl group of 2 or 3 carbon atoms, an alkoxy group of 1 to 3 carbon atoms, a fluoroalkyl group of 1 to 3 carbon atoms, a fluoroalkenyl group of 2 or 3 carbon atoms, a fluoroalkoxy group of 1 to 3 carbon atoms or a tert-butoxycarbonyl group; more preferably a hydrogen atom or an alkyl group of 1 to 3 carbon atoms, and even more preferably a hydrogen atom or a methyl group.

In the above formula (1) structure, in terms of charge transportability, it is preferable for the bonding sites of the benzene rings on the pyrrole ring to be, as indicated in formula (1-1) below, the carbon atoms adjoining the nitrogen atom on the pyrrole ring.

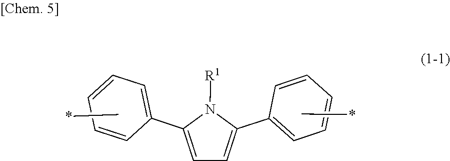

Preferred examples of diamines having a structure of above formula (1) include diamines represented by formula (1-2) below.

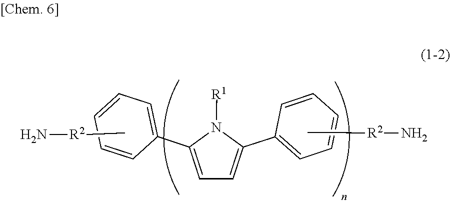

In formula (1-2), R¹ is the same as in formula (1). The two occurrences of R² are each independently a single bond or a structure of formula (1-3) below. As in the case of formula (1), any hydrogen atom forming the benzene ring may be substituted with a monovalent organic group.

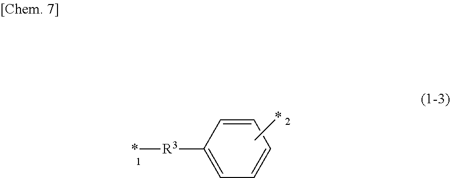

In formula (1-3), R³ is a single bond or a divalent organic group selected from the group consisting of —O—, —COO—, —OCO—, —(CH₂)ᵢ—, —O(CH₂)ⱼO—, —CONH—, —NHCO—, —CON(CH₃)—, —N(CH₃)CO— and —NR¹—. Here, the letter ‘i’ represents an integer from 1 to 14, and the letter ‘j’ represents an integer from 1 to 14. R¹ is the same as in formula (1). Of these, from the standpoint of charge transportability, R³ is preferably a single bond, —O—, —COO—, —OCO—, —CONH—, —NHCO— or —N(CH₃)—. Also _{*}1 represents a site that bonds with the benzene ring in formula (2), and _{*}2 represents a site that bonds with the amino group in formula (1-2). The subscript ‘n’ in formula (1-2) is an integer from 1 to 3, and is preferably 1 or 2.

Specific, non-limiting, examples of the compound of above formula (1-2) include the compounds of formulas (1-2-1) to (1-2-17) below. Of these, from the standpoint of charge transportability, the compounds of formulas (1-2-1), (1-2-2), (1-2-3), (1-2-5), (1-2-8), (1-2-9), (1-2-10), (1-2-11), (1-2-12), (1-2-13), (1-2-14), (1-2-15), (1-2-16) and (1-2-17) are preferred. Compounds of formulas (1-2-1), (1-2-2), (1-2-3), (1-2-11), (1-2-12), (1-2-13), (1-2-14), (1-2-15), (1-2-16) and (1-2-17) are more preferred. In formulas (1-2-6) and (1-2-7) below, x1 is an integer from 1 to 14 and Boc stands for an tert-butoxycarbonyl group.

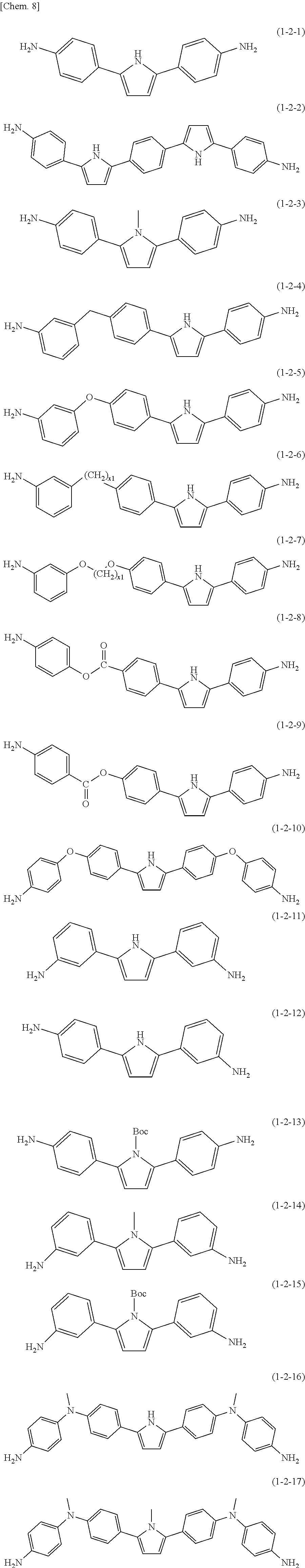

In formula (2), regarding the amino or other group bonding sites to the carbazole, from the standpoint of steric hindrance, bonding in the manner of formula (2-1) is preferred.

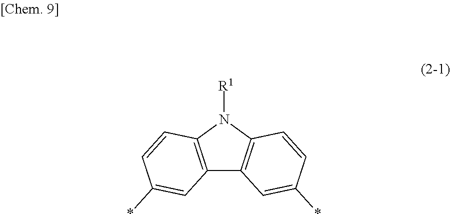

In formula (2-1), R¹ is as defined above.

Examples of the specific diamine above include diamines of formulas (2-2) to (2-7) below. In particular, from the standpoint of charge transportability, diamines of formulas (2-3) to (2-7) are preferred, and diamines of formulas (2-4) to (2-7) are more preferred.

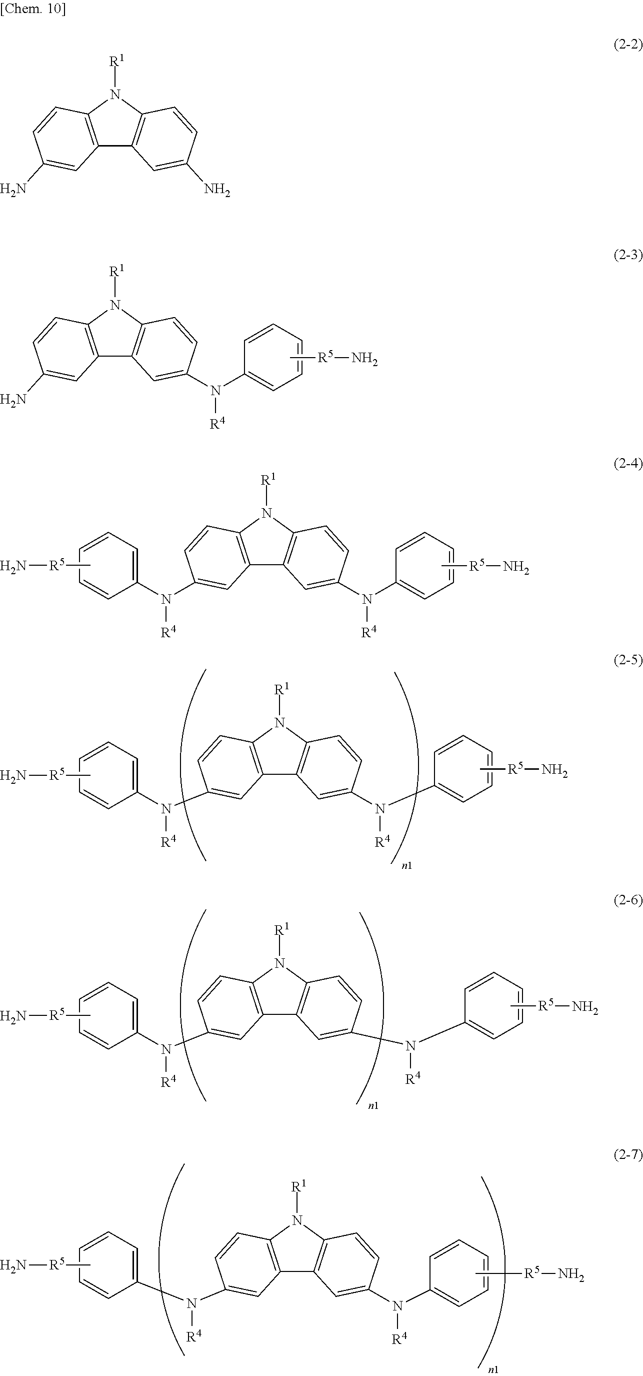

In the above formulas, R¹ is defined in the same way as in the case of formula (1), each R⁴ is independently a hydrogen atom or a monovalent organic group, each R⁵ is independently a single bond or a divalent organic group, and each n1 is independently 2 or 3. Any hydrogen atom on the benzene ring may be substituted with a monovalent organic group.

The monovalent organic group in R⁴ is exemplified by the same groups as mentioned above for R¹. R⁴ is preferably a hydrogen atom, an alkyl group of 1 to 3 carbon atoms, an alkenyl group of 2 or 3 carbon atoms, an alkoxy group of 1 to 3 carbon atoms, a fluoroalkyl group of 1 to 3 carbon atoms, a fluoroalkenyl group of 2 or 3 carbon atoms, a fluoroalkoxy group of 1 to 3 carbon atoms or a tert-butoxycarbonyl group; more preferably a hydrogen atom or an alkyl group of 1 to 3 carbon atoms; and even more preferably a hydrogen atom or a methyl group.

The divalent organic group in R⁵ is exemplified by groups having the structure of formula (2-8) below.

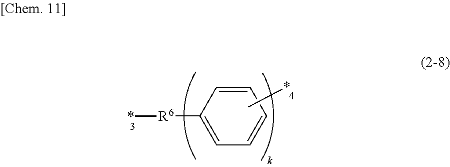

In the formula, R⁶ is a single bond or a divalent organic group selected from the group consisting of —O—, —COO—, —OCO—, —(CH₂)ᵣ—, —O(CH₂)ₛO—, —NR—, —CONR— and —NRCO—; and k is an integer from 1 to 5. Also, R represents a hydrogen or a monovalent organic group, r is an integer from 1 to 5, and s is an integer from 1 to 5. The above monovalent organic group is preferably an alkyl group of 1 to 3 carbon atoms, and more preferably a methyl group. Also, _{*}3 represents a site that bonds with a benzene ring in formulas (2-5) to (2-7), and _{*}4 represents a site that bonds with an amino group in formulas (2-5) to (2-7).

Examples of the specific diamine include, but are not limited to, the diamines of formulas (2-1-1) to (2-1-19) below. Of these, from the standpoint of charge transportability, the diamines of formulas (2-1-1) to (2-1-7) and (2-1-10) to (2-1-17) are preferred, and those of formulas (2-1-1) to (2-1-7) and (2-1-15) to (2-1-17) are more preferred. In the following formulas, x2 is an integer from 1 to 14.

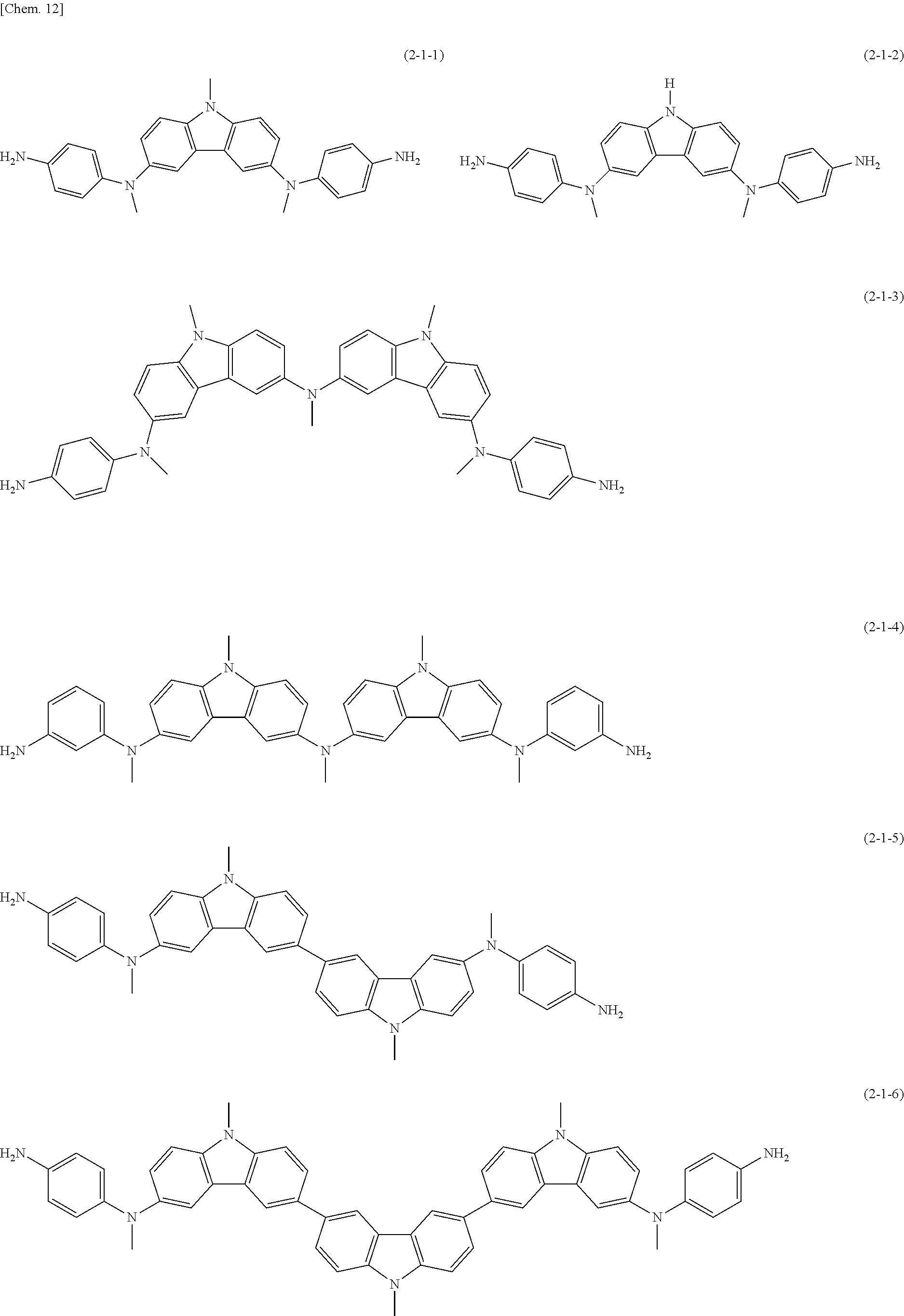 [SMILES: CN(c1ccc(N)cc1)c1ccc2c(c1)c1cc(N(C)c3ccc(N)cc3)ccc1n2C ; CN(c1ccc(N)cc1)c1ccc2[nH]c3ccc(N(C)c4ccc(N)cc4)cc3c2c1 ; CN(c1ccc(N)cc1)c1ccc2c(c1)c1cc(N(C)c3ccc4c(c3)c3cc(N(C)c5ccc(N)cc5)ccc3n4C)ccc1n2C ; CN(c1cccc(N)c1)c1ccc2c(c1)c1cc(N(C)c3ccc4c(c3)c3cc(N(C)c5cccc(N)c5)ccc3n4C)ccc1n2C ; CN(c1ccc(N)cc1)c1ccc2c(c1)c1cc(-c3ccc4c(c3)c3cc(N(C)c5ccc(N)cc5)ccc3n4C)ccc1n2C ; CN(c1ccc(N)cc1)c1ccc2c(c1)c1cc(-c3ccc4c(c3)c3cc(-c5ccc6c(c5)c5cc(N(C)c7ccc(N)cc7)ccc5n6C)ccc3n4C)ccc1n2C]

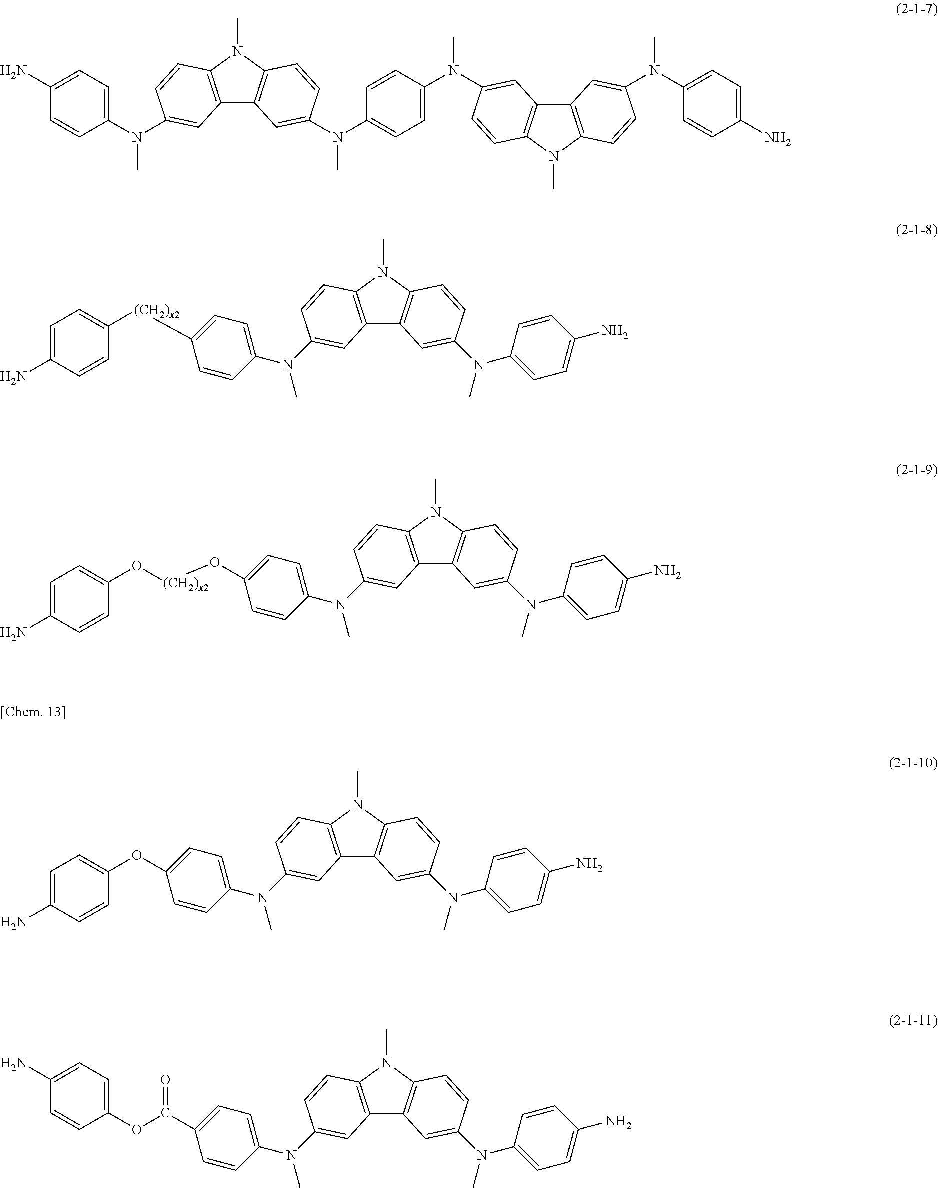

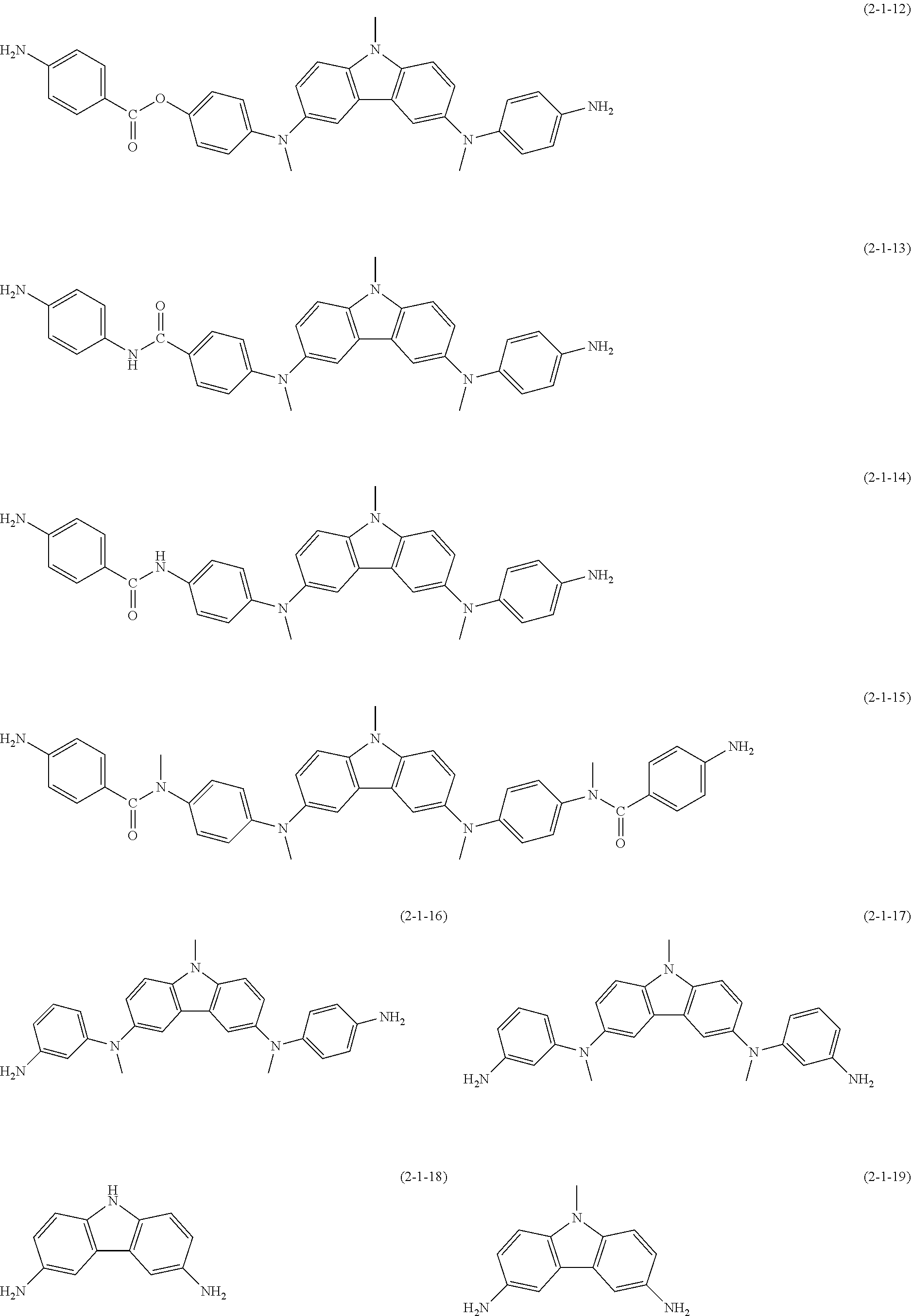

### <Synthesis of Specific Diamine>

The above specific diamine may be synthesized using a known method without particular limitation. For example, synthesis may be carried out by the methods described in WO 2018/062197 A1 and WO 2018/110354 A1.

<Other Diamine: Diamine Other than the Above>

Another diamine aside from the above-described specific diamine may be included in the diamine component for obtaining the specific polymer. Examples of the other diamine include those represented by formula [2] below.

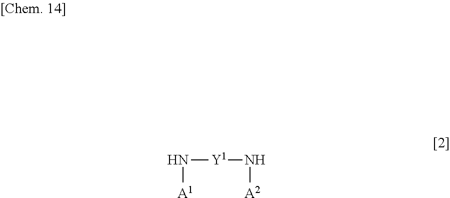

In formula [2], A¹ and A² are each independently a hydrogen atom, an alkyl group of 1 to 5 carbon atoms, an alkenyl group of 2 to 5 carbon atoms or an alkynyl group of 2 to 5 carbon atoms, and Y¹ is a divalent organic group.

Examples of alkyl groups of 1 to 5 carbon atoms include methyl, ethyl, n-propyl, isopropyl, n-butyl, i-butyl, s-butyl, t-butyl and n-pentyl groups.

Examples of alkenyl groups of 2 to 5 carbon atoms include ethenyl, n-1-propenyl, n-2-propenyl, 1-methylethenyl, n-1-butenyl, n-2-butenyl, n-3-butenyl, 2-methyl-1-propenyl, 2-methyl-2-propenyl, 1-ethylethenyl, 1-methyl-1-propenyl, 1-methyl-2-propenyl and n-1-pentenyl groups.

Examples of alkynyl groups of 2 to 5 carbon atoms include ethynyl, n-1-propynyl, n-2-propynyl, n-1-butynyl, n-2-butynyl, n-3-butynyl, 1-methyl-2-propynyl, n-1-pentynyl, n-2-pentynyl, n-3-pentynyl, n-4-pentynyl, 1-methyl-n-butynyl, 2-methyl-n-butynyl, 3-methyl-n-butynyl and 1,1-dimethyl-n-propynyl groups.

Of these, from the standpoint of the monomer reactivity, A¹ and A² are preferably hydrogen atoms or methyl groups.

Examples of Y¹ include the groups of formulas (Y-1) to (Y-170) below. In the groups shown below, x3 is an integer from 1 to 14, although for those groups having a more suitable range, that range is indicated with the formula. For groups in which a specific x3 range is not mentioned, x3 is preferably an integer from 1 to 6. In the following formulas, Me stands for a methyl group.

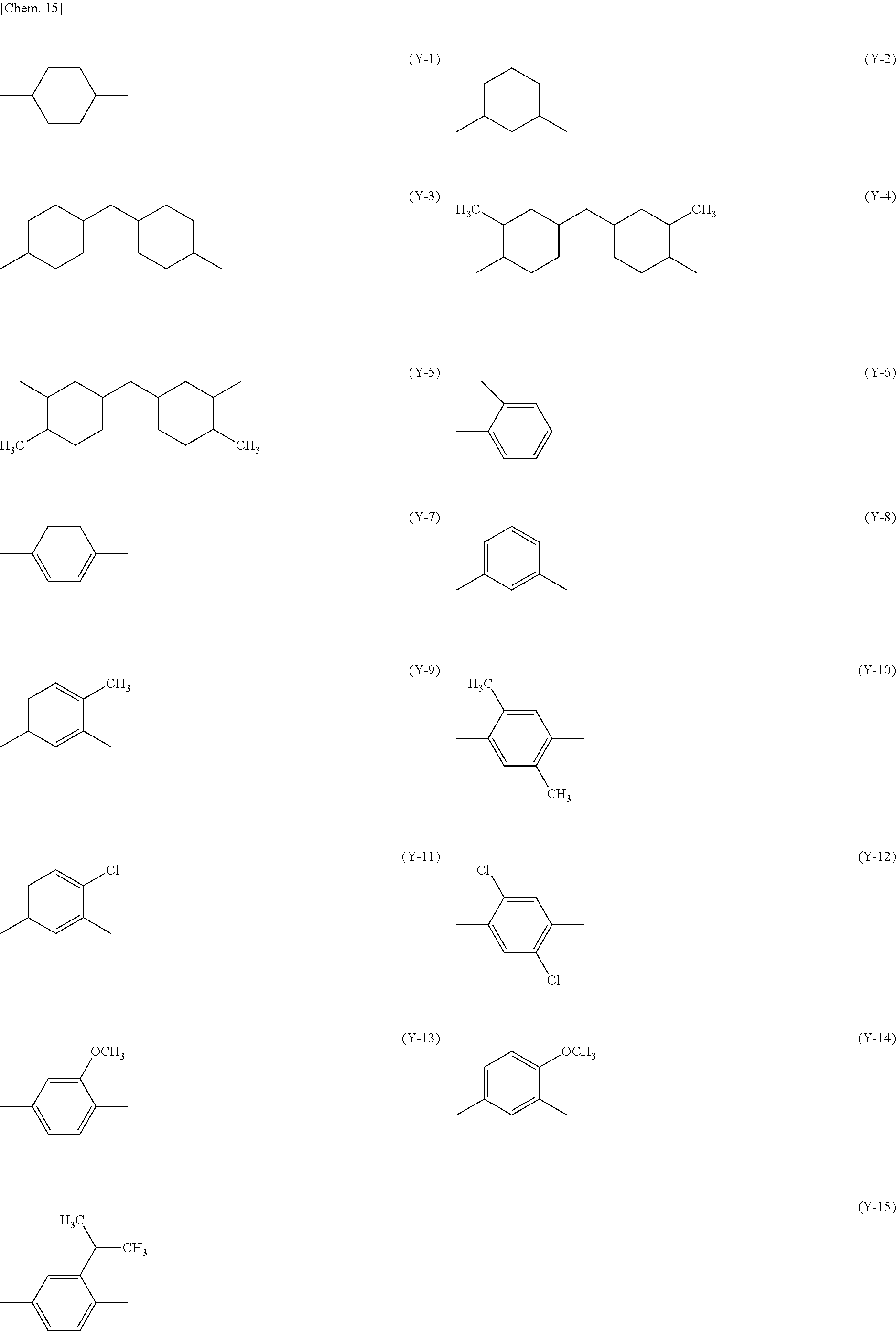

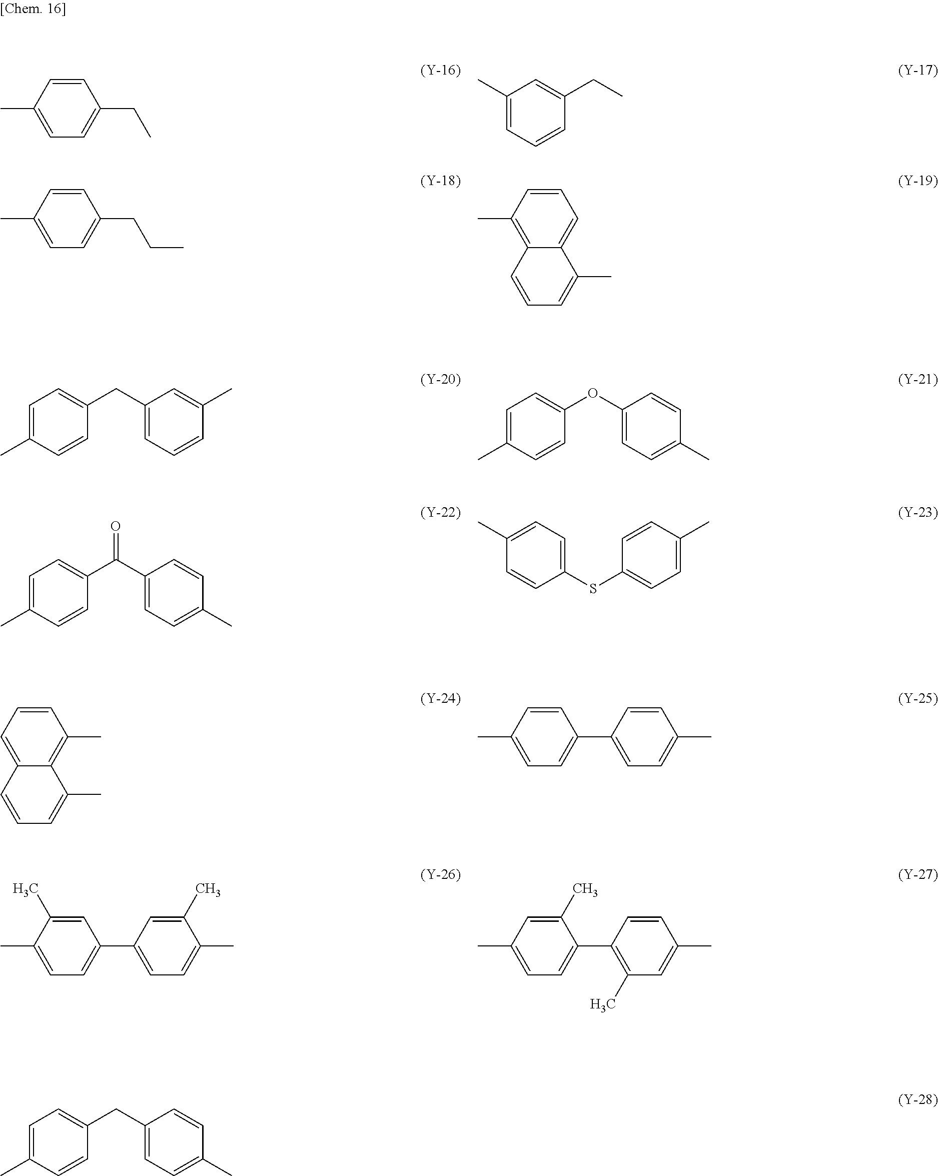

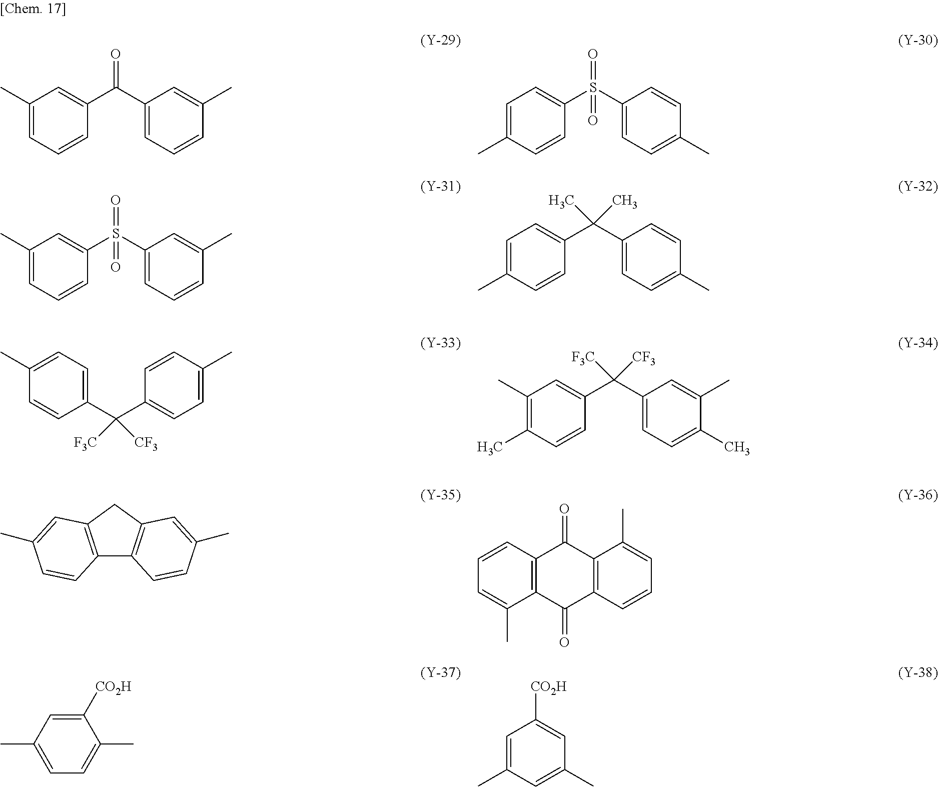

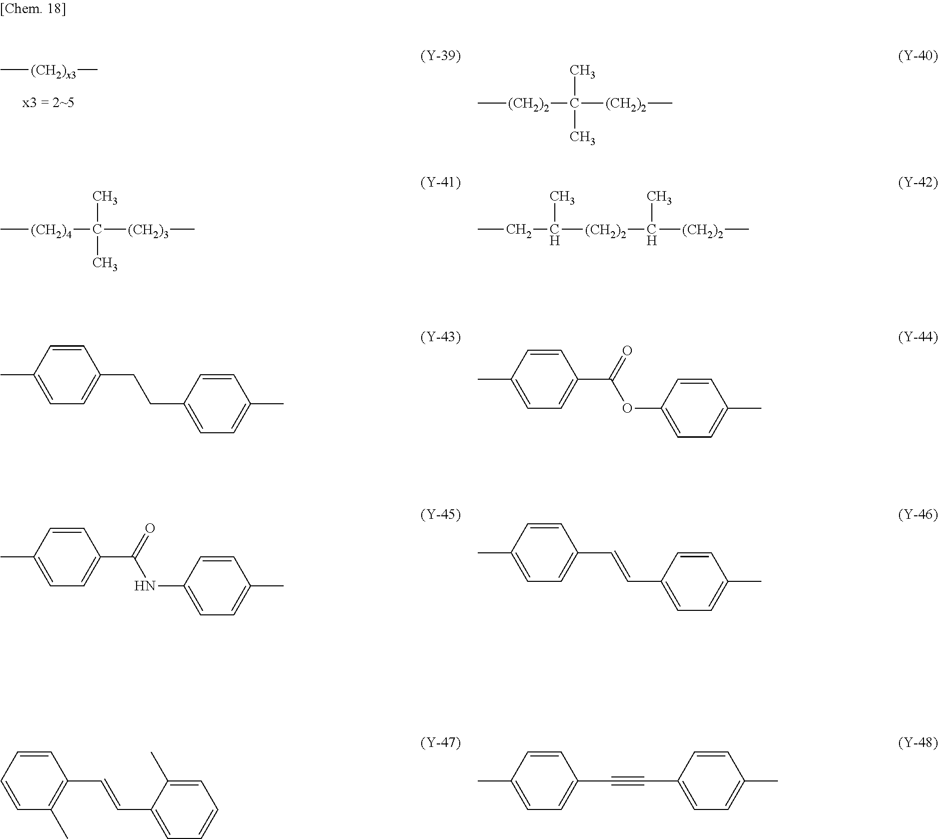

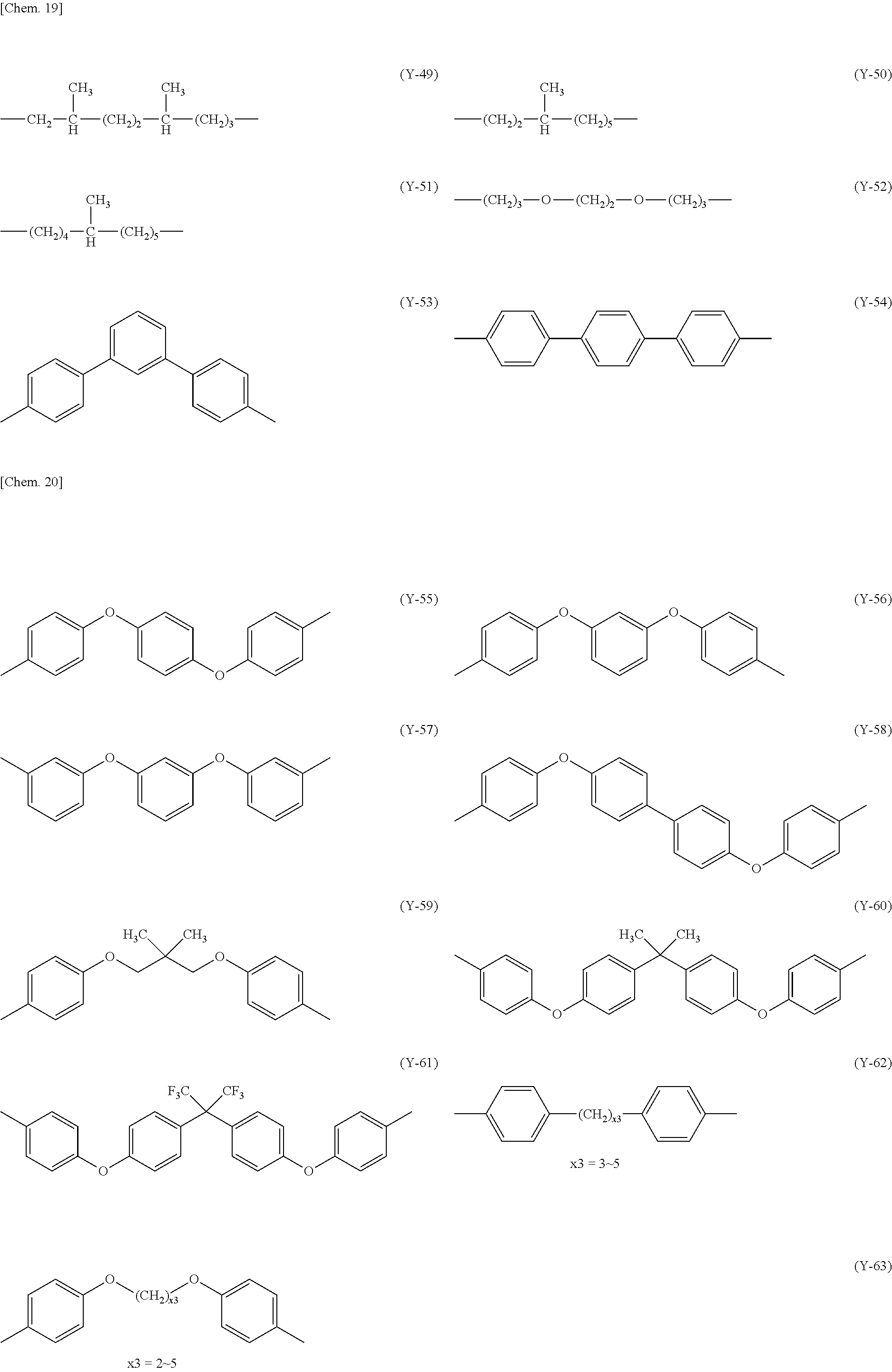

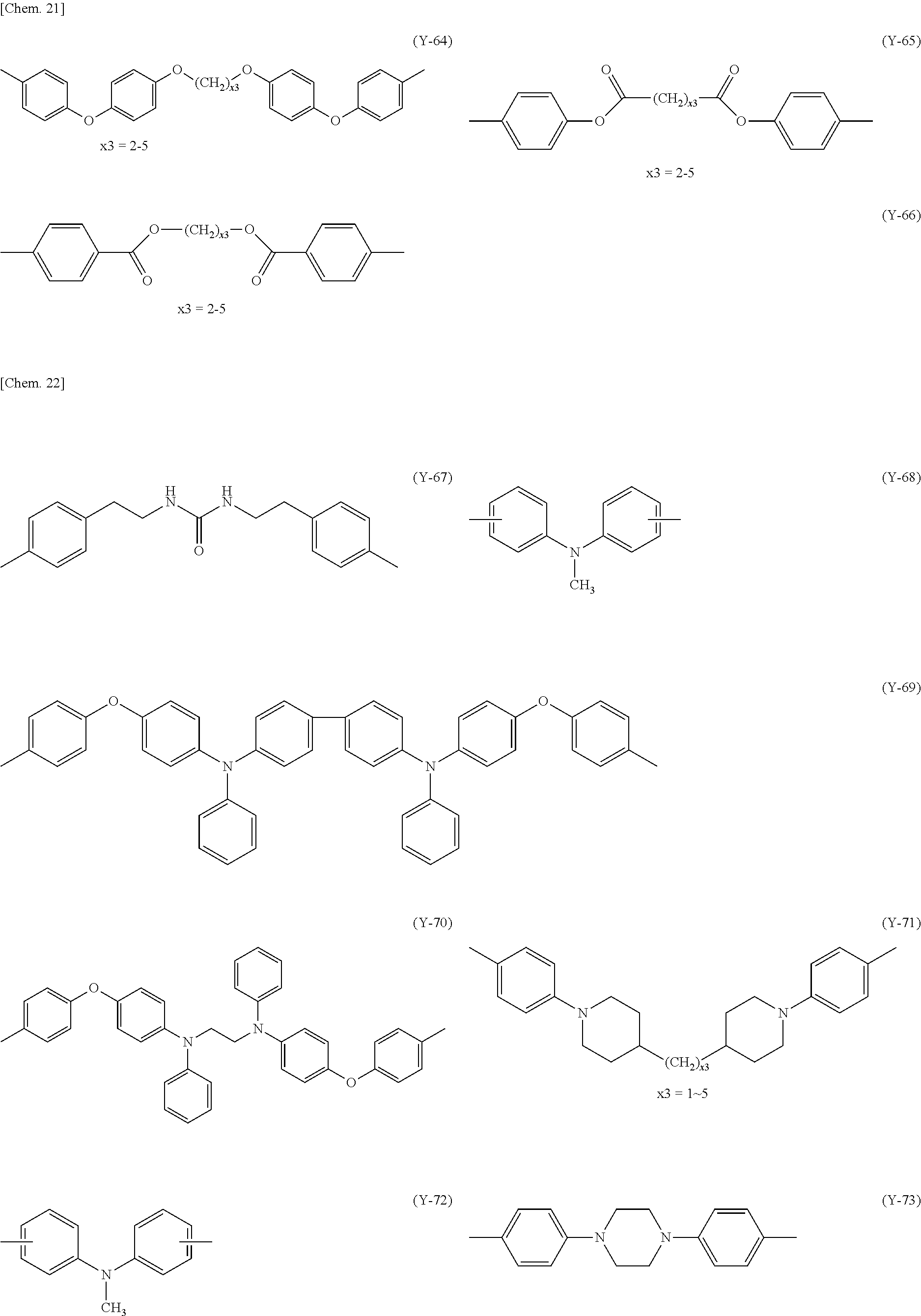

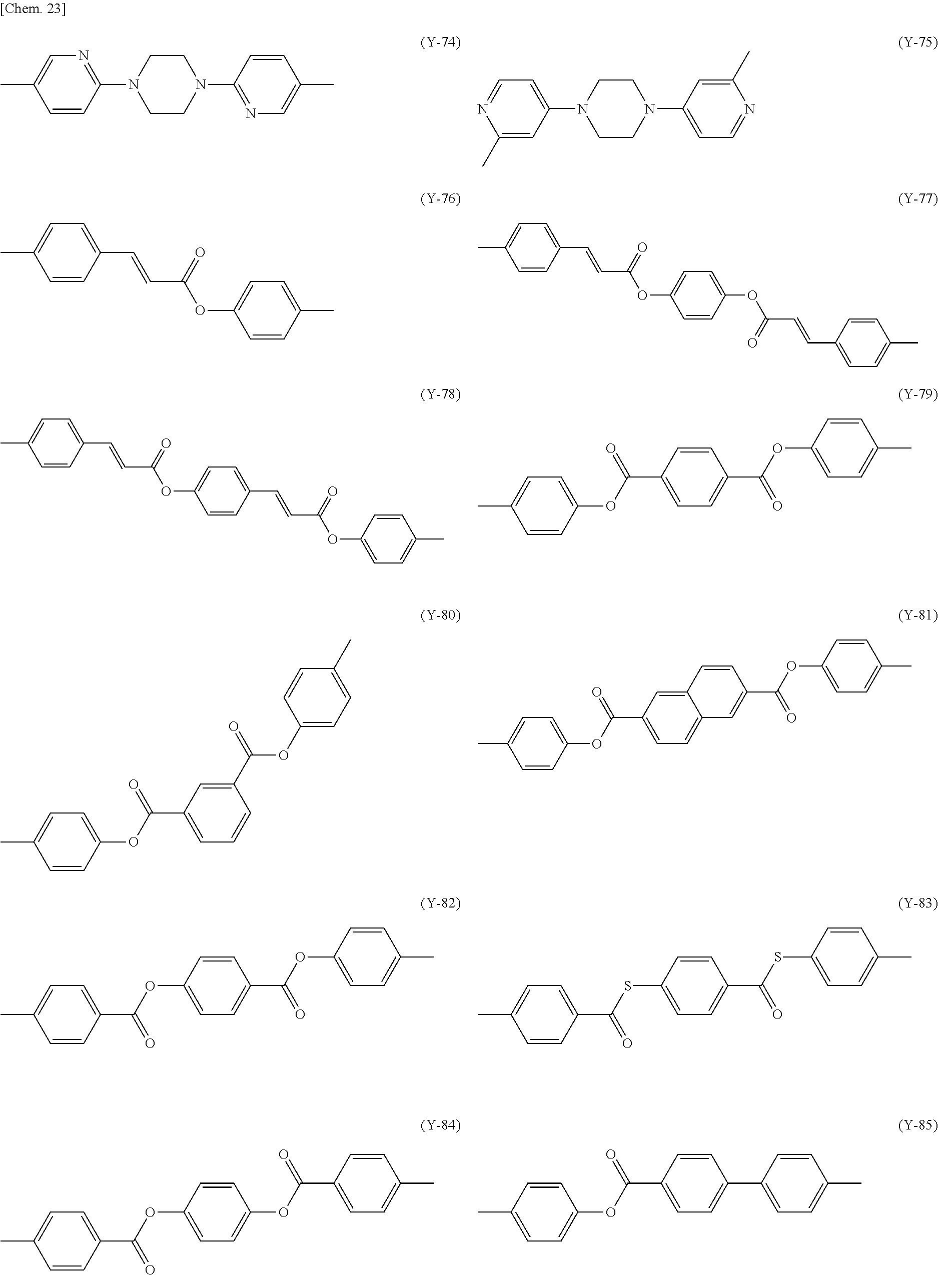

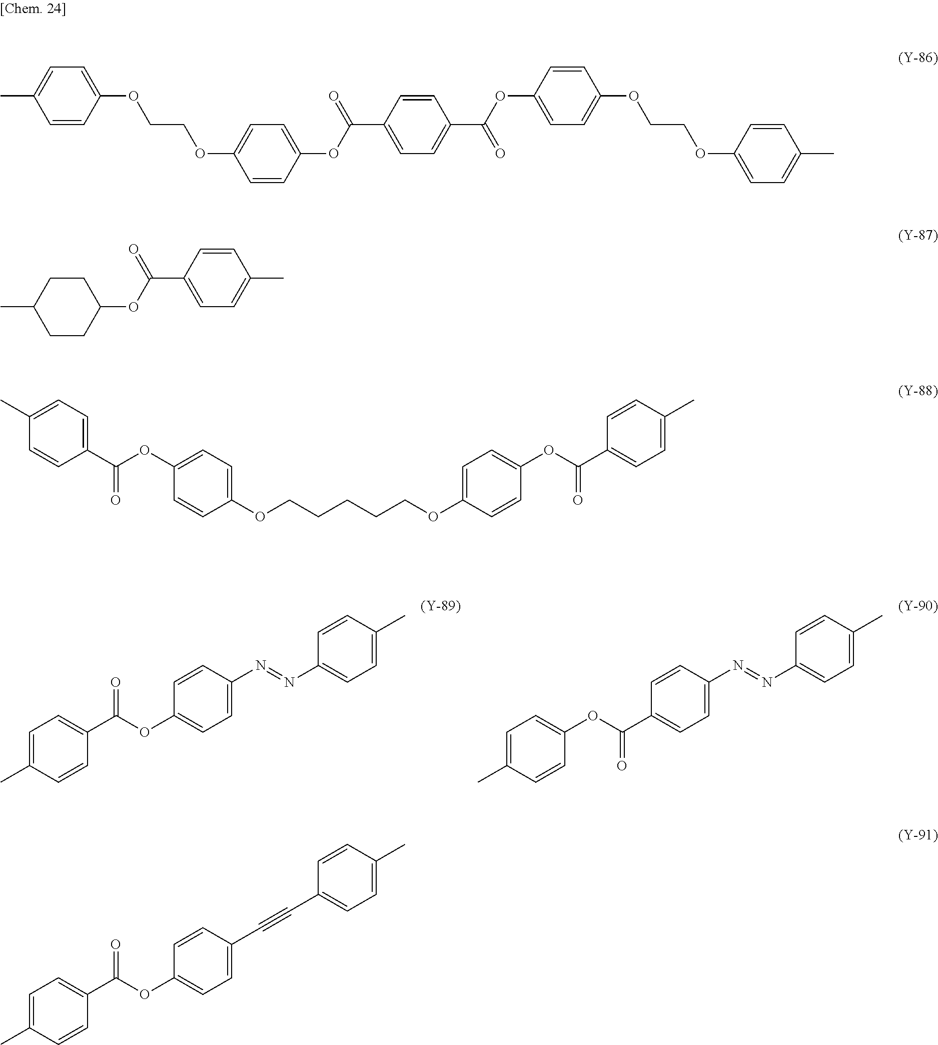

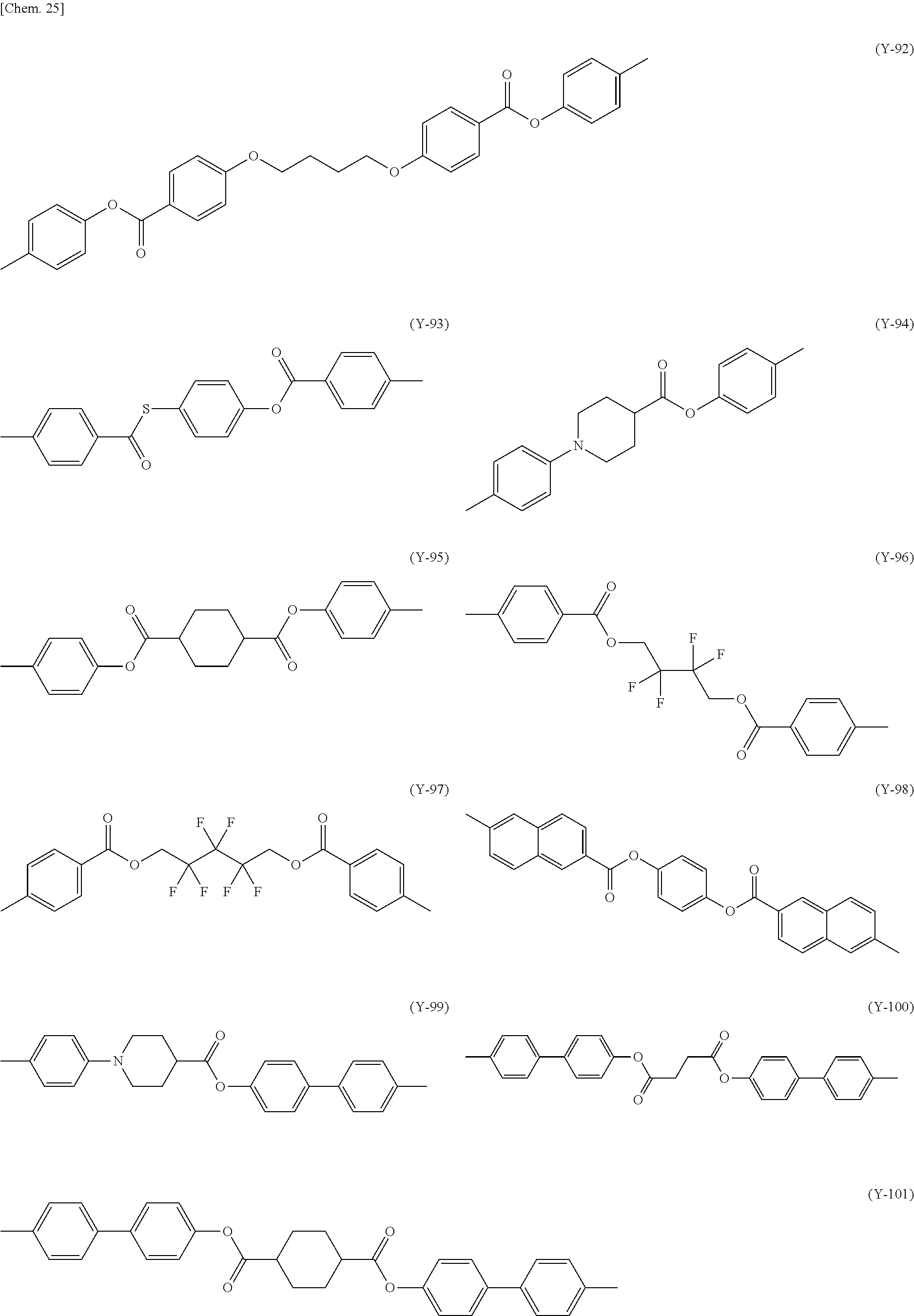

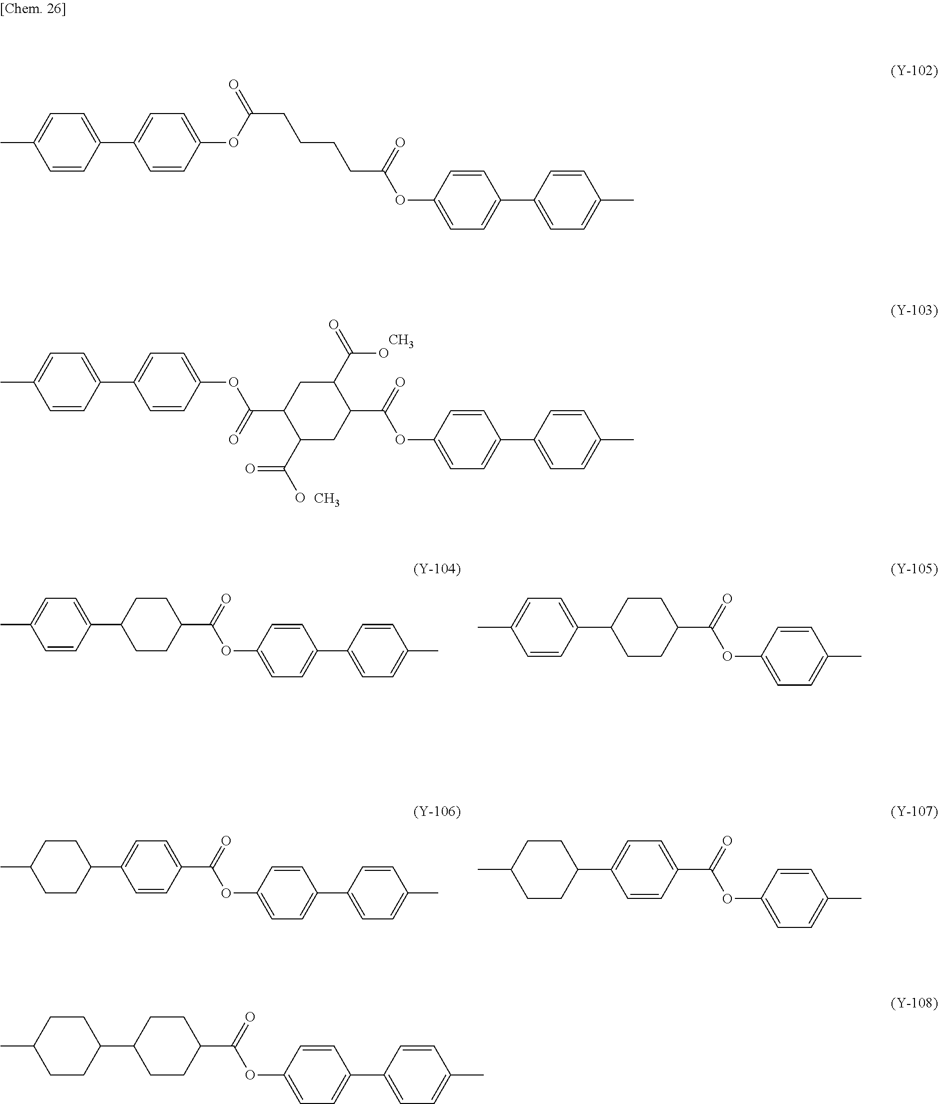

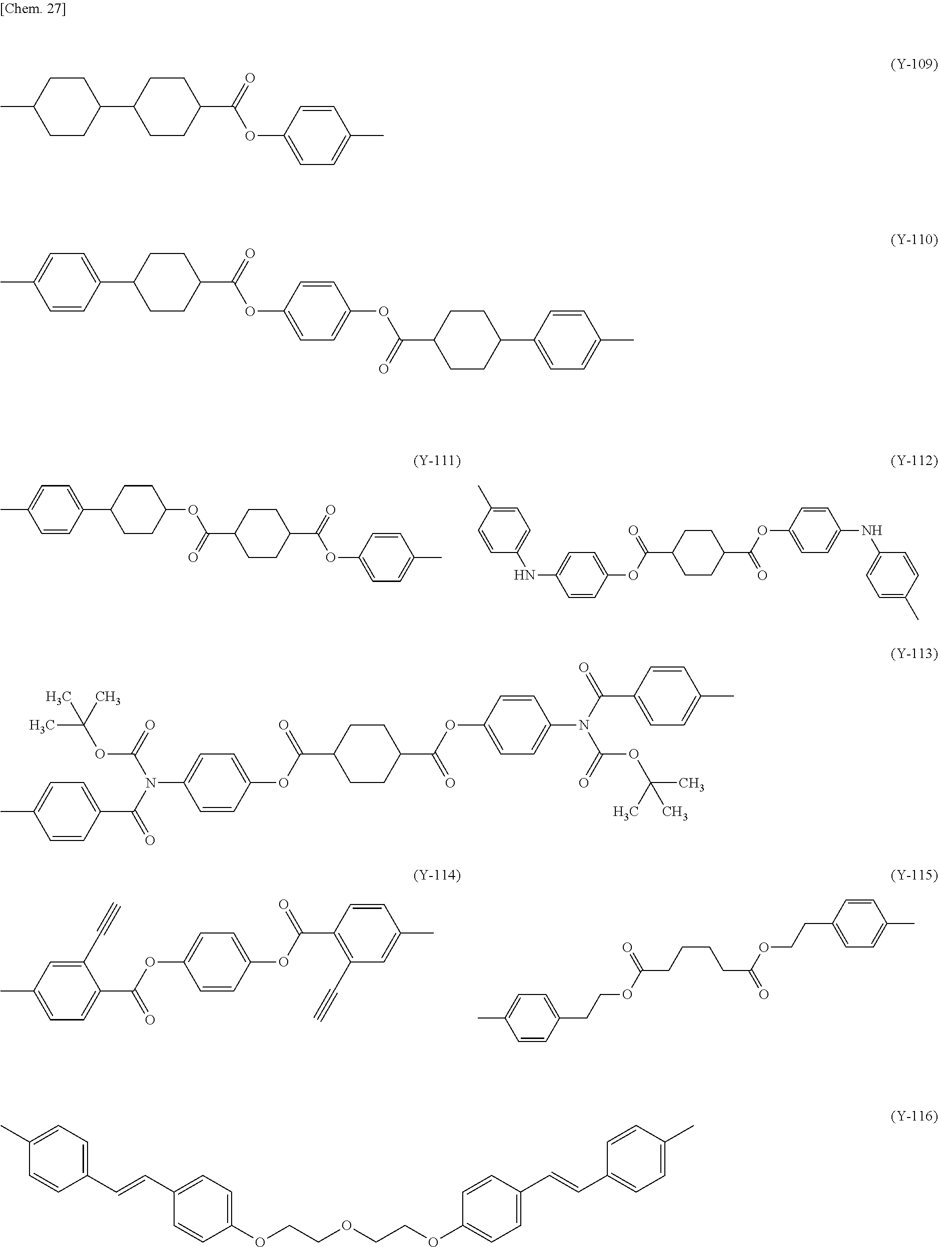

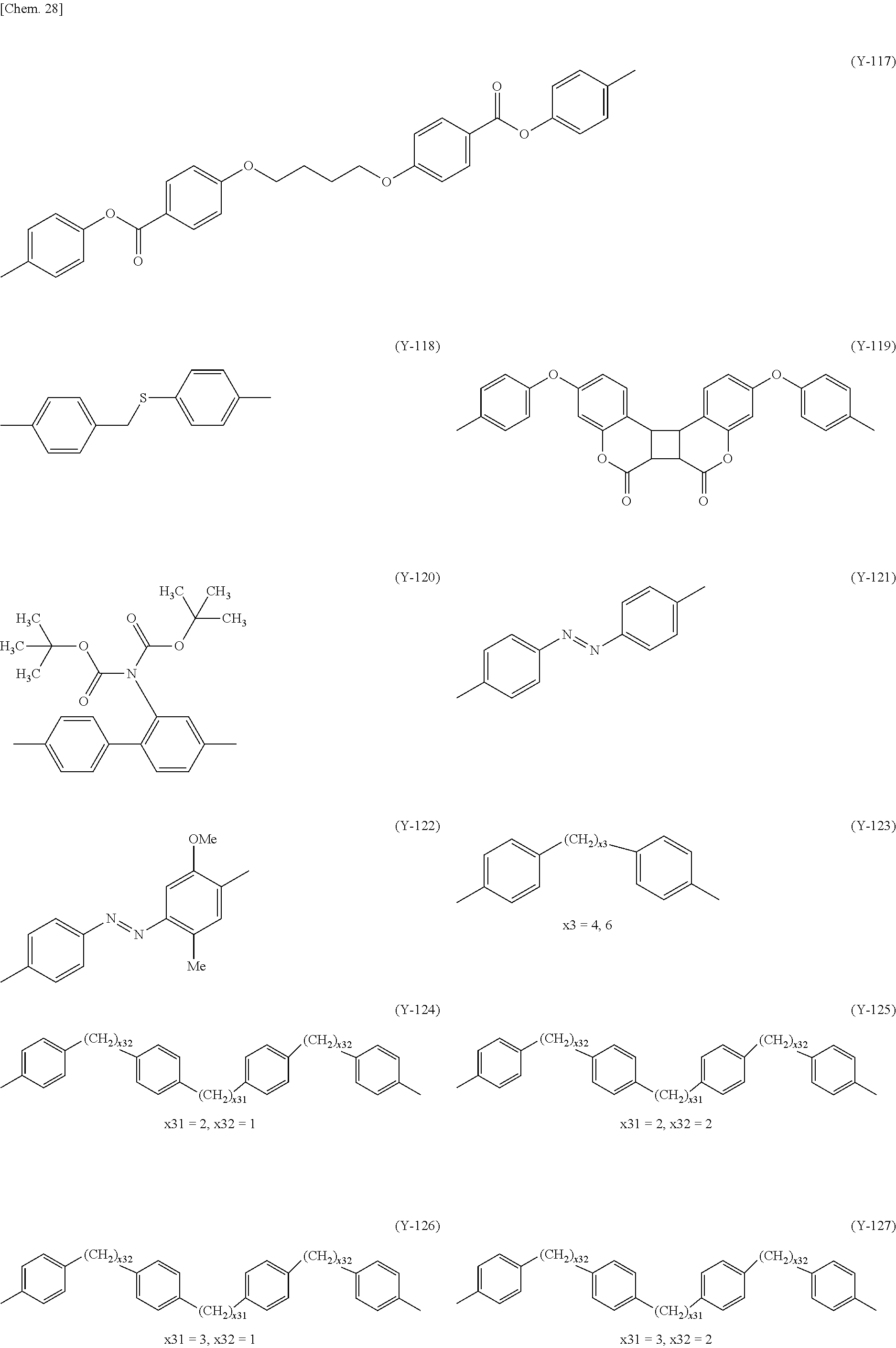

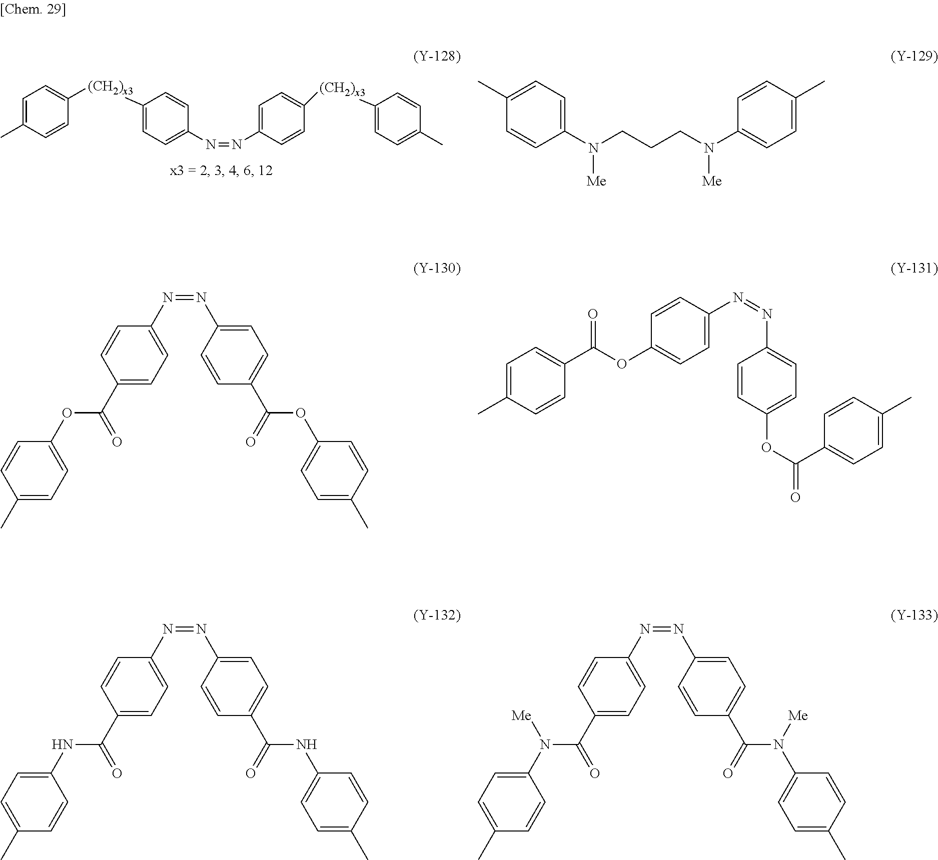

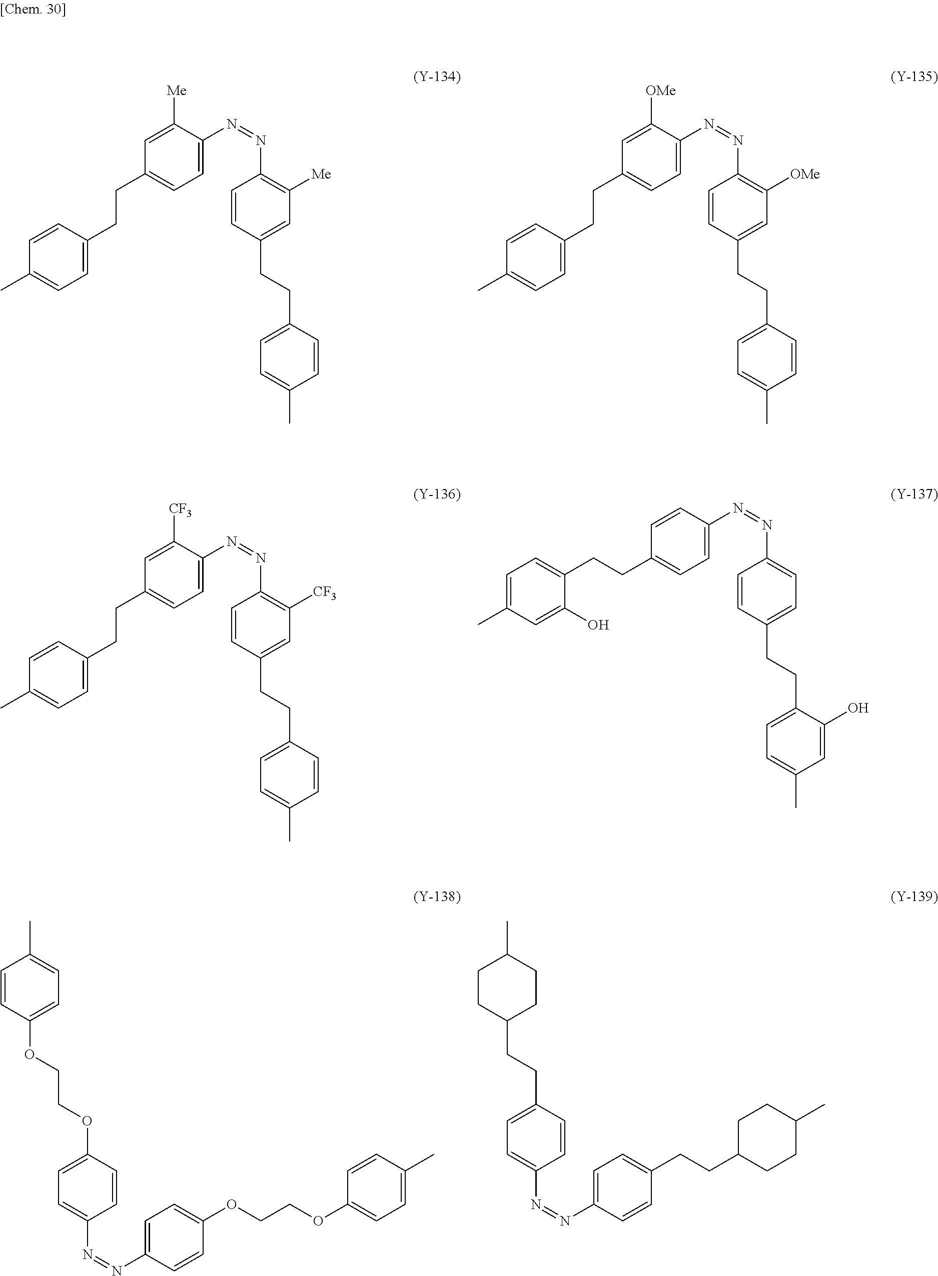 [SMILES: Cc1ccc(CCc2ccc(/N=N\c3ccc(CCc4ccc(C)cc4)cc3C)c(C)c2)cc1 ; COc1cc(CCc2ccc(C)cc2)ccc1/N=N\c1ccc(CCc2ccc(C)cc2)cc1OC ; Cc1ccc(CCc2ccc(/N=N\c3ccc(CCc4ccc(C)cc4)cc3C(F)(F)F)c(C(F)(F)F)c2)cc1 ; Cc1ccc(CCc2ccc(/N=N\c3ccc(CCc4ccc(C)cc4O)cc3)cc2)c(O)c1 ; Cc1ccc(OCCOc2ccc(/N=N\c3ccc(OCCOc4ccc(C)cc4)cc3)cc2)cc1 ; CC1CCC(CCc2ccc(/N=N\c3ccc(CCC4CCC(C)CC4)cc3)cc2)CC1]

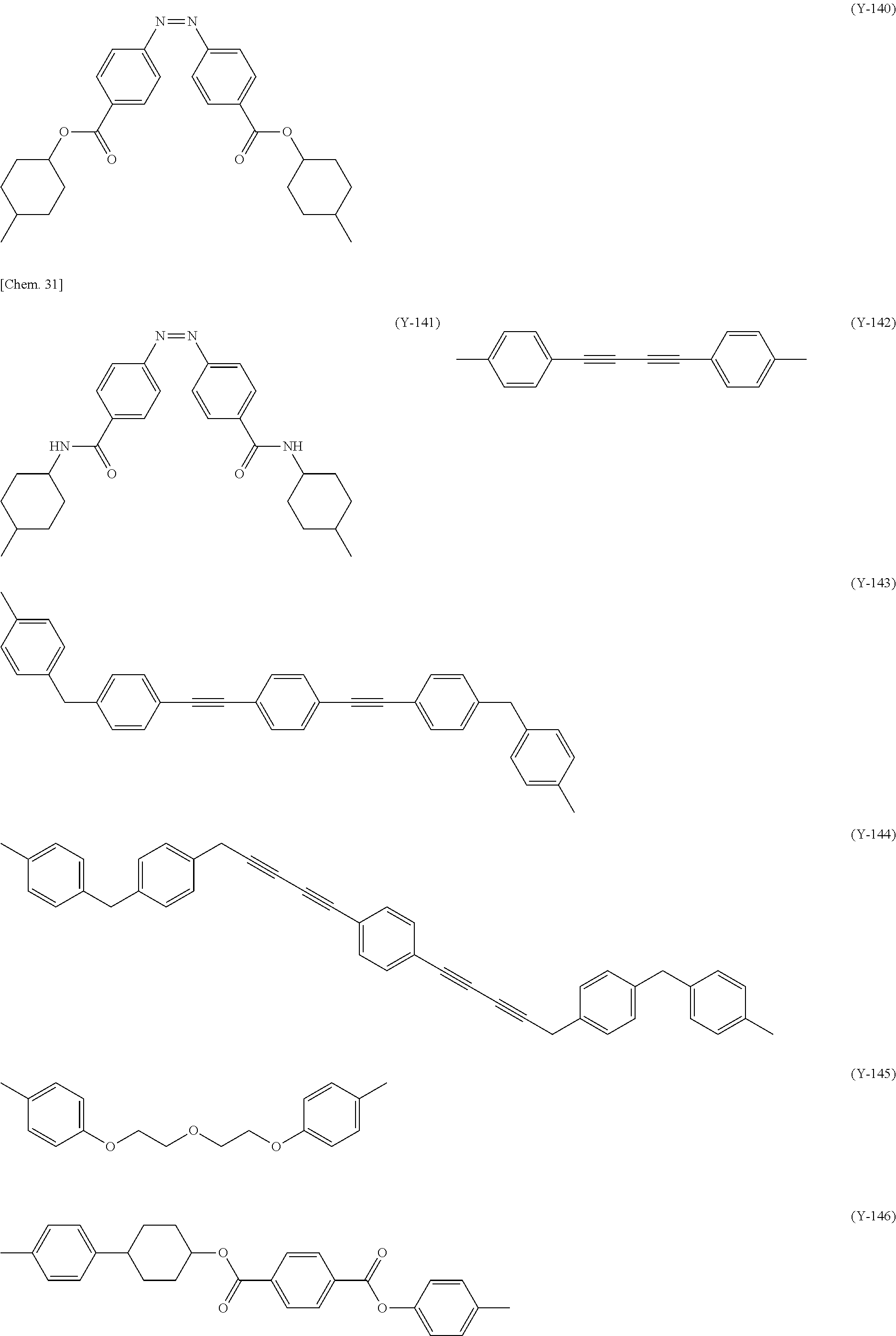

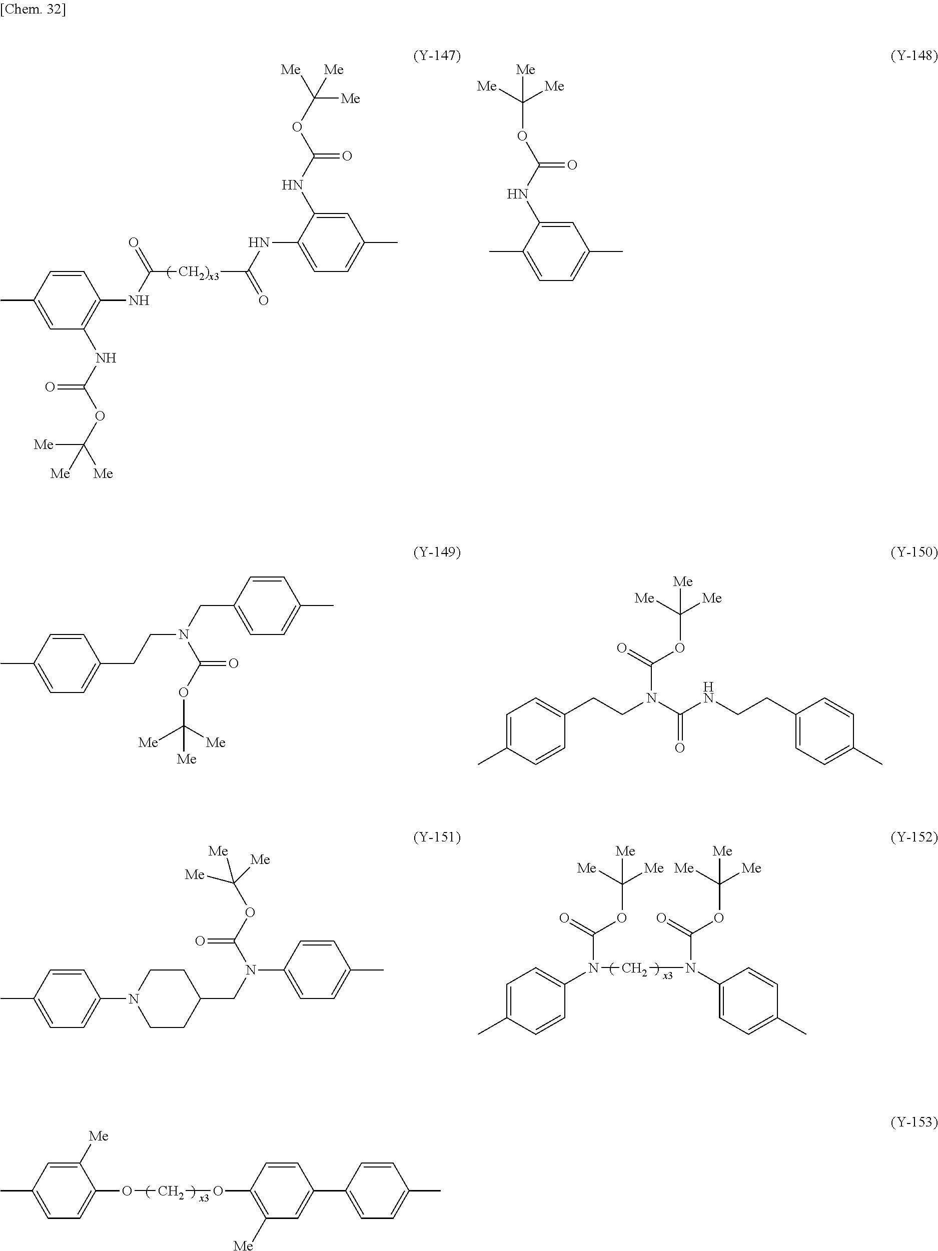

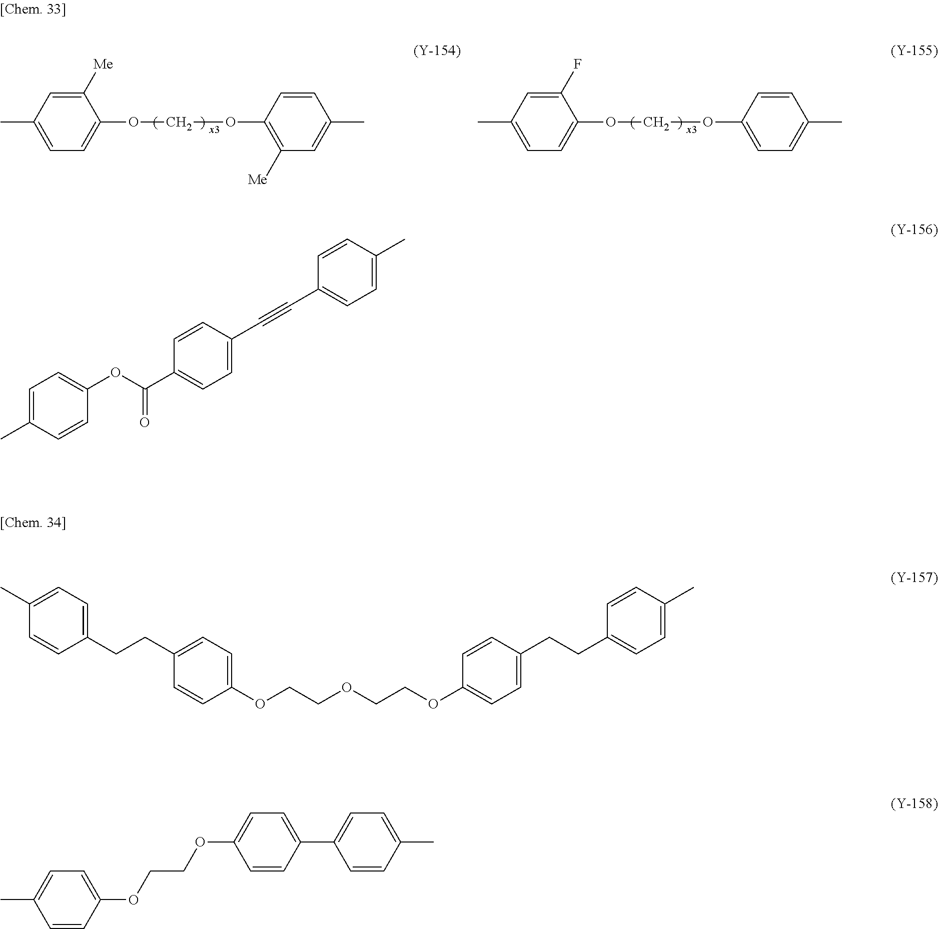

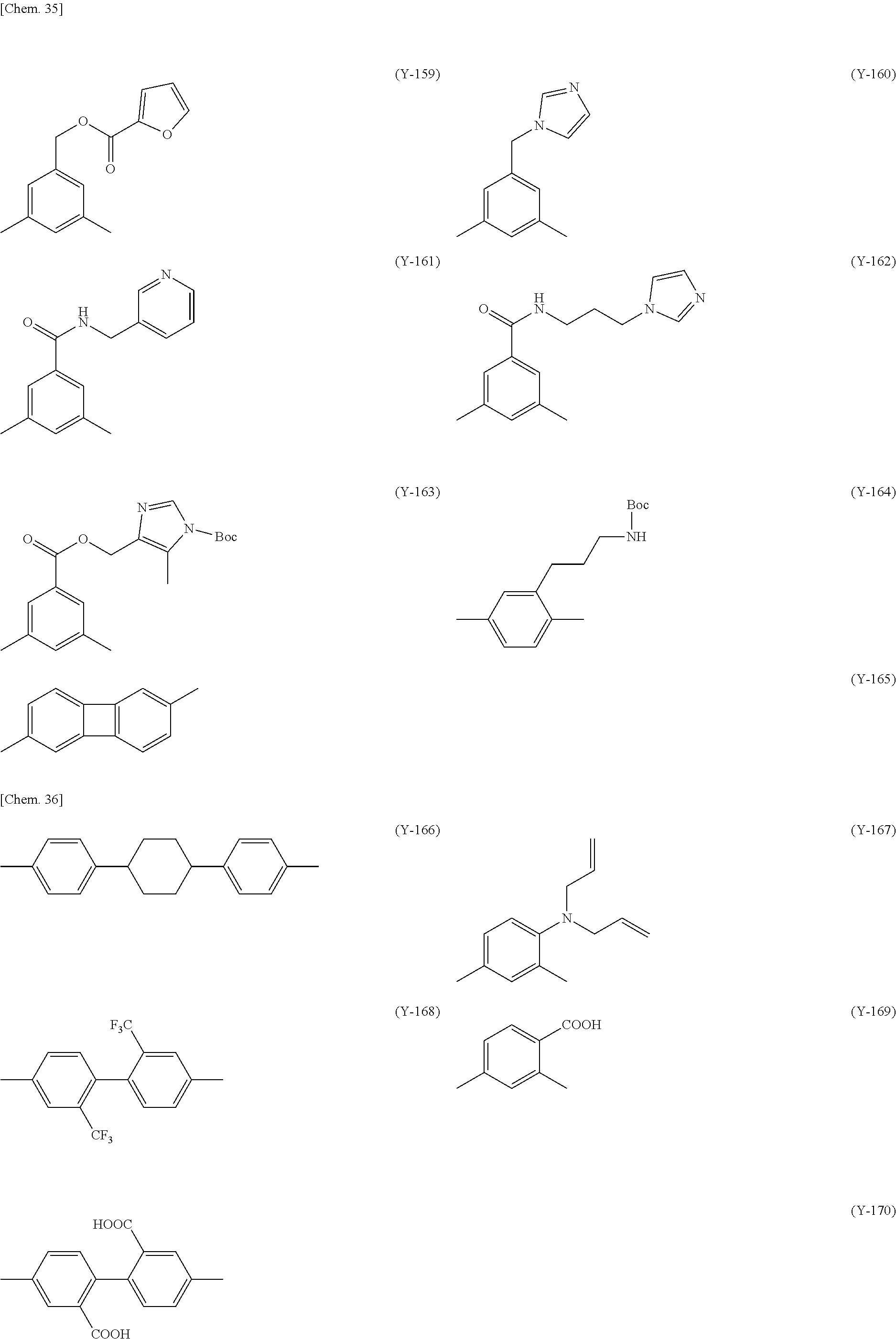

In the above formulas, Boc stands for a tert-butoxycarbonyl group.

The other diamine described above may be a single diamine used alone, or two or more may be used in combination. In cases where the diamine component includes another diamine, the content of the specific diamine within the diamine component may be set to preferably from 10 to 100 mol %, more preferably from 30 to 100 mol %, and even more preferably from 50 to 100 mol %.

### <Tetracarboxylic Acid Component>

Examples of the tetracarboxylic acid component for obtaining the specific polymer include tetracarboxylic acids, tetracarboxylic dianhydrides, tetracarboxylic dihalides, tetracarboxylic acid dialkyl esters and tetracarboxylic acid dialkyl ester dihalides. In this invention, these are referred to collectively as the “tetracarboxylic acid component.”

Tetracarboxylic dianhydrides and derivatives thereof—namely tetracarboxylic acids, tetracarboxylic dihalides, tetracarboxylic acid dialkyl esters and tetracarboxylic acid dialkyl ester dihalides (which tetracarboxylic acid dianhydrides and derivatives are referred to collectively as the “first tetracarboxylic acid component”), may be used as the tetracarboxylic acid component.

Examples of tetracarboxylic dianhydrides include aliphatic tetracarboxylic dianhydrides, alicyclic tetracarboxylic dianhydrides and aromatic tetracarboxylic dianhydrides. Specific examples of these include the compounds of groups [1] to [5] below.
[1] An example of an aliphatic tetracarboxylic dianhydride is 1,2,3,4-butanetetracarboxylic dianhydride.
[2] Examples of alicyclic tetracarboxylic dianhydrides include the acid dianhydrides of formulas (X1-1) to (X1-13) below.

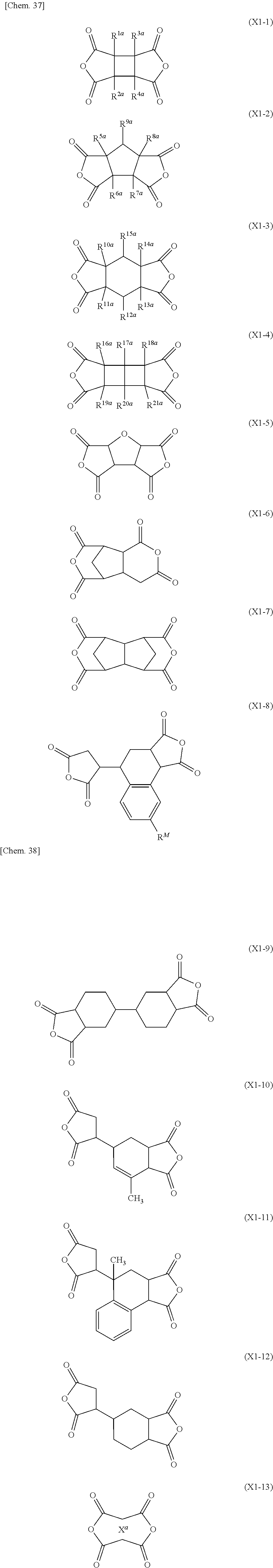

In formulas (X1-1) to (X1-4), R^{1a} to R^{21a} are each independently a hydrogen atom, a halogen atom, an alkyl group of 1 to 6 carbon atoms, an alkenyl group of 2 to 6 carbon atoms, an alkynyl group of 2 to 6 carbon atoms, a fluorine-containing monohydric organic group of 1 to 6 carbon atoms or a phenyl group. R^{M} represents a hydrogen atom or a methyl group. In formula (X1-13), X^{a} represents a tetravalent organic group of any of formulas (Xa-1) to (Xa-7) below.

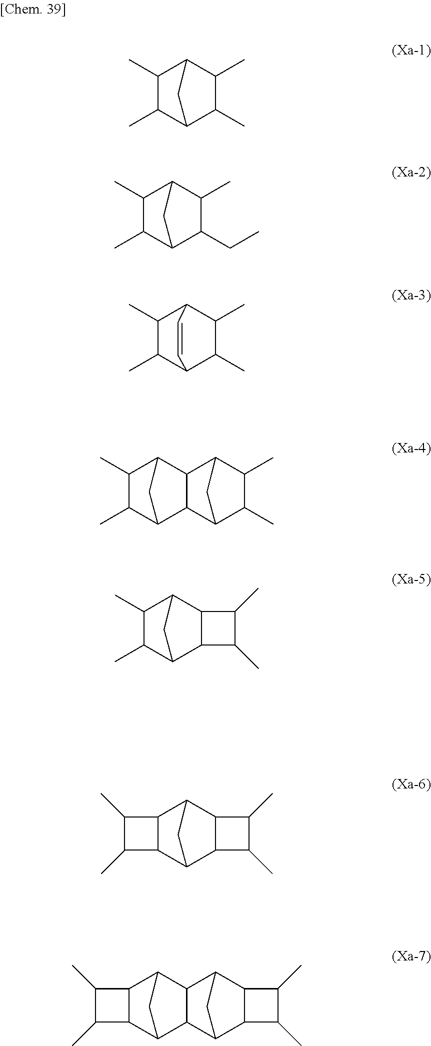

[3] 3-Oxabicyclo[3.2.1]octane-2,4-dione-6-spiro-3′-(tetrahydrofuran-2′,5′-dione), 3,5,6-tricarboxy-2-carboxymethylnorbornane-2:3,5:6-dianhydride, 4,9-dioxatricyclo[5.3.1.02,6]undecane-3,5,8,10-tetraone, etc.
[4] Examples of aromatic tetracarboxylic dianhydrides include pyromellitic anhydride, 4,4′-(hexafluoroisopropylidene)diphthalic anhydride, 3,3′,4,4′-diphenylsulfonetetracarboxylic dianhydride, and the acid dianhydrides represented by formulas (X2-1) to (X2-10) below.

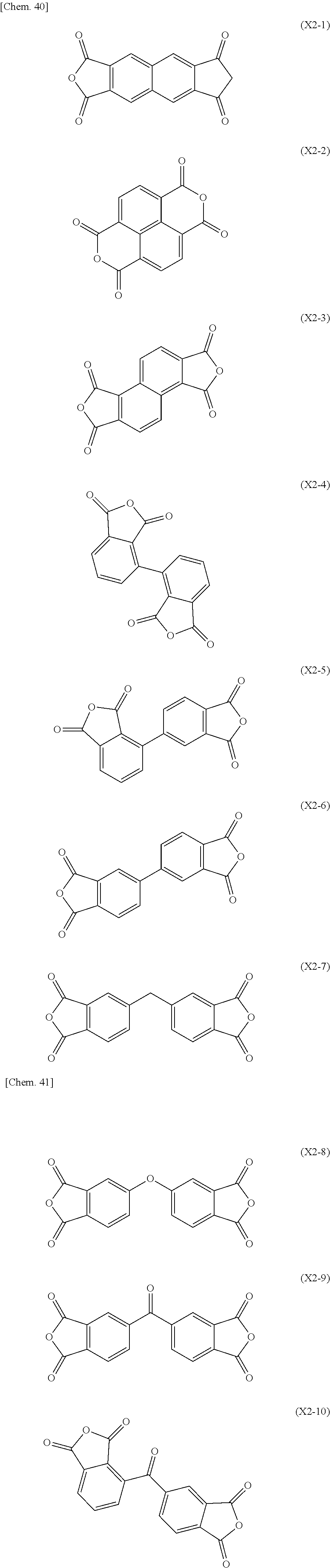

[5] The acid dianhydrides of formulas (X3-1) to (X3-9) below, the tetracarboxylic dianhydrides mentioned in JP-A 2010-97188, etc.

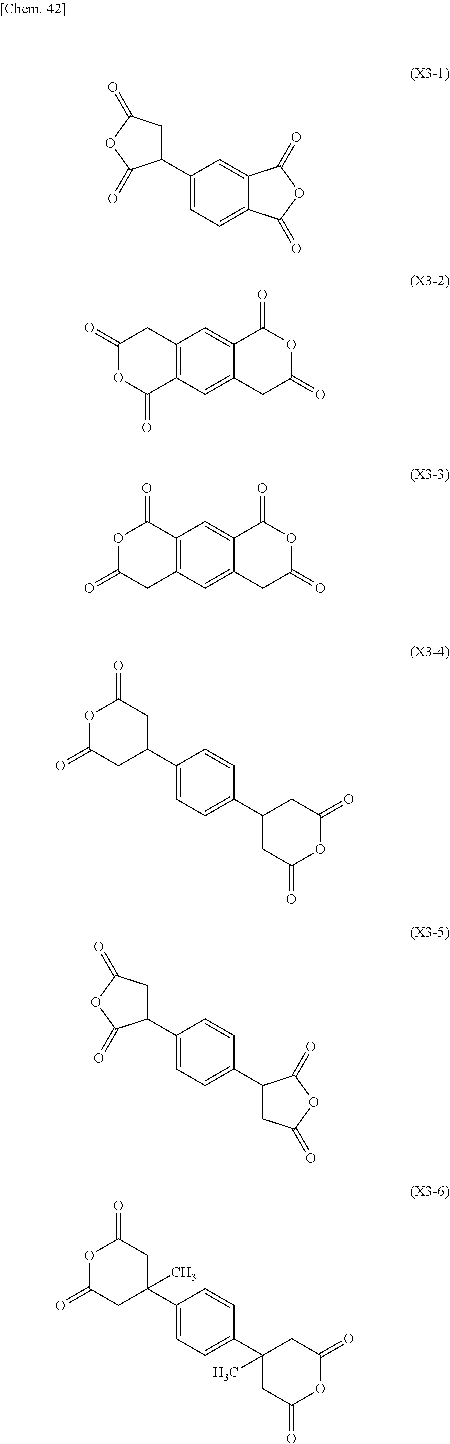 [SMILES: O=C1CC(c2ccc3c(c2)C(=O)OC3=O)C(=O)O1 ; O=C1Cc2cc3c(cc2C(=O)O1)CC(=O)OC3=O ; O=C1Cc2cc3c(cc2C(=O)O1)C(=O)OC(=O)C3 ; O=C1CC(c2ccc(C3CC(=O)OC(=O)C3)cc2)CC(=O)O1 ; O=C1CC(c2ccc(C3CC(=O)OC3=O)cc2)C(=O)O1 ; CC1(c2ccc(C3(C)CC(=O)OC(=O)C3)cc2)CC(=O)OC(=O)C1]

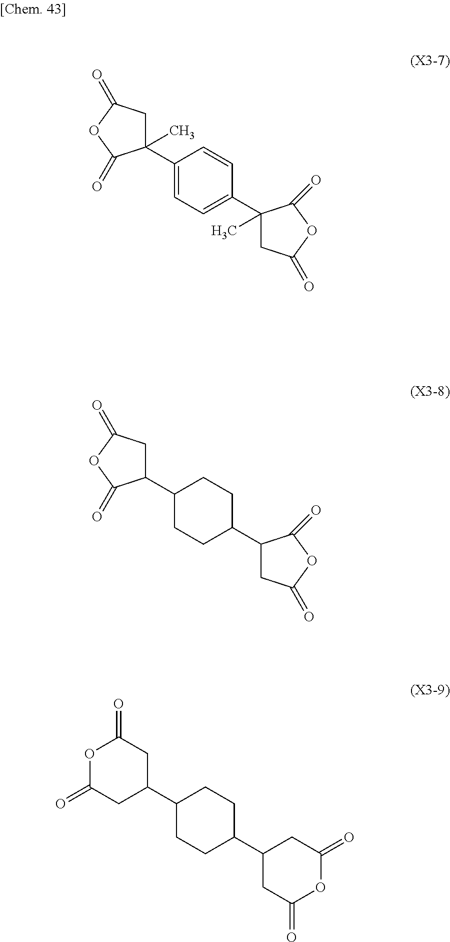 [SMILES: CC1(c2ccc(C3(C)CC(=O)OC3=O)cc2)CC(=O)OC1=O ; O=C1CC(C2CCC(C3CC(=O)OC3=O)CC2)C(=O)O1 ; O=C1CC(C2CCC(C3CC(=O)OC(=O)C3)CC2)CC(=O)O1]

The above-described tetracarboxylic acid component may be a single compound used alone or two or more may be used in admixture. One compound is used alone or two or more are used in admixture according to the properties required of the organic optical sensor and the charge transporting layer. In cases where two or more are used in admixture, the relative proportions, etc. thereof may be suitably adjusted.

### <Method for Preparing Specific Polymer>

As explained above, the specific polymer can be obtained by a method that reacts the diamine component with the tetracarboxylic acid component. An example of this method involves reacting a diamine component consisting of one or a plurality of diamines with at least one tetracarboxylic acid component selected from the group consisting of tetracarboxylic dianhydrides and derivatives of the tetracarboxylic acid to obtain a polyamic acid. Specifically, use can be made of a method which obtains a polyamic acid by polycondensing a primary or secondary diamine with a tetracarboxylic dianhydride.

A polyamic acid alkyl ester can be obtained by the polycondensation of a tetracarboxylic acid in which the carboxylic acid groups have been dialkyl esterified with a primary or secondary diamine, the polycondensation of a tetracarboxylic dihalide prepared by halogenating the carboxylic acid groups with a primary or secondary diamine, or the esterification of the carboxyl groups on a polyamic acid. A polyimide can be obtained by a method which forms a polyimide via ring closure of the above polyamic acid or polyamic acid alkyl ester.

Reaction of the diamine component with the tetracarboxylic acid component is typically carried out in a solvent. The solvent used at this time is not particularly limited, provided that it is one in which the polyimide precursor that has formed dissolves. Examples of the solvent here include N-methyl-2-pyrrolidone, N-ethyl-2-pyrrolidone, γ-butyrolactone, N,N-dimethylformamide, N,N-diethylformamide, N,N-dimethylacetamide, N,N-diethylacetamide, 3-methoxy-N,N-dimethylpropanamide, dimethylsulfoxide and 1,3-dimethyl-imidazolidinone. When the polyimide precursor has a high solvent solubility, it is also possible to use methyl ethyl ketone, cyclohexanone, cyclopentanone, 4-hydroxy-4-methyl-2-pentanone or the solvents represented by formulas [D-1] to [D-3] below.

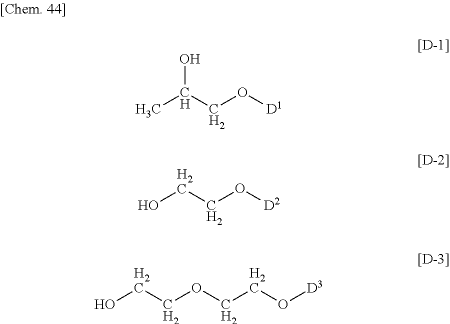

In formula [D-1], D¹ represents an alkyl group of 1 to 3 carbon atoms. In formula [D-2], D² represents an alkyl group of 1 to 3 carbon atoms. In formula [D-3], D³ represents an alkyl group of 1 to 4 carbon atoms.

Examples of the alkyl group of 1 to 4 carbon atoms include methyl, ethyl, n-propyl, isopropyl, n-butyl, i-butyl, s-butyl and t-butyl groups. Examples of the alkyl group of 1 to 3 carbon atoms include those groups among the foregoing alkyl groups of 1 to 4 carbon atoms which have from 1 to 3 carbon atoms.

One of these solvents may be used alone, or two or more may be used in admixture. Even solvents which do not dissolve the polyimide precursor may be used by admixture with the above solvents within a range where the polyimide precursor that has formed does not precipitate out of solution. Because moisture within the solvent hinders the polymerization reaction and moreover causes the polyimide precursor that has formed to hydrolyze, the solvent which is used is preferably one that has been dewatered and dried.

Any of the following methods may be used when reacting the diamine component with the tetracarboxylic acid component in a solvent: a method which stirs a solution of the diamine component dispersed or dissolved in a solvent and adds thereto the tetracarboxylic acid component, either directly as is or after dispersion or dissolution in a solvent; a method which, conversely, adds the diamine component to a solution of the tetracarboxylic acid component dispersed or dissolved in a solvent; or a method which alternately adds the diamine component and the tetracarboxylic acid component. Alternatively, in cases where reaction is carried out using a plurality of diamine components or tetracarboxylic acid components, these may be reacted in a premixed state, they may be successively reacted one at a time, or low-molecular-weight compounds that have been individually reacted may be mixed and reacted together to form the polymer.

The temperature for polycondensing the diamine component with the tetracarboxylic acid component may be set to any temperature between −20° C. and 150° C., although a temperature in the range of between −5° C. and 100° C. is preferred. The reaction may be carried out at any concentration, although when the concentration is too low, it is difficult to obtain a high-molecular-weight polymer and when the concentration is too high, the viscosity of the reaction mixture becomes too high, making uniform stirring difficult. Hence, the concentration is preferably from 1 to 50 wt %, and more preferably from 5 to 30 wt %. It is also possible to initially carry out the reaction at a high concentration and to subsequently add solvent.

In the polyimide precursor polymerization reaction, the ratio between the total number of moles of the diamine component and the total number of moles of the tetracarboxylic acid component is preferably from 0.8 to 1.2. As with conventional polycondensation reactions, the closer this molar ratio is to 1.0, the larger the molecular weight of the polyimide precursor that forms.

The polyimide is a polyimide that is obtained by ring closing the above polyimide precursor. In this polyimide, the amic acid group ring-closing ratio (also called the imidization ratio) does not necessarily have to be 100%, and may be adjusted at one's discretion according to the intended application or purpose. Examples of methods for imidizing the polyimide precursor include thermal imidization which involves directly heating a solution of the polyimide precursor, and catalytic imidization which involves adding a catalyst to a solution of the polyimide precursor.

The temperature when subjecting the polyimide precursor to thermal imidization in a solution is between 100° C. and 400° C., and preferably between 120° C. and 250° C. A method that is carried out while removing from the system water which forms due to the imidization reaction is preferred. Catalytic imidization of the polyimide precursor can be carried out by adding a basic catalyst and an acid anhydride to a solution of the polyimide precursor and stirring at between −20° C. and 250° C., preferably between 0° C. and 180° C.

The amount of basic catalyst per mole of amic acid groups is from 0.5 to 30 moles, preferably from 2 to 20 moles, and the amount of acid anhydride is from 1 to 50 moles, preferably from 3 to 30 moles. Examples of basic catalysts include pyridine, triethylamine, trimethylamine, tributylamine and trioctylamine. Of these, pyridine is preferable because it has a basicity suitable for promoting the reaction. Examples of acid anhydrides include acetic anhydride, trimellitic anhydride and pyromellitic anhydride. In particular, the use of acetic anhydride is preferred because purification following reaction completion is easy. The imidization ratio with catalytic imidization can be controlled by adjusting the amount of catalyst and the reaction temperature and time.

When recovering the polyimide precursor or polyimide that has formed from the reaction solution of polyimide precursor or polyimide, the reaction solution may be poured into the solvent to induce precipitation. Examples of the solvent used for precipitation include methanol, ethanol, isopropyl alcohol, acetone, hexane, butyl cellosolve, heptane, methyl ethyl ketone, methyl isobutyl ketone, toluene, benzene and water. The polymer that has been poured into the solvent and caused to precipitate may be recovered by filtration and then dried at normal pressure or reduced pressure and normal temperature or under heating. Alternatively, by subjecting the precipitated and recovered polymer repeatedly, i.e., from 2 to 10 times, to redissolution in a solvent, reprecipitation and recovery, the level of impurities within the polymer can be reduced. The solvent used at this time is exemplified by alcohols, ketones and hydrocarbons. Using three or more solvents selected from among these increases the efficiency of purification all the more and is thus preferred.

More specific examples of methods for preparing the polyamic acid alkyl ester of the invention are shown in (1) to (3) below.

### (1) Preparation by Polyamic Acid Esterification

This is a method which, for example, prepares a polyamic acid from the diamine component and the tetracarboxylic acid component, and then carries out chemical reactions at the carboxyl groups (COOH) thereon, i.e., esterification reactions, producing a polyamic acid alkyl ester. The esterification reactions are carried out in the presence of a polyamic acid and an esterifying agent at between −20° C. and 150° C. (preferably between 0° C. and 50° C.) for a period of from 30 minutes to 24 hours (preferably from 1 to 4 hours).

The esterifying agent is preferably one which can be easily removed following the esterification reaction. Specific examples include N,N-dimethylformamide dimethyl acetal, N,N-dimethylformamide diethyl acetal, N,N-dimethylformamide dipropyl acetal, N,N-dimethylformamide dineopentylbutyl acetal, N,N-dimethylformamide di-t-butyl acetal, 1-methyl-3-p-tolyltriazene, 1-ethyl-3-p-tolyltriazine, 1-propyl-3-p-tolyltriazene and 4-(4,6-dimethoxy-1,3,5-triazin-2-yl)-4-methylmorpholinium chloride. The esterifying agent is used in an amount that is preferably from 2 to 6 molar equivalents per mole of repeating units on the polyamic acid. From 2 to 4 molar equivalents is more preferred.

Examples of the solvent used in the esterification reaction include, from the standpoint of the solubility of the polyamic acid in the solvent, the solvents used in the above-described reaction between the diamine component and the tetracarboxylic acid component. Of these, N,N-dimethylformamide, N,N-diethylformamide, N-methyl-2-pyrrolidone, N-ethyl-2-pyrrolidone, N,N-dimethylacetamide, N,N-diethylacetamide, 3-methoxy-N,N-dimethylpropanamide and γ-butyrolactone are preferred. One of these solvents may be used alone or two or more may be used in admixture. To discourage precipitation of the polyamic acid, the polyamic acid concentration within the solvent in the above esterification reaction is preferably from 1 to 30 wt %, and more preferably from 5 to 20 wt %.

(2) Preparation by Reaction of Diamine Component with Tetracarboxylic Acid Diester Dichloride

This is a method which, for example, reacts the diamine component with a tetracarboxylic acid diester dichloride in the presence of a base and a solvent at between −20° C. and 150° C. (preferably between 0° C. and 50° C.) for a period of from 30 minutes to 24 hours (preferably from 1 to 4 hours). The base that is used may be, for example, pyridine, triethylamine or 4-dimethylaminopyridine. Of these, for the reaction to proceed calmly, pyridine is preferred. The amount of base used is preferably an amount that can be easily removed following the reaction, this amount being preferably from 2 to 4 moles, and more preferably from 2 to 3 moles, per mole of the tetracarboxylic acid diester dichloride.

Examples of the solvent used include, from the standpoint of the solvent solubility of the polymer used, i.e., the polyamic acid alkyl ester, the solvents used in the above-described reaction between the diamine component and the tetracarboxylic acid component. Of these, N,N-dimethylformamide, N,N-diethylformamide, N-methyl-2-pyrrolidone, N-ethyl-2-pyrrolidone, N,N-dimethylacetamide, N,N-diethylacetamide, 3-methoxy-N,N-dimethylpropanamide and γ-butyrolactone are preferred. One of these solvents may be used alone or two or more may be used in admixture.

To discourage precipitation of the polyamic acid alkyl ester, the polyamic acid alkyl ester concentration within the solvent in the reaction is preferably from 1 to 30 wt %, and more preferably from 5 to 20 wt %. To prevent hydrolysis of the tetracarboxylic acid diester dichloride, the solvent used in preparing the polyamic acid alkyl ester is preferably one that has been dehydrated to the extent possible. In addition, it is preferable to carry out the reaction in a nitrogen atmosphere and thus prevent the admixture of outside air.

(3) Preparation by Reaction of Diamine Component with Tetracarboxylic Acid Diester

This is a method which, for example, carries out a polycondensation reaction between the diamine component and a tetracarboxylic acid diester in the presence of a condensing agent, a base and a solvent at between 0° C. and 150° C. (preferably between 0° C. and 100° C.) for a period of from 30 minutes to 24 hours (preferably from 3 to 15 hours).

Examples of compounds that may be used as the condensing agent include triphenyl phosphite, dicyclohexylcarbodiimide, 1-ethyl-3-(3-dimethylaminopropyl)carbodiimide hydrochloride, N,N′-carbonyl diimidazole, dimethoxy-1,3,5-triazinyl methyl morpholinium, O-(benzotriazol-1-yl)-N,N,N′,N′-tetramethyluronium tetrafluoroborate, O-(benzotriazol-1-yl)-N,N,N′,N′-tetramethyluronium hexafluorophosphate and diphenyl (2,3-dihydro-2-thioxo-3-benzoxazolyl)phosphate. The amount of condensing agent used is preferably from 2 to 3 moles, especially from 2 to 2.5 moles, per mole of the tetracarboxylic acid diester.

A tertiary amine such as pyridine or triethylamine may be used as the base. The amount of base used is preferably an amount that can be easily removed following the polycondensation reaction. The amount is preferably from 2 to 4 moles, and more preferably from 2 to 3 moles, per mole of the diamine component. From the standpoint of the solvent solubility of the resulting polymer, i.e., the polyamic acid alkyl ester, the solvent used in the polycondensation reaction is exemplified by the solvents used in the above reaction between the diamine component and the tetracarboxylic acid component. Of these, N,N-dimethylformamide, N-methyl-2-pyrrolidone, N-ethyl-2-pyrrolidone or γ-butyrolactone is preferred. One of these solvents may be used alone or two or more may be used in admixture.

The reaction proceeds efficiently with the addition of a Lewis acid as an additive to the polycondensation reaction. The Lewis acid is preferably a lithium halide such as lithium chloride or lithium bromide. The Lewis acid is used in an amount of from 0.1 to 10 moles per mole of the diamine component. From 2.0 to 3.0 moles is more preferred.

When recovering the polyamic acid alkyl ester from the polyamic acid alkyl ester solution obtained by above methods (1) to (3), precipitation may be induced by pouring the reaction solution into a solvent. Examples of the solvent used for precipitation include water, methanol, ethanol, 2-propanol, hexane, butyl cellosolve, acetone and toluene. The polymer that has been precipitated out by pouring the solution into a solvent is preferably subjected to a plurality of washing operations with the above solvent in order to remove the additives and catalysts used as described above. After washing, filtration and recovery, the polymer may be dried under normal pressure or reduced pressure and at normal temperature or under heating. Alternatively, by subjecting the precipitated and recovered polymer repeatedly, i.e., from 2 to 10 times, to redissolution in a solvent, reprecipitation and recovery, the level of impurities within the polymer can be reduced. Preparation method (2) or (3) is preferred for polyamic acid alkyl esters.

### <Other Charge Transporting Substances>

A conductive polymer such as polythiophene or polyaniline may be included in the charge transporting composition of the invention in order to adjust the charge transportability of the charge transporting layer.

Examples of conductive polymers such as polythiophene and polyaniline include conductive polymers containing recurring units of formula (3) or (4) below.

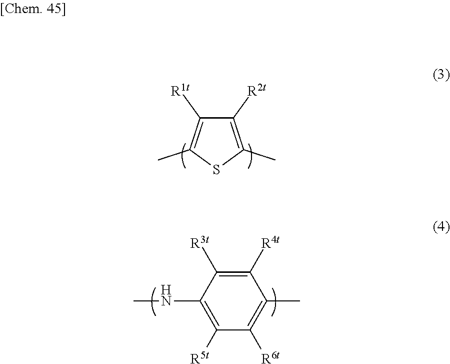

In these formulas, R^{1t} and R^{2t} are each independently a hydrogen atom, an alkyl group of 1 to 40 carbon atoms, a fluoroalkyl group of 1 to 40 carbon atoms, an alkoxy group of 1 to 40 carbon atoms, a fluoroalkoxy group of 1 to 40 carbon atoms, an aryloxy group of 6 to 20 carbon atoms, —O—[Z—O]ₚ—R^{e}, a sulfonic group, a sulfonate group or a sulfonic ester group, or R² and R³ are bonded to each other, forming —O—Y—O— in which Y is an alkylene group of 1 to 40 carbon atoms that may include an ether bond and may be substituted with a sulfonic group, sulfonate group or sulfonic ester group represented by the formula (S) below; Z is an alkylene group of 1 to 40 carbon atoms which may be substituted with a halogen atom; p is an integer of 1 or more; and R^{e} is a hydrogen atom, an alkyl group of 1 to 40 carbon atoms, a fluoroalkyl group of 1 to 40 carbon atoms or an aryl group of 6 to 20 carbon atoms.

R^{3t} to R^{6t} are each independently a hydrogen atom, an alkyl group of 1 to 40 carbon atoms, a fluoroalkyl group of 1 to 40 carbon atoms, an alkoxy group of 1 to 40 carbon atoms, a fluoroalkoxy group of 1 to 40 carbon atoms, a hydroxyl group, a carboxyl group, or a sulfonic group, sulfonate group or sulfonic ester group represented by the formula (S) below.

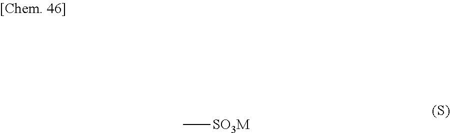

In this formula, M is a hydrogen atom, an alkali metal selected from the group consisting of lithium, sodium and potassium, NH(R^{S})₃, an alkyl group or fluoroalkyl group of 1 to 5 carbon atoms or HNC₅H₅, each R^{S} being independently a hydrogen atom or an alkyl group of 1 to 6 carbon atoms which may have a substituent.

In cases where R^{S} is an alkyl group having a substituent, the substituent is exemplified by alkyl groups of 1 to 6 carbon atoms, alkoxy groups of 1 to 6 carbon atoms, aryl groups of 6 to 20 carbon atoms, hydroxyl groups, amino groups and carboxyl groups.

The alkyl groups of 1 to 6 carbon atoms are exemplified by the same groups as already mentioned in connection with the above-described alkyl groups.

Specific examples of alkoxy groups of 1 to 6 carbon atoms include methoxy, ethoxy, n-propoxy, i-propoxy and n-butoxy groups. Specific examples of aryl groups of 6 to 20 carbon atoms include phenyl, tolyl, 1-naphthyl, 2-naphthyl, 1-anthryl, 2-anthryl, 9-anthryl, 1-phenanthryl, 2-phenanthryl, 3-phenanthryl, 4-phenanthryl and 9-phenanthryl groups.

A hydroxyl group is especially preferred as the substituent. Specific examples of alkyl groups having a hydroxyl group include 2-hydroxyethyl, 3-hydroxypropyl, 2-hydroxypropyl and 2,3-dihydroxypropyl groups.

Of these, R^{S} is preferably a hydrogen atom or a linear or branched alkyl group of 1 to 3 carbon atoms. A hydrogen atom or a methyl group is more preferred.

In above formula (3), it is preferable for R^{1t} and R^{2t} to be each independently a hydrogen atom, a fluoroalkyl group of 1 to 40 carbon atoms, an alkoxy group of 1 to 40 carbon atoms, —O[C(R^{a}R^{b})—C(R^{c}R^{d})—O]ₚ—R^{e}, —OR^{f}, a sulfonic group, a sulfonate group or a sulfonic ester group, or for R^{1t} and R^{2t} to be bonded to each other, forming —O—Y—O—.

R^{a} to R^{d} are each independently a hydrogen atom, an alkyl group of 1 to 40 carbon atoms, a fluoroalkyl group of 1 to 40 carbon atoms or an aryl group of 6 to 20 carbon atoms.

Of these, it is preferable for R^{a} to R^{d} to be each independently a hydrogen atom, an alkyl group of 1 to 8 carbon atoms, a fluoroalkyl group of 1 to 8 carbon atoms or a phenyl group.

R^{e} represents a hydrogen atom, an alkyl group of 1 to 40 carbon atoms, a fluoroalkyl group of 1 to 40 carbon atoms or an aryl group of 6 to 20 carbon atoms.

Of these, R^{e} is preferably a hydrogen atom, an alkyl group of 1 to 8 carbon atoms, a fluoroalkyl group of 1 to 8 carbon atoms, or a phenyl group. A hydrogen atom or a methyl, propyl or butyl group is more preferred.

Also, the subscript p is preferably from 1 to 5, and more preferably 1, 2 or 3.

R^{f} is a hydrogen atom, an alkyl group of 1 to 40 carbon atoms, a fluoroalkyl group of 1 to 40 carbon atoms or an aryl group of 6 to 20 carbon atoms; preferably a hydrogen atom, an alkyl group of 1 to 8 carbon atoms, a fluoroalkyl group of 1 to 8 carbon atoms or a phenyl group; and more preferably —CH₂CRF₃.

In this invention, R^{1t} is preferably a hydrogen atom or a sulfonic group or sulfonate group, and more preferably a sulfonic group, sulfonate group or sulfonic ester group; and R^{2t} is preferably an alkoxy group of 1 to 40 carbon atoms or —O—[Z—O]ₚ—R^{e}, more preferably —O[C(R^{a}R^{b})—C(R^{c}R^{d})—O]ₚ—R^{e} or —OR^{f}, and even more preferably —O[C(R^{a}R^{b})—C(R^{c}R^{d})—O]ₚ—R^{e}, —O—CH₂CH₂—O—CH₂CH₂—O—CH₃, O—CH₂CH₂—O—CH₂CH₂—OH or —O—CH₂CH₂—OH. Alternatively, R^{1t} and R^{2t} are bonded to each other, forming —O—Y—O—.

For example, the above polythiophene derivative according to a preferred embodiment of the invention includes recurring units in which R^{1t} is a sulfonic group, sulfonate group or sulfonic acid ester group and R^{2t} is a group other than a sulfonic group, sulfonate group or sulfonic ester group, or includes recurring units in which R^{1t} and R^{2t} are bonded to each other, forming —O—Y—O—.

The polythiophene derivative includes preferably recurring units in which R^{1t} is a sulfonic group, sulfonate group or sulfonic ester group and R^{2t} is an alkoxy group of 1 to 40 carbon atoms or —O—[Z—O]ₚ—R^{e}, or includes recurring units in which R^{1t} and R^{2t} are bonded to each other, forming —O—Y—O—.

The polythiophene derivative includes more preferably recurring units in which R^{1t} is a sulfonic group, sulfonate group or sulfonic ester group and R^{2t} is —O[C(R^{a}R^{b})—C(R^{c}R^{d})—O]ₚ—R^{e} or —OR^{f}.

The polythiophene derivative includes even more preferably recurring units in which R^{1t} is a sulfonic group, sulfonate group or sulfonic ester group and R^{2t} is —O[C(R^{a}R^{b})—C(R^{c}R^{d})—O]ₚ—R^{e}, or includes recurring units in which R¹ and R² are bonded to each other, forming —O—Y—O—.

The polythiophene derivative includes still more preferably recurring units in which R^{1t} is a sulfonic group, sulfonate group or sulfonic ester group and R² is —O—CH₂CH₂—O—CH₂CH₂—O—CH₃, —O—CH₂CH₂—O—CH₂CH₂—OH or —O—CH₂CH₂—OH, or includes recurring units in which R^{1t} and R^{2t} are bonded to each other, forming a group of formula (Y1) below

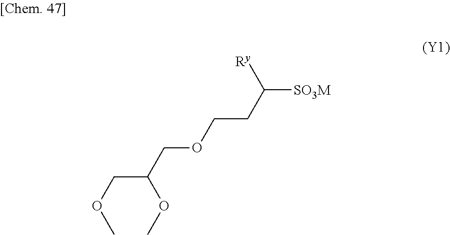

(wherein R^{y} is an alkyl group of 1 to 6 carbon atoms or a fluorine atom, and M is the same as above).

The alkyl group of 1 to 6 carbon atoms represented by R^{y} is exemplified by the same groups as mentioned in the description of R^{1t} and R^{2t}. Alkyl groups of 1 to 3 carbon atoms are preferred, methyl and ethyl groups are more preferred, and a methyl group is still more preferred.

Specific preferred examples of the polythiophene derivative include polythiophenes having at least one type of recurring unit represented by formulas (3-1) to (3-4) below. Polythiophenes containing recurring units of formula (3-4) below are more preferred in particular because a good conductivity can be reproducibly obtained and the solubility in solvents is high.

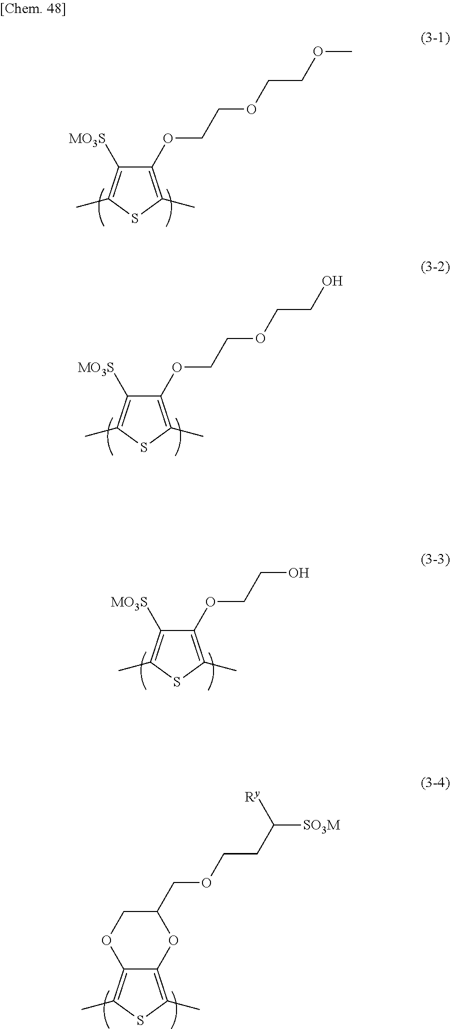

In these formulas, R^{y} and M are the same as indicated above.

With regard to suitable structures for the above polythiophene derivative, examples include polythiophene derivatives which have a structure represented by formula (3a) below. In the following formula, the units may be randomly bonded or may be bonded as a block polymer.

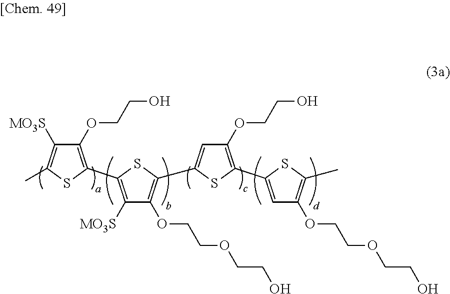

In the above formula, the subscripts ‘a’ to ‘d’ represent the molar ratios of the respective units and satisfy the conditions 0≤a≤1, 0≤b≤1, 0<a+b≤1, 0≤c<1, 0≤d<1 and a+b+c+d=1. M is the same as above.

The above polythiophene derivative may be a homopolymer or a copolymer (including statistical, random, gradient and block copolymers). Polymers containing monomer A and monomer B include such block copolymers as A-B diblock copolymers, A-B-A triblock copolymers and (AB)ₘ multiblock copolymers. The polythiophene may include recurring units derived from other types of monomers (e.g., thienothiophene, selenophene, pyrrole, furan, tellurophene, aniline, arylamines and arylenes (phenylene, phenylene-vinylene and fluorene, etc.)).

In this invention, the content of recurring units of formula (3) in the polythiophene derivative is preferably more than 50 mol %, more preferably 80 mol % or more, even more preferably 90 mol % or more, still more preferably 95 mol % or more, and most preferably 100 mol %, of all the recurring units included in the polythiophene derivative.

The content of recurring units having a sulfonic group, sulfonate group or sulfonic ester group is preferably 10 mol % or more, more preferably 30 mol % or more, even more preferably 50 mol % or more, and still more preferably 100 mol %, of the recurring units of formula (3) in the polythiophene derivative.

In the practice of the invention, depending on the purity of the starting monomer used in polymerization, the polymer that is formed may contain recurring units derived from impurities. In this invention, the above term “homopolymer” signifies a polymer which contains recurring units derived from one type of monomer, although recurring units derived from impurities may also be included. The above-described polythiophene derivative is preferably a polymer in which basically all the recurring units are recurring units of above formula (3), and is more preferably a polymer containing at least one recurring unit of above formulas (3-1) to (3-4).

In the invention, when the polythiophene derivative includes recurring units having a sulfonic group, to further enhance the solubility or dispersibility in a solvent, it is preferable to render the polythiophene derivative into an amine adduct in which an amine compound has been added to at least some of the sulfonic groups included in the polythiophene derivative.

Amine compounds that can be used to form the amine adduct are exemplified by primary amine compounds, including monoalkylamine compounds such as methylamine, ethylamine, n-propylamine, isopropylamine, n-butylamine, isobutylamine, s-butylamine, t-butylamine, n-pentylamine, n-hexylamine, n-heptylamine and n-octylamine, and monoarylamine compounds such as aniline and tolylamine; secondary amine compounds, including dialkylamine compounds such as N-ethylmethylamine, N-methyl-n-propylamine, N-methylisopropylamine, N-methyl-n-butylamine, N-methyl-s-butylamine, N-methyl-t-butylamine, N-methylisobutylamine, diethylamine, N-ethyl-n-propylamine, N-ethylisopropylamine, N-ethyl-n-butylamine, N-ethyl-s-butylamine, N-ethyl-t-butylamine, dipropylamine, N-n-propylisopropylamine, N-n-propyl-n-butylamine, N-n-propyl-s-butylamine, aziridine (ethylenimine), 2-methylaziridine (propylenimine), 2,2-dimethylaziridine, azetidine (trimethylenimine), 2-methylazetidine, pyrrolidine, 2-methylpyrrolidine, 3-methylpyrrolidine, 2,5-dimethylpyrrolidine, piperidine, 2,6-dimethylpiperidine, 3,5-dimethylpiperidine, 2,2,6,6-tetramethylpiperidine, hexamethylenimine, heptamethylenimine and octamethylenimine, and alkylarylamine compounds such as diphenylamine and indoline; and trialkylamine compounds such as N,N-dimethylethylamine, N,N-dimethyl-n-propylamine, N,N-dimethylisopropylamine, N,N-dimethyl-n-butylamine, N,N-dimethyl-s-butylamine, N,N-dimethyl-t-butylamine, N,N-dimethylisobutylamine, N,N-diethylmethylamine, N-methyldi(n-propyl)amine, N-methyldiisopropylamine, triethylamine, N,N-diethyl-n-butylamine, N,N-diisopropylethylamine, N,N-di(n-butyl)ethylamine, 1-methylacetidine, 1-methylpyrrolidine and 1-methylpiperidine. Taking into account the balance between, for example, the solubility of the amine adduct and the charge transportability of the charge-transporting thin film that is obtained, a tertiary amine compound is preferred, a trialkylamine compound is more preferred, and triethylamine is still more preferred.

The amine adduct can be obtained by pouring the polythiophene derivative into the amine itself or into a solution of the amine and thoroughly stirring.

In above formula (4), R^{3t} to R^{6t} are each independently a hydrogen atom, an alkyl group of 1 to 40 carbon atoms, a fluoroalkyl group of 1 to 40 carbon atoms, an alkoxy group of 1 to 40 carbon atoms, a fluoroalkoxy group of 1 to 40 carbon atoms, a hydroxyl group, a carboxyl group, a sulfonic group, a sulfonate group or a sulfonic ester group.

Typical examples of the polyaniline of formula (4) include polyanilines containing structures from sulfone-substituted anilines or carboxy-substituted anilines.

Of these, in terms of, for example, polymer conductivity and solubility, the polyaniline preferably includes structures in which an acidic group such as a sulfonic group or a carboxyl group is bonded to an amino group at the ortho or meta position.

The above sulfone-substituted aniline structure is most typically an aminobenzenesulfonic acid. From the standpoint of polymer conductivity, solubility and the like, o-aminobenzenesulfonic acid, m-aminobenzenesulfonic acid, p-aminobenzenesulfonic acid, aniline-2,6-disulfonic acid, aniline-2,5-disulfonic acid, aniline-3,5-disulfonic acid, aniline-2,4-disulfonic acid and aniline-3,4-disulfonic acid are preferred.

Examples of sulfone-substituted anilines other than aminobenzenesulfonic acids include alkyl-substituted aminobenzenesulfonic acids such as methylaminobenzenesulfonic acid, ethylaminobenzenesulfonic acid, n-propylaminobenzenesulfonic acid, iso-propylaminobenzenesulfonic acid, n-butylaminobenzenesulfonic acid, sec-butylaminobenzenesulfonic acid and t-butylaminobenzenesulfonic acid; alkoxy-substituted aminobenzenesulfonic acids such as methoxyaminobenzenesulfonic acid, ethoxyaminobenzenesulfonic acid and propoxyaminobenzenesulfonic acid; and hydroxy-substituted aminobenzenesulfonic acids.

Of these, alkyl-substituted aminobenzenesulfonic acids, hydroxy-substituted aminobenzenesulfonic acids and halogen-substituted aminobenzenesulfonic acids are most preferred when taking into account the conductivity and solubility of the resulting polyaniline. These sulfone-substituted anilines may include two or more structures in any ratio.

The above carboxy-substituted aniline is most typically an aminobenzenecarboxylic acid. From the standpoint of the conductivity and solubility of the resulting polymer, o-aminobenzenecarboxylic acid, m-aminobenzenecarboxylic acid, p-aminobenzenecarboxylic acid, aniline-2,6-dicarboxylic acid, aniline-2,5-dicarboxylic acid, aniline-3,5-dicarboxylic acid, aniline-2,4-dicarboxylic acid and aniline-3,4-dicarboxylic acid are preferred.

Examples of carboxy-substituted anilines other than aminobenzenecarboxylic acids include alkyl-substituted aminobenzenecarboxylic acids such as methylaminobenzenecarboxylic acid, ethylaminobenzenecarboxylic acid, n-propylaminobenzenecarboxylic acid, iso-propylaminobenzenecarboxylic acid, n-butylaminobenzenecarboxylic acid, sec-butylaminobenzenecarboxylic acid and t-butylaminobenzenecarboxylic acid; alkoxy-substituted aminobenzenecarboxylic acids such as methoxyaminobenzenecarboxylic acid, ethoxyaminobenzenecarboxylic acid and propoxyaminobenzenecarboxylic acid; and hydroxy-substituted aminobenzenecarboxylic acids. Of these, alkyl-substituted aminobenzenecarboxylic acids and alkoxy-substituted aminobenzenecarboxylic acids are most preferred from the standpoint of the conductivity and solubility of the resulting polymer.

These carboxy-substituted anilines may be of one type used alone, or two or more structures may be included in any ratio.

In some of the recurring units that make up conductive polymers such as polythiophenes and polyanilines, the chemical structure is sometimes an oxidized type structure called a “quinoid structure.” The term ‘quinoid structure’ is used in contrast with the term ‘benzenoid structure. Unlike the latter, which is a structure that includes an aromatic ring, the former refers to a structure in which a double bond inside the aromatic ring has moved out of the ring (resulting in disappearance of the aromatic ring) and two exocyclic double bonds that are conjugated with the other double bonds remaining within the ring have formed. To one of ordinary skill in the art, the relationship between these two structures will be readily apparent from the relationship between a benzoquinone structure and a hydroquinone structure. Quinoid structures for recurring units in various conjugated polymers are familiar to persons skilled in the art. For example, formula (3′) below shows the quinoid structure corresponding to the recurring units in a polythiophene derivative containing recurring units of formula (3) above.

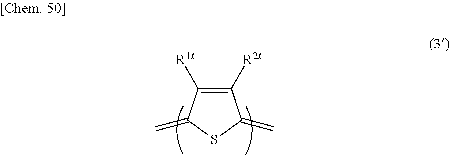

In formula (3′), R^{1t} and R^{2t} are as defined in formula (3) above.

The weight-average molecular weight of conductive polymers such as polythiophenes or polyanilines is preferably from about 1,000 to about 1,000,000, more preferably from about 5,000 to about 100,000, and even more preferably from about 10,000 to about 50,000.

The conductive polymer having recurring units of formula (3) or formula (4) that is used may be a commercial product, or may be one that has been polymerized by a known method using, for example, a thiophene derivative or an aniline derivative as the starting material.

Examples of commercial products include SELFTRON® from Tosoh Corporation and aquaPASS from Mitsubishi Chemical Corporation.

### <Charge Transporting Composition>

The charge transporting composition of the invention includes the above-described specific polymer, and may include two or more specific polymers of differing structures. In addition to the specific polymer, the composition may include another polymer; that is, a polymer which does not have divalent groups of formula (1) or (2) (a polymer obtained without including the specific diamine of formula (1) or (2)). The polymer may be in the form of, for example, a polyamic acid, polyimide, polyamic acid ester, polyester, polyamide, polyurea, polyorganosiloxane, cellulose derivative, polyacetal, polystyrene or derivative thereof, poly(styrene-phenyl maleimide) derivative or poly(meth)acrylate. In cases where the charge transporting composition of the invention includes another polymer, the ratio of the specific polymer to the total polymer components is preferably 50 wt % or more, such as from 70 to 99.9 wt %.

From the standpoint of forming a uniform thin film, the charge transporting composition generally takes the form of a coating fluid. The charge transporting composition of the invention is preferably a coating fluid that includes the above polymer component and an organic solvent which dissolves this polymer component. The polymer concentration within the charge transporting composition can be suitably changed according to the intended thickness of the coating film to be formed. From the standpoint of forming a uniform, defect-free film, and taking into account such considerations as the shelf stability of the solution, the concentration is preferably 1 wt % or more and preferably not more than 10 wt %. It is especially preferable for the polymer concentration to be from 2 to 8 wt %.

The organic solvent included in the charge transporting composition is not particularly limited, so long as it is one that uniformly dissolves the polymer component. Specific examples include N,N-dimethylformamide, N,N-dimethylacetamide, N-methyl-2-pyrrolidone, N-ethyl-2-pyrrolidone, dimethylsulfoxide, N,N-diethylformamide, N,N-diethylformamide, 3-methoxy-N,N-dimethylpropanamide, γ-butyrolactone, 1,3-dimethylimidazolidinone, methyl ethyl ketone, cyclohexanone and cyclopentanone. Of these, the use of N-methyl-2-pyrrolidone, N-ethyl-2-pyrrolidone, 3-methoxy-N,N-dimethylpropanamide or γ-butyrolactone is preferred.

In addition to the above solvents, the organic solvent included in the charge transporting composition of the invention may also use a solvent which enhances the coatability when applying the charge transporting composition and the surface smoothness of the resulting film. Specific, not-limiting, examples of such organic solvents include those mentioned below.

Examples include ethanol, isopropyl alcohol, 1-butanol, 2-butanol, isobutyl alcohol, tert-butyl alcohol, 1-pentanol, 2-pentanol, 3-pentanol, 2-methyl-1-butanol, isopentyl alcohol, tert-pentyl alcohol, 3-methyl-2-butanol, neopentyl alcohol, 1-hexanol, 2-methyl-1-pentanol, 2-methyl-2-pentanol, 2-ethyl-1-butanol, 1-heptanol, 2-heptanol, 3-heptanol, 1-octanol, 2-octanol, 2-ethyl-1-hexanol, cyclohexanol, 1-methylcyclohexanol, 2-methylcyclohexanol, 3-methylcyclohexanol, 2,6-dimethyl-4-heptanol, 1,2-ethanediol, 1,2-propanediol, 1,3-propanediol, 1,2-butanediol, 1,3-butanediol, 1,4-butanediol, 2,3-butanediol, 1,5-pentanediol, 2-methyl-2,4-pentanediol, 2-ethyl-1,3-hexanediol, diisopropyl ether, dipropyl ether, dibutyl ether, dihexyl ether, dioxane, ethylene glycol dimethyl ether, ethylene glycol diethyl ether, ethylene glycol dibutyl ether, 1,2-butoxyethane, diethylene glycol dimethyl ether, diethylene glycol diethyl ether, 4-hydroxy-4-methyl-2-pentanone, diethylene glycol methyl ethyl ether, diethylene glycol dibutyl ether, 2-pentanone, 3-pentanone, 2-hexanone, 2-heptanone, 4-heptanone, 2,6-dimethyl-4-heptanone, 4,6-dimethyl-2-heptanone, 3-ethoxybutyl acetate, 1-methylpentyl acetate, 2-ethylbutyl acetate, 2-ethylhexyl acetate, ethylene glycol monoacetate, ethylene glycol diacetate, propylene carbonate, ethylene carbonate, 2-(methoxymethoxy)ethanol, ethylene glycol monobutyl ether, ethylene glycol monoisoamyl ether, ethylene glycol monohexyl ether, 2-(hexyloxy)ethanol, furfuryl alcohol, diethylene glycol, propylene glycol, propylene glycol monobutyl ether, 1-(butoxyethoxy)propanol, propylene glycol monomethyl ether acetate, dipropylene glycol, diethylene glycol monoethyl ether, diethylene glycol monomethyl ether, dipropylene glycol monomethyl ether, dipropylene glycol monoethyl ether, dipropylene glycol dimethyl ether, tripropylene glycol monomethyl ether, ethylene glycol monomethyl ether acetate, ethylene glycol monoethyl ether acetate, ethylene glycol monobutyl ether acetate, ethylene glycol monoacetate, ethylene glycol diacetate, diethylene glycol monoethyl ether acetate, diethylene glycol monobutyl ether acetate, 2-(2-ethoxyethoxy)ethylacetate, diethylene glycol acetate, triethylene glycol, triethylene glycol, monomethyl ether, triethylene glycol monoethyl ether, methyl lactate, ethyl lactate, methyl acetate, ethyl aetate, n-butyl acetate, propylene glycol monoethyl ether acetate, methyl pyruvate, ethyl pyruvate, methyl 3-methyoxypropionate, ethyl 3-ethoxypropionate, methyl ethyl 3-ethoxypropionate, ethyl 3-methoxypropionate, 3-ethoxypropionic acid, 3-methoxypropionic acid, propyl 3-methoxypropionate, butyl 3-methoxypropionate, methyl lactate, ethyl lactate, n-propyl lactate, n-butyl lactate, isoamyl lactate, and the solvents of formulas [D-1] to [D-4] above.

Of these, the organic solvent used is preferably 1-hexanol, cyclohexanol, 1,2-ethanediol, 1,2-propanediol, propylene glycol monobutyl ether, diethylene glycol diethyl ether, 4-hydroxy-4-methyl-2-pentanone, ethylene glycol monobutyl ether or dipropylene glycol dimethyl ether. The type and content of such solvents is suitably selected according to, for example, the coating equipment, coating conditions and coating environment when applying the charge transporting composition.

The charge transporting composition of the invention may additionally include ingredients other than the polymer component and the organic solvent. Examples of such additional ingredients include adhesive modifiers for increasing adhesion between the charge transporting layer and the substrate and crosslinking agents for increasing the strength of the charge transporting layer. Specific examples of these additional ingredients include the poor solvents and the crosslinkable compounds disclosed in paragraphs [0104] to [0116] of WO 2015/060357 A1.

In addition to the above, polymers other than the specific polymer mentioned in this invention, silane coupling agents for enhancing adhesion between the charge transporting layer and the substrate, crosslinking compounds for increasing the film hardness and density when the composition has been formed into a charge transporting layer, and imidization accelerators for efficiently promoting the imidization reaction due to heating of the polyimide precursor when the applied film is baked may be included in the charge transporting composition of the invention.

Compounds that increase adhesion between the charge transporting composition and the substrate are exemplified by functional silane-containing compounds and epoxy group-containing compounds. Examples include 3-aminopropyltrimethoxysilane, 3-aminopropyltriethoxysilane, 3-glycidoxypropyltriethoxysilane, 3-glycidoxypropyltrimethoxysilane, 3-glycidoxypropylmethyldiethoxysilane, 2-aminopropyltrimethoxysilane, 2-aminopropyltriethoxysilane, N-(2-aminoethyl)-3-aminopropyltrimethoxysilane, N-(2-aminoethyl)-3-aminopropylmethyldimethoxysilane, 3-ureidopropyltrimethoxysilane, 3-ureidopropyltriethoxysilane, N-ethoxycarbonyl-3-aminopropyltrimethoxysilane, N-ethoxycarbonyl-3-aminopropyltriethoxysilane, N-triethoxysilylpropyltriethylenetriamine, N-trimethoxysilylpropyltriethylenetriamine, 10-trimethoxysilyl-1,4,7-triazadecane, 10-triethoxysilyl-1,4,7-triazadecane, 9-trimethoxysilyl-3,6-diazanonyl acetate, 9-triethoxysilyl-3,6-diazanonyl acetate, N-benzyl-3-aminopropyltrimethoxysilane, N-benzyl-3-aminopropyltriethoxysilane, N-phenyl-3-aminopropyltrimethoxysilane, N-phenyl-3-aminopropyltriethoxysilane, N-bis(oxyethylene)-3-aminopropyltrimethoxysilane, N-bis(oxyethylene)-3-aminopropyltriethoxysilane, ethylene glycol diglycidyl ether, polyethylene glycol diglycidyl ether, propylene glycol diglycidyl ether, tripropylene glycol diglycidyl ether, polypropylene glycol diglycidyl ether, neopentyl glycol diglycidyl ether, 1,6-hexanediol diglycidyl ether, glycerol diglycidyl ether, 2,2-dibromoneopentyl glycol diglycidyl ether, 1,3,5,6-tetraglycidyl-2,4-hexanediol, N,N,N′,N′-tetraglycidyl-m-xylenediamine, 1,3-bis(N,N-diglycidylaminomethyl)cyclohexane and N,N,N′,N′-tetraglycidyl-4,4′-diaminodiphenylmethane.

Additives such as the following may be added to the charge transporting composition of the invention in order to increase the mechanical strength of the resulting charge transporting thin film.

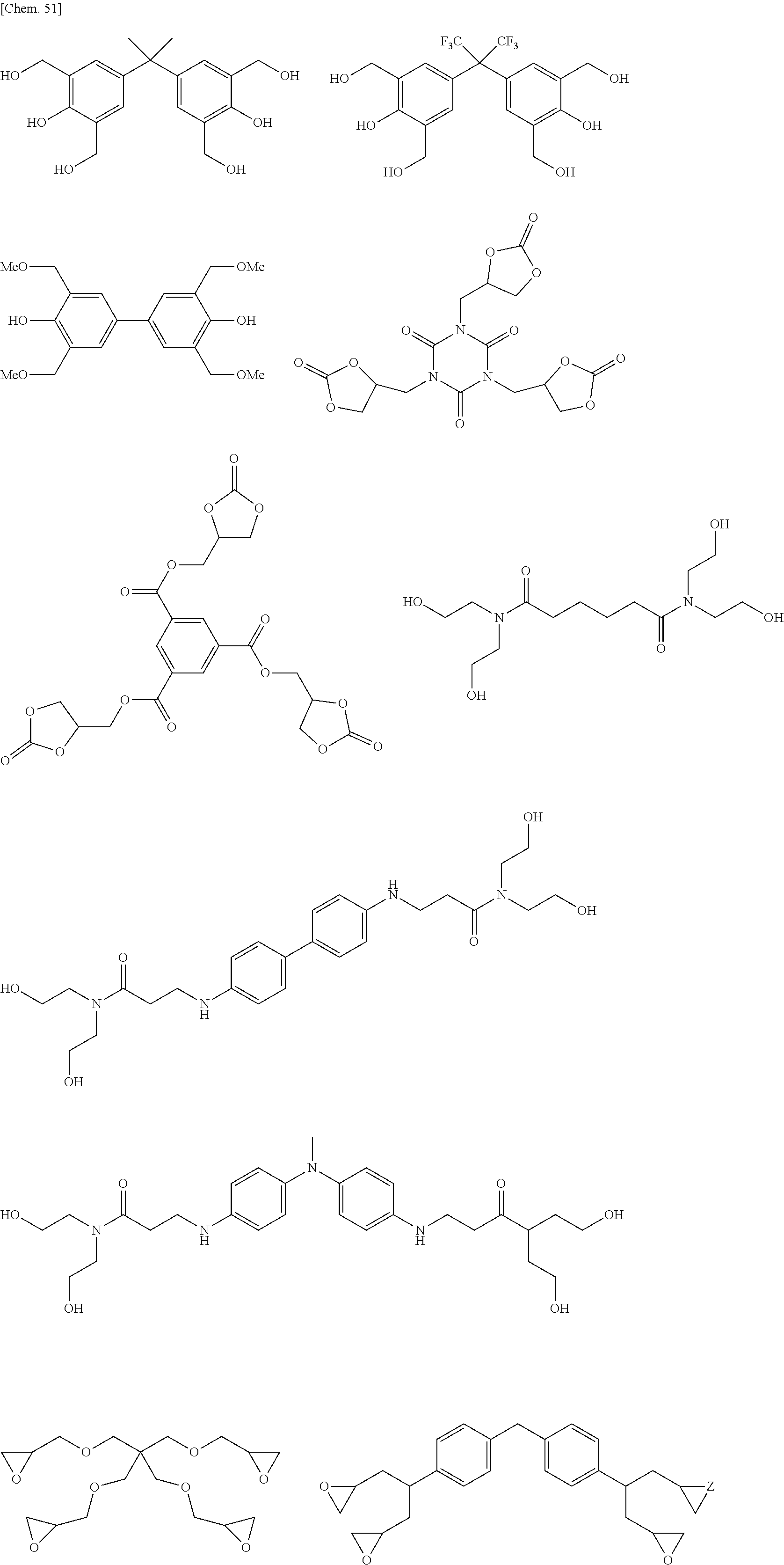

The amount of the above additive is preferably from 0.1 to 30 parts by weight per 100 parts by weight of the polymer component included in the charge transporting composition. Including less than 0.1 part by weight is unlikely to be effective, and including more than 30 parts by weight may lower the charge transportability. The amount is more preferably from 0.5 to 20 parts by weight.

In addition, amine-type additives such as those mentioned in paragraphs [0075] to [0079] of WO 2008/013285 A1 may be added to the charge transporting composition of the invention in order to enhance the stability and uniformity of the charge transporting composition.

The hole collecting layer of the invention can be formed by coating the above-described hole collecting layer-forming composition onto the anode of an optical sensor and then baking the composition, although the invention is not limited thereby.

In coating, the optimal technique from among various types of wet processes such as drop casting, spin coating, blade coating, dip coating, roll coating, bar coating, die coating, inkjet coating and printing methods (e.g., relief printing, intaglio printing, lithography, screen printing) may be used while taking into account, for example, the viscosity and surface tension of the composition and the desired thickness of the thin film.

Coating is typically carried out in an inert gas atmosphere at normal temperature and pressure, although it may be carried out in an open-air atmosphere (in the presence of oxygen) or may be carried out under heating, provided that the compounds within the composition do not decompose and the composition does not undergo any large change in makeup.

The film thickness is generally from about 1 nm to about 300 nm, and preferably from about 30 nm to about 200 nm. Methods for changing the film thickness include ones that involve changing the solids concentration within the composition and ones that involve changing the amount of solution applied during coating.

A method for fabricating an optical sensor using the hole collecting layer-forming composition of the invention is described below.

### [Formation of Anode Layer]: Step of Producing Transparent Electrode by Forming Layer of Anode Material on Surface of Transparent Substrate

A metal oxide such as indium-tin oxide (ITO) or indium-zinc oxide (IZO) or an organic compound having high charge transportability, such as a polythiophene derivative or a polyaniline derivative, may be used as the anode material. A substrate made of glass or a clear plastic may be used as the transparent substrate.

The method of forming the layer of anode material (anode layer) is suitably selected according to the nature of the anode material. A dry process that uses a sublimable compound (vapor deposition) or a wet process that uses a charge transporting compound-containing varnish (especially spin coating or slit coating) is generally employed.

Alternatively, a commercial product may be used as the transparent electrode. In this case, from the standpoint of increasing the device yield, the use of a substrate that has been subjected to smoothing treatment is preferred. When a commercial product is used, the method for fabricating the organic thin-film solar cell of the invention does not include an anode layer-forming step.

The transparent electrode is preferably used after being cleaned with, for example, a cleaning agent, alcohol or pure water. For example, in the case of an anode substrate, the substrate is preferably subjected to surface treatment such as UV/ozone treatment or oxygen-plasma treatment just prior to use (in cases where the anode material is composed primarily of an organic substance, surface treatment need not be carried out).

### [Formation of Hole Collecting Layer]: Step of Forming Hole Collecting Layer on Layer of Anode Material

Using the hole collecting layer-forming composition of the invention, a hole collecting layer is formed on the anode material layer in accordance with the above method.

### [Formation of Photoelectric Conversion Layer]: Step of Forming Photoelectric Conversion Layer on Hole Collecting Layer

The photoelectric conversion layer may be obtained by stacking an n-layer which is a thin film consisting of an n-type semiconductor material and a p-layer which is a thin film consisting of a p-type semiconductor material, or may be a non-stacked thin film consisting of a mixture of these materials.

Examples of n-type semiconductor materials include fullarene, [6,6]-phenyl-C₆₁ butyric acid methyl ester (PC₆₁BM) and [6,6]-phenyl-C₇₁ butyric acid methyl ester (PC₇₁BM). Examples of p-type semiconductor materials include polymers having a thiophene skeleton on the main chain, such as regioregular poly(3-hexylthiophene) (P3HT), PTB7, PDTP-DFBT, and the thienothiophene unit-containing polymers mentioned in JP-A 2009-158921 and WO 2010/008672 A1; phthalocyanines such as CuPC and ZnPC; and porphyrins such as tetrabenzoporphyrin.

Of these, PC₆₁BM and PC₇₁BM are preferred as the n-type material, and polymers having a thiophene skeleton on the main chain such as PTB7 are preferred as the p-type material.

Here, “thiophene skeleton on the main chain” refers to a divalent aromatic ring consisting solely of thiophene, or a divalent condensed aromatic ring containing one or more thiophene, such as thienothiophene, benzothiophene, dibenzothiophene, benzodithiophene, naphthothiophene, naphthodithiophene, anthrathiophene and anthradithiophene. These may be substituted with the substituents indicated as R¹ to R⁶ above.

The method of forming a photoelectric conversion layer is suitably selected according to the nature of the n-type semiconductor material or p-type semiconductor material. Typically, a dry process that uses a sublimable compound (especially vapor deposition) or a wet process that uses a varnish containing the material (especially spin coating or slit coating) is used.

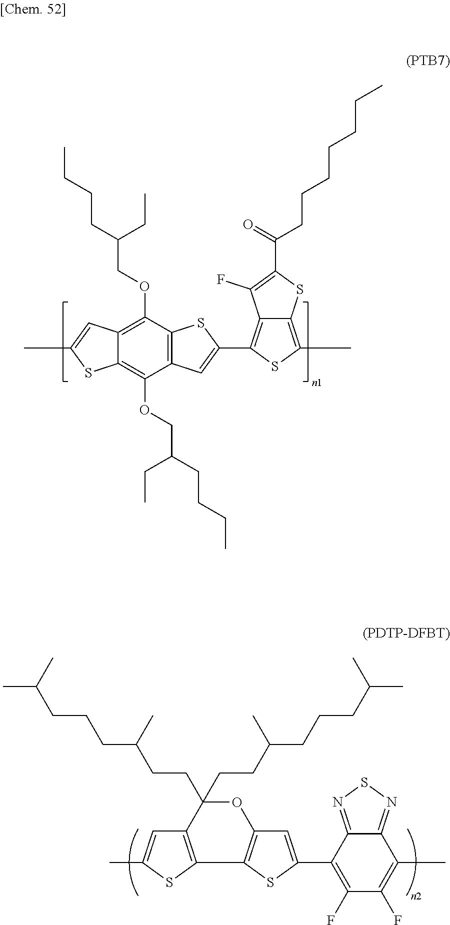

In the formulas, n1 and n2 are positive integers indicating the number of recurring units.

### [Formation of Electron Collecting Layer]: Step of Forming Electron Collecting Layer on Photoelectric Conversion Layer

Where necessary, an electron collecting layer may be formed between the photoelectric conversion layer and the cathode layer.

Illustrative examples of electron collecting layer-forming materials include lithium oxide (Li₂O), magnesium oxide (MgO), alumina (Al₂O₃), lithium fluoride (LiF), sodium fluoride (NaF), magnesium fluoride (MgF₂), strontium fluoride (SrF₂), cesium carbonate (Cs₂CO₃), lithium 8-quinolinolate (Liq), sodium 8-quinolinolate (Naq), bathocuproin (BCP), 4,7-diphenyl-1,10-phenanthroline (BPhen), polyethyleneimine (PEI) and ethoxylated polyethyleneimine (PEIE).

The method of forming the electron collecting layer is suitably selected according to the nature of the material therein. Typically, a dry process that uses a sublimable compound (especially vapor deposition) or a wet process that uses a varnish containing the material (especially spin coating or slit coating) is used.

### [Formation of Cathode Layer]: Step of Forming Cathode Layer on Electron Collecting Layer

Illustrative examples of cathode materials include aluminum, magnesium-silver alloys, aluminum-lithium alloys, lithium, sodium, potassium, cesium, calcium, barium, silver and gold. A plurality of cathode materials may be used by stacking or by mixing them together.

The method of forming the cathode layer is suitably selected according to the nature of the material therein. Typically, a dry process (especially vapor deposition) is used.

### [Formation of Carrier Blocking Layer]

Where necessary, a carrier blocking layer may be provided between any of the layers for such purposes as to control the rectifiability of the photoelectric current.

Examples of carrier blocking layer-forming materials include titanium oxide and zinc oxide.

The method of forming a carrier blocking layer is suitably selected according to the nature of the material therein. A vapor deposition process is typically employed in cases where a sublimable compound is used. Spin coating or slit coating is typically employed in cases where a varnish in which the material has been dissolved is used.

To prevent device deterioration from exposure to the atmosphere, the optical sensor manufactured in the manner illustrated above can be placed once again in a glovebox, sealed in a nitrogen or other inert gas atmosphere and, in the sealed state, made to function as an optical sensor or measurement of the device characteristics carried out.

The sealing method may be, for example, a method in which a concave glass substrate with a UV-curable resin attached to the edges is bonded to the film-forming side of the organic thin-film solar cell and the resin is cured by UV irradiation, all within an inert gas atmosphere, or a method in which film sealing is carried out in a vacuum by a technique such as sputtering.

In “Formation of Photoelectric Conversion Layer” above, a perovskite solar cell can be produced by using a perovskite semiconductor compound-containing active layer composition in the photoelectric conversion layer.

“Perovskite semiconductor compound” refers to a semiconductor compound having a perovskite structure. Known compounds may be used without particular limitation as the perovskite semiconductor compound. Examples include compounds of the general formula A⁺M²⁺X⁻₃ and compounds of the general formula A⁺₂M²⁺X⁻₄. Here, A⁺ represents a monovalent cation, M²⁺ represents a divalent cation and X⁺ represents a monovalent anion.

Examples of the monovalent cation A⁺ include cations containing Group 1 elements and Groups 13 to 16 elements of the periodic table. Of these, cesium ions, rubidium ions, ammonium ions which may have substituents and phosphonium ions which may have substituents are preferred.

Examples of ammonium ions which may be substituents include primary ammonium ions and secondary ammonium ions. The substituent, although not particularly limited, is preferably an alkylammonium ion or an arylammonium ion. In particular, to avoid steric hindrance, monoalkylammonium ions that assume a three-dimensional crystal structure are more preferred. The number of carbon atoms on the alkyl group included in the above alkylammonium ions is preferably from 1 to 30, more preferably from 1 to 20, and even more preferably from 1 to 10. The number of carbon atoms in the aryl group included in the above arylammonium ions is preferably from 6 to 30, more preferably from 6 to 20, and even more preferably from 6 to 12.

Specific examples of the monovalent cation A⁺ include the methylammonium ion (MA), ethylammonium ion, isopropylammonium ion, n-propylammonium ion, isobutylammonium ion, n-butylammonium ion, t-butylammonium ion, dimethylammonium ion, diethylammonium ion, phenylammonium ion, benzylammonium ion, phenethylammonium ion, guanidinium ion, formamidinium ion (FA), acetamidinium ion and imidazolium ion. The cation A⁺ may be of one type used alone, or two or more types may be used in combination.

The divalent cation M²⁺ is preferably a divalent metal cation or semi-metal cation, and is more preferably a cation of a Group 14 element of the periodic table. Specific examples of the divalent cation M²⁺ include the lead cation (Pb²⁺), tin cation (Sn²⁺) and germanium cation (Ge²⁺). In this invention, from the standpoint of obtaining a photoelectric conversion device of excellent stability, it is preferable to include a lead cation. The above cation M²⁺ may be of one type used alone or two or more types may be used in combination.

Examples of the monovalent anion X⁻ include halide ions, the acetate ion, the nitrate ion, the acetylacetonate ion, the thiocyanate ion and the 2,4-pentanedionato ion. A halide ion is preferred. The anion X⁻ may be of one type used alone or two or more types may be used in combination.

Examples of halide ions include the chloride ion, the bromide ion and the iodide ion.

The perovskite semiconductor compound is preferably, for example, an organic-inorganic perovskite semiconductor compound, and more preferably a halogenated organic-inorganic perovskite semiconductor compound. Specific examples of perovskite semiconductor compounds include MAPbI₃, MAPbBr₃, MAPbCl₃, MASnI₃, MASnBr₃, MASnCl₃, MAPbl₍₃₋ₓ₎Brₓ, MAPbBr₍₃₋ₓ₎Clₓ, MAPb_{(1-y)}Sn_{y}I₃, MAPb_{(1-y)}Sn_{y}Br₃, MAPb(_{(1-y)}Sn_{y}Cl₃, MAPb_{(1-y)}Sn_{y}I₍₃₋ₓ₎Clₓ, MAPb_{(1-y)}Sn_{y}I₍₃₋ₓ₎Brₓ, MAPb_{(1-y)}Sn_{y}Br₍₃₋ₓ₎Clₓ, FAPbl₃, FAPbBr₃, FAPbI₍₃₋ₓ₎Brₓ, FA₍₁₋ᵥ₎MAᵥPbI₍₃₋ₓ₎Brₓ and Cs_{(1-w-v)}FA_{w}MAᵥPbI₍₃₋ₓ₎Brₓ. Here, x represents any number from 0 to 3, and y represents any number from 0 to 1.

From the standpoint of enhancing the photoelectric conversion efficiency, it is desirable to use a semiconductor compound having an energy band gap of from 1.0 to 3.5 eV as the perovskite semiconductor compound.

Two or more perovskite semiconductor compounds may be included in the active layer. For example, two or more perovskite semiconductor compounds in which at least one of the above A⁺, M²⁺ and X⁻ differs may be included in the active layer.

To obtain good photoelectric conversion properties, the perovskite semiconductor compound content in the active layer is preferably 50 wt % or more, more preferably 70 wt % or more, and even more preferably 80 wt % or more. There is no particular upper limit, the content being typically up to 100 wt %.

The active layer may optionally include other additives. Examples include surfactants, charge-imparting agents, 1,8-diiodooctane and N-cyclohexyl-2-pyrrolidone.

To obtain a good power conversion efficiency (PCE), the content of these additives in the active layer is preferably 50 wt % or less, more preferably 30 wt % or less, and even more preferably 20 wt % or less. There is no particular lower limit, the content being typically 0 wt % or more.

As for the method of forming the active layer, here too, the optimal method is selected from among the various above-described wet processes while taking into account, for example, the viscosity and surface tension of the composition and the desired thickness of the thin film.

### EXAMPLES

The invention is described below in further detail based on Examples, although the invention is not limited by these Examples.

### <Synthesis of Polyimide Precursor>

Abbreviations used in preparation of the polyimide precursors below are as follows.

### (Tetracarboxylic Dianhydrides)

BODA: Bicyclo[3,3,0]octane-2,4,6,8-tetracarboxylic dianhydride
BPDA: 4,4′-Biphthalic dianhydride
CBDA: 1,2,3,4-Cyclobutanetetracarboxylic dianhydride
TCA: 2,3,5-Tricarboxycyclopentylacetic dianhydride
CBDE: The compound of the following structural formula

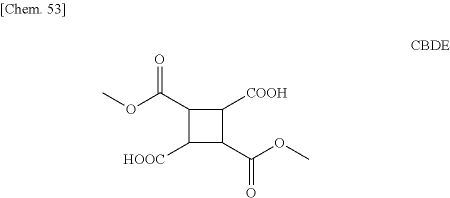

### (Diamines)

The diamine compounds of formulas DA-1 and DA-2 below.

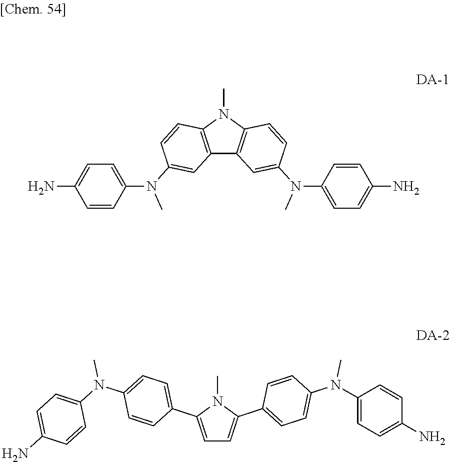 [SMILES: CN(c1ccc(N)cc1)c1ccc2c(c1)c1cc(N(C)c3ccc(N)cc3)ccc1n2C ; CN(c1ccc(N)cc1)c1ccc(-c2ccc(-c3ccc(N(C)c4ccc(N)cc4)cc3)n2C)cc1]

### <Solvents>

NMP: N-Methyl-2-pyrrolidone
NEP: N-Ethyl-2-pyrrolidone
BCS: Butyl cellosolve

### <Condensing Agent>

DMT-MM: Dimethoxy-1,3,5-triazinylmethyl morpholinium

### <Additive>

3API: 1-(3-Aminopropyl)imidazole

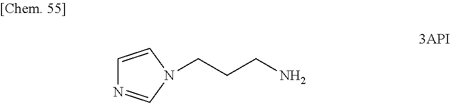

### <Conductivity Enhancer>

SELFTRON S: 2.0 wt % Aqueous solution of polythiophene system, available from Tosoh Corporation

The conditions under which the molecular weight of the polyimide precursor was measured were as follows.
Apparatus: Room-temperature gel permeation chromatography (GPC) unit (SSC-7200), from Senshu Scientific Co., Ltd.
Columns: Shodex columns (KD-803, KD-805)
Column temperature: 50° C.
Eluant: N,N′-Dimethylformamide
   (containing as additives: 30 mmol/L of lithium bromide hydrate (LiBr·H₂O), 30 mmol/L of anhydrous phosphoric acid, and 10 ml/L of tetrahydrofuran (THF))
Flow rate: 1.0 ml/min
Standard Samples for Preparing Working Curve:
   TSK Standard Polyethylene Oxides from Tosoh Corporation (molecular weights: approx. 9,000,000, 150,000, 100,000 and 30,000) and polyethylene glycols from Polymer Laboratory (molecular weights: approx. 12,000, 4,000 and 1,000).

The conditions under which the viscosity of the polyimide precursor solution was measured were as follows.

Measurement was carried out using an E type viscometer (TVE-22H, from Toki Sangyo Co., Ltd.), a sample amount of 1.1 mL and cone rotor TE-1 (1° 34′, R24) at a temperature of 25° C.

### Synthesis Example 1

BPDA (2.74 g, 9.3 mmol) and DA-1 (4.21 g, 10 mmol) were dissolved in NMP (79.95 g) and reacted for 5 hours at 25° C., giving Polyamic Acid Solution (A).

The viscosity of the resulting polyamic acid solution was 35 mPa·s. The number-average molecular weight of this polyamic acid was 7,300 and the weight-average molecular weight was 33,200.

### Synthesis Example 2

BODA (3.36 g, 13.4 mmol) and DA-2 (6.63 g, 14 mmol) were dissolved in NMP (89.94 g) and reacted for 20 hours at 40° C., giving Polyamic Acid Solution (B).

The viscosity of the resulting polyamic acid solution was 72 mPa·s. The number-average molecular weight of this polyamic acid was 9,500 and the weight-average molecular weight was 42,300.

### Synthesis Example 3

BODA (3.36 g, 13.4 mmol) and DA-1 (6.63 g, 14 mmol) were dissolved in NEP (89.94 g) and reacted for 20 hours at 40° C., giving Polyamic Acid Solution (D).

The viscosity of the resulting polyamic acid solution was 90 mPa·s. The number-average molecular weight of this polyamic acid was 8,400 and the weight-average molecular weight was 22,100.

### Synthesis Example 4

BODA (3.53 g, 14.1 mmol) and DA-2 (6.32 g, 15 mmol) were dissolved in NEP (88.66 g) and reacted for 20 hours at 40° C., giving Polyamic acid solution (E).

The viscosity of the resulting polyamic acid solution was 101 mPa·s. The number-average molecular weight of this polyamic acid was 10,100 and the weight-average molecular weight was 52,200.

### Synthesis Example 5

CBDA (0.94 g, 4.8 mmol) and DA-1 (2.37 g, 5 mmol) were dissolved in NEP (29.78 g) and reacted for 5 hours at 5° C., giving Polyamic Acid Solution (F).

The viscosity of the resulting polyamic acid solution was 328 mPa·s. The number-average molecular weight of this polyamic acid was 13,500 and the weight-average molecular weight was 67,700.

### Synthesis Example 6

CBDA (0.94 g, 4.8 mmol) and DA-2 (2.11 g, 5 mmol) were dissolved in NEP (27.44 g) and reacted for 5 hours at 5° C., giving Polyamic Acid Solution (G).

The viscosity of the resulting polyamic acid solution was 180 mPa·s. The number-average molecular weight of this polyamic acid was 11,100 and the weight-average molecular weight was 38,000.

### Synthesis Example 7

TCA (3.01 g, 13.4 mmol) and DA-1 (6.63 g, 14 mmol) were dissolved in NEP (86.79 g) and reacted for 20 hours at 40° C., giving Polyamic Acid Solution (H).

The viscosity of the resulting polyamic acid solution was 193 mPa·s. The number-average molecular weight of this polyamic acid was 10,500 and the weight-average molecular weight was 43,900.

### Synthesis Example 8

TCA (3.01 g, 13.4 mmol) and DA-2 (5.90 g, 14 mmol) were dissolved in NMP (80.23 g) and reacted for 20 hours at 40° C., giving Polyamic Acid Solution (I).

The viscosity of the resulting polyamic acid solution was 164 mPa·s. The number-average molecular weight of this polyamic acid was 11,800 and the weight-average molecular weight was 67,900.

### Synthesis Example 9

CBDE (2.47 g. 9.5 mmol) and DA-1 (4.74 g, 10 mmol) were dissolved in NMP (84.1 g) and triethylamine (0.51 g, 5 mmol) was added as a catalyst, following which the condensing agent DMT-MM (8.3 g, 30 mmol) was added under ice cooling and the reaction was carried out for 20 hours, giving a polyamic acid ester solution (PAE-1) having a viscosity of 113 mPa·s. This polyamic acid ester solution was purified by re-precipitation in methanol, giving a polyamic acid ester powder (PAE-P1).

The number-average molecular weight of this polyamic acid ester was 14,100 and the weight-average molecular weight was 45,000.

### Synthesis Example 10

CBDE (2.45 g. 9.4 mmol) and DA-2 (4.22 g, 10 mmol) were dissolved in NMP (76.6 g) and triethylamine (0.51 g, 5 mmol) was added as a catalyst, following which the condensing agent DMT-MM (8.30 g, 30 mmol) was added under ice cooling and the reaction was carried out for 20 hours, giving a polyamic acid ester solution (PAE-2) having a viscosity of 32 mPa·s. This polyamic acid ester solution was purified by re-precipitation in methanol, giving a polyamic acid ester powder (PAE-P2).

The number-average molecular weight of this polyamic acid ester was 10,300 and the weight-average molecular weight was 31,100.

### <Preparation of Charge Transporting Compositions>

### Example 1-1

NMP (8.10 g) and BCS (3.9 g) were added to Polyamic Acid Solution (A) (7.50 g) obtained in Synthesis Example 1, following which 3API (8 wt % aqueous solution, 5.29 g) and water (5.21 g) were slowly added as additives to this solution, and the mixture was stirred for 1 hour at 25° C. The mixture was then filtered with a syringe filter having a pore size of 0.45 μm, giving Charge Transporting Composition (A1) having a polyamic acid concentration of 2.0 wt %.

### Example 1-2

SELFTRON S (2.0 wt % aqueous solution, from Tosoh Corporation) was added in an amount of 1.0 g to 9.0 g of Charge Transporting Composition (A1) obtained in Example 1, and the mixture was stirred for 1 hour at 25° C. The mixture was then filtered with a syringe filter having a pore size of 0.45 μm, giving Charge Transporting Composition (A2).

### Example 1-3

Aside from changing Polyamic Acid Solution (A) to Polyamic Acid Solution (B), the same operations were carried out as in Example 1, giving Charge Transporting Composition (B1).

### Example 1-4

Aside from changing Charge Transporting Composition (A1) to Charge Transporting Composition (B1), the same operations were carried out as in Example 2, giving Charge Transporting Composition (B2).

### Comparative Example 1-1

The polythiophene aqueous dispersion PET:PSS (CLEVIOS HTL Solar, from Heraeus K.K.) was used directly without modification as a Comparative Example of the charge transporting composition.

The charge transporting compositions obtained as described above are shown collectively in Table 1.

TABLE 1

| | Charge | Polyamic | |
|---|---|---|---|
| | transporting | acid | Amount of conductivity |
| | composition | solution | enhancer |
| Example 1-1 | A1 | A | — |
| Example 1-2 | A2 | A | SELFTRON S, 10 wt % |
| Example 1-3 | B1 | B | — |
| Example 1-4 | B2 | B | SELFTRON S, 10 wt % |
| Comparative | PEDOT:PSS | — | — |
| Example 1-1 | | | |

### Example 1-5

NEP (6.0 g) and BCS (2.0 g) were added to 2.0 g of Polyamic Acid Solution (D) obtained in Synthesis Example 3, and the mixture was stirred for 1 hour at 25° C. The mixture was then filtered with a syringe filter having a pore size of 0.45 μm, giving Charge Transporting Composition (D1) having a polyamic acid concentration of 2.0 wt %.

### Examples 1-6 to 1-10

Aside from changing Polyamic Acid Solution (D) to the respective polyamic acid solutions obtained in Synthesis Example 4 to 8, the same operations were carried out as in Example 1-5, giving Charge Transporting Compositions (E1) to (I1) having polyamic acid concentrations of 2.0 wt %.

### Example 1-11

The polyamic acid ester powder (PAE-P1, 0.2 g) obtained in Synthesis Example 9 was re-precipitated in 7.8 g of NEP at 25° C., diluted with 2.0 g of BCS and stirred for 1 hour at 25° C., thereby preparing Charge Transporting Composition (J1) having a polyamic acid ester concentration of 2.0 wt %.

### Example 1-12

Aside from changing the polyamic acid ester powder of Example 1-11 to (PAE-P2), Charge Transporting Composition (K1) was prepared in the same way as in Example 1-11.

The charge transporting compositions obtained as described above are shown collectively in Table 2.

TABLE 2

| | | Charge transporting |
|---|---|---|
| | Polyimide precursor | composition |
| Example 1-5 | Polyamic Acid Solution (D) | D1 |
| Example 1-6 | Polyamic Acid Solution (E) | E1 |
| Example 1-7 | Polyamic Acid Solution (F) | F1 |
| Example 1-8 | Polyamic Acid Solution (G) | G1 |
| Example 1-9 | Polyamic Acid Solution (H) | H1 |
| Example 1-10 | Polyamic Acid Solution (I) | I1 |
| Example 1-11 | Polyamic Acid Ester (PAE-P1) | J1 |
| Example 1-12 | Polyamic Acid Ester (PAE-P2) | K1 |

### <Fabrication of Single Layer Devices>

### Example 2-1

Single layer devices having a hole collecting layer were fabricated as described below for the purpose of evaluating the dark current properties and carrier mobility of the hole collecting layer.

A 25 mm×25 mm glass substrate was furnished which had a transparent ITO conductive film patterned thereon as 5 mm×25 mm stripes on top of which was patterned in turn a polyimide insulating film such as to form ITO pixel surface areas of 2 mm×2 mm.

Hole Collecting Layer Composition A1 prepared in Example 1-1 was applied by spin coating onto this glass substrate in an open-air atmosphere, dried for 2 minutes on a 100° C. hot plate and then baked for 10 minutes on a 200° C. hot plate, forming a hole collecting layer having a film thickness of 30 nm.

Next, the substrate on which the hole collecting layer had been formed was placed in a vacuum deposition system, the interior of the system was evacuated to 1×10⁻³ Pa or less, and an aluminum layer was vapor deposited to a thickness of 80 nm by resistance heating, thereby fabricating a single layer device (A1-1) in which the surface area of the region where the ITO layer and the aluminum layer intersect was 2 mm×2 mm.

### Example 2-2

Aside from changing Charge Transporting Composition (A1) to Charge Transporting Composition (A2), a single layer device (A2-1) was fabricated in the same way as in Example 2-1.

### Example 2-3

Aside from changing Charge Transporting Composition (A1) to Charge Transporting Composition (B2), a single layer device (B2-1) was fabricated in the same way as in Example 3-1.

### Comparative Example 2-1

Aside from changing Charge Transporting Composition (A1) to Charge Transporting Composition (PEDOT:PSS) and eliminating the bake at 200° C., a single layer device (C1-1) was fabricated in the same way as in Example 3-1.

### <Measurement of Current-Voltage Characteristics, Carrier Mobility and Conductivity of Hole Collecting Layer>

The voltage-current characteristic curve (I-V curve) for the single layer device fabricated in Example 2-1 was measured. A semiconductor parameter analyzer was used to measure the I-V curve. Measurement was carried with the device in a light-shielded state within a manual desktop prober (from Apollo Wave Inc.).

The current value at 1 V was calculated from the resulting I-V curve as the dark current value, and the value obtained by dividing this dark current value by 4 mm² was calculated as the current density (mA/cm²).

The carrier mobility and conductivity were calculated from this current density value using the Mott-Gurney formula in the space charge-limited current (computed with the electric constant set to 8.85×10⁻¹² F/m and the relative permittivity of the hole collecting layer set to 3).

The dark current properties, carrier mobility and conductivity were calculated in the same way for the single layer devices fabricated in Examples 2-2 and 2-3 and Comparative Example 2-1.

These results are presented in Table 3.

TABLE 3

| | Example | Example | Example | Comparative |
|---|---|---|---|---|
| | 2-1 | 2-2 | 2-3 | Example 2-1 |
| Charge transporting | A1 | A2 | B2 | PEDOT:PSS |
| composition | | | | |
| Current | 31.3 | 48.8 | 9.8 | 581 |
| density (mA/cm²) | | | | |
| Carrier | 2.8 × 10⁻⁶ | 4.4 × 10⁻⁶ | 8.9 × 10⁻⁷ | 5.3 × 10⁻⁵ |
| mobility (cm²/Vs) | | | | |
| Conductivity (S/cm) | 9.4 × 10⁻⁸ | 1.5 × 10⁻⁷ | 3.9 × 10⁻⁸ | 1.7 × 10⁻⁶ |

When I-V curve measurements were carried out on the single layer devices, the order of the current density, the carrier mobility and the conductivity for the respective devices was found to correspond with the order of the dark current properties in optical sensors. In the device using PEDOT-PSS in Comparative Example 2-1, the I-V curve had a linear shape, which is indicative of ohmic contact. Hence, it appears that Comparative Example 2-1 is not a space charge-limited current, indicating that the actual carrier mobility and conductivity are even higher values.

From these results, holding down the carrier mobility and conductivity of the hole transporting material to low values is effective for lowering the dark current characteristics of the optical sensor. The polyimide material of the invention appears to satisfy these characteristics.

### <Fabrication of Optical Sensors>

The equipment used in optical sensor fabrication and evaluation was as follows.
(1) Glovebox: VAC glovebox system, from Yamahachi &Co., Ltd.
(2) Vapor Deposition System: A vacuum deposition system from Aoyama Engineering KK
(3) Solar Simulator: OTENTOSUN-III, AM 1.5 G filter; radiation intensity, 100 mW/cm²; from Bunkoukeiki Co., Ltd.
(4) Source Measurement Unit: 2612A, from Keithley Instruments KK
(5) Semiconductor Parameter Analyzer:
   4156C, from Keysite Technologies, Inc.

### <Fabrication of Optical Sensors>

### Example 3-1

A 25 mm×25 mm glass substrate patterned thereon with, as the cathode, a transparent ITO conductive layer in the form of 10 mm×25 mm stripes was UV/ozone treated for 15 minutes. Hole Collecting Layer Composition A1 prepared in Example 1-1 was applied onto this substrate by spin coating in an open-air atmosphere and dried for 2 minutes on a 100° C. hot plate, then baked for 10 minutes on a 200° C. hot plate, thereby forming a hole collecting layer. The hole collecting layer had a film thickness of about 30 nm.

Next, within a glovebox purged with nitrogen gas, PV-ALT-D1A1 (from Raynergy tek) was spin-coated onto the hole transporting layer, thereby forming an active layer. The active layer had a film thickness of about 100 nm.

The stacked substrate was then set within a vacuum vapor deposition system, the interior of the system was evacuated to a vacuum of 1×10⁻³ Pa or less, and LiQ was deposited as the electron collecting layer to a thickness of 1 nm. Last of all, a silver layer was vapor deposited to a thickness of 100 nm as the anode, thereby producing Optical Sensor (A1-2) in which the surface area of regions where the striped ITO layer and the silver layer intersect is 10 mm×10 mm.

### Example 3-2

Aside from changing Charge Transporting Composition (A1) to Charge Transporting Composition (A2), Optical Sensor (A2-2) was fabricated by following the same procedure as in Example 3-1.

### Example 3-3

Aside from changing Charge Transporting Composition (A1) to Charge Transporting Composition (B2), Optical Sensor (B2-2) was fabricated by following the same procedure as in Example 3-1.

### Comparative Example 3-1

Aside from changing Charge Transporting Composition (A1) to Charge Transporting Composition (PEDOT:PSS) and eliminating the bake at 200° C., Optical Sensor (C1-2) was fabricated by following the same procedure as in Example 3-1.

### <Dark Current Properties of Optical Sensor>

The I-V curve for the optical sensor fabricated in Example 3-1 was measured. A semiconductor parameter analyzer was used to measure the I-V curve. Measurement was carried out with the device in a light-shielded state within a manual desktop prober (from Apollo Wave Inc.).

The current value at 1 V was calculated as the dark current value from the resulting I-V curve.

The dark current properties of the optical sensors fabricated in Examples 3-2 and 3-3 and Comparative Example 3-1 were computed in the same way.

The results are presented in Table 4.

TABLE 4

| | Example | Example | Example | Comparative |
|---|---|---|---|---|
| | 3-1 | 3-2 | 3-3 | Example 3-1 |
| Charge transporting | A1 | A2 | B2 | PEDOT:PSS |
| composition | | | | |
| Dark current value | 14.84 nA | 217.86 nA | 2.82 nA | 2.25 μA |

The results in Table 4 confirmed that optical sensors which use the polyimide material of the invention have greatly improved dark current properties compared with the optical sensor in the Comparative Example.

### <Fabrication of Organic Thin-Film Solar Cells>

### Example 4-1

Aside from changing the active layer to PV-F1062 (Merck KGaA), a normal stack-type solar cell (A2-3) was fabricated by carrying out the same procedure as in Example 3-1.

### Example 4-2

Aside from changing Charge Transporting Composition (A2) to Charge Transporting Composition (B2), a normal stack-type solar cell (B2-3) was fabricated by carrying out the same procedure as in Example 4-1.

### Comparative Example 4-1

Aside from changing Charge Transporting Composition (B2) to Charge Transporting Composition (PEDOT-PSS), a normal stack-type solar cell (C1-3) was fabricated by carrying out the same procedure as in Example 4-1.

The power generation performances of the normal stack-type solar cells fabricated as described above were evaluated using a solar simulator in which the amount of light was adjusted to 100 mW/cm². The results are shown in Table 5.

The power conversion efficiency PCE (%) was computed as follows. In this formula, units are given in brackets.

$$PCE [ \% ] = Jsc [ mA / {cm}^{2} ] \times Voc [ V ] \times FF \div incident light intensity ( 100 [ mW / {cm}^{2} ] ) \times 100$$

wherein
Jsc [mA/cm²] is the short-circuit current density
Voc [V] is the open-circuit voltage
FF is the fill factor

TABLE 5

| | Example | Example | Comparative |
|---|---|---|---|
| | 4-1 | 3-2 | Example 4-1 |
| Charge transporting composition | A2 | B2 | PEDOT:PSS |
| Jsc [mA/cm²] | 4.82 | 10.42 | 11.61 |
| Voc [V] | 0.34 | 0.86 | 0.66 |
| FF | 0.21 | 0.49 | 0.41 |
| PCE [%] | 0.35 | 4.23 | 3.10 |

As a result of the evaluations, it is apparent that the polyimide material-containing charge transporting compositions of the invention may be employed also in solar cells.

### <Fabrication of Perovskite Solar Cells>

### Example 5-1

First, 504 mg of formamidium iodide, 65 mg of methyl ammonium bromide, 1,487 mg of lead(II) iodide and 214 mg of lead(II) bromide were weighed out into a 5 mL vial within a nitrogen-filled glovebox. Next, 2,346 μL of dimethylsulfoxide (DMSO) and 586 μL of N,N-dimethylformamide were added and the vial contents were stirred for 15 minutes under heating at 70° C., completely dissolving each of the weighed out substances. To this was added 134 μL of a solution of cesium iodide dissolved in DMSO to a concentration of 1.5 mol/L, thereby preparing a perovskite precursor solution (Pvsk) containing a perovskite semiconductor compound (Cs_{0.05}(FA_{0.83}MA_{0.17})_{0.95}Pb(I_{0.83}Br_{0.17})₃).

Next, Electron Collecting Layer Composition ETL1 was prepared by adding 150 mg of [6,6]-phenyl-C₆₁-acetic acid methyl ester (Frontier Carbon Corporation) and 5,000 μL of chlorobenzene to a 3 mL vial and stirring for 15 minutes.

In addition, Electron Collecting Layer Composition ETL2 was prepared by adding 2.5 mg of bathocuproine (Tokyo Chemical Industry Co., Ltd.) and 5,000 μL of 2-propanol (Kanto Chemical Co., Inc.) to a 3 mL vial and stirring for one hour.

A 25 mm×25 mm glass substrate patterned thereon with, as the cathode, a transparent ITO conductive layer in the form of 10 mm×25 mm stripes was UV/ozone treated for 15 minutes. Charge Transporting Composition (D1) prepared in Example 1-5 was added dropwise and spin-coated onto this substrate and then heated for 10 minutes at 100° C. on a hot plate, forming a hole collecting layer. The hole collecting layer had a film thickness of about 30 nm.

This substrate with a hole collecting layer thereon was transferred to a glovebox and the perovskite precursor solution Pvsk was added dropwise and spin-coated onto the hole collecting layer. Chlorobenzene was added dropwise to the substrate during spin coating. The resulting substrate was heated for 30 minutes at 105° C. on a hot plate, thereby forming an active layer composed of the perovskite semiconductor compound. The active layer had a film thickness of about 400 nm.

Electron Collecting Layer Composition ETL1 was spin-coated onto the active layer thus formed and then heated for 10 minutes at 100° C. on a hot plate. In addition, Electron Collecting Layer Composition ETL2 was spin-coated onto this substrate, thereby forming an electron collecting layer. The layer obtained from Electron Collecting Layer Composition ETL1 had a film thickness of about 30 nm, and the layer obtained from Electron Collecting Layer Composition ETL2 had a film thickness of about 8 nm.

Lastly, the stacked substrate was set within a vacuum vapor deposition system, the interior of the system was evacuated to a vacuum of 1×10⁻³ Pa or less and a silver layer was vapor deposited to a thickness of 100 nm as the anode, thereby producing an inverted perovskite solar cell (D1-1) in which the surface area of regions where the striped ITO layer and the silver layer intersect was 8 mm×3 mm.

### Examples 5-2 to 5-8, Comparative Example 5-1

Aside from changing Charge Transporting Composition D1 to the respective Charge Transporting Compositions E1 to K1 and PEDOT:PSS, inverted perovskite solar cells (E1-1 to K1-1) were fabricated in the same way as in Example 5-1.

The power generation performances of the inverted perovskite solar cells fabricated as described above were evaluated in the same way as in Example 4-1. The results are presented in Table 6.

TABLE 6

| | | Power generation performance | | | |
|---|---|---|---|---|---|
| | Charge | of perovskite solar cell | | | |
| | transporting | Jsc | Voc | | PCE |
| | composition | [mA/cm²] | [V] | FF | [%] |
| Example 5-1 | D1 | 18.5 | 0.95 | 0.68 | 11.7 |
| Example 5-2 | E1 | 15.3 | 0.98 | 0.55 | 8.2 |
| Example 5-3 | F1 | 17.2 | 0.84 | 0.59 | 8.6 |
| Example 5-4 | G1 | 17.9 | 0.93 | 0.56 | 9.4 |
| Example 5-5 | H1 | 19.1 | 0.95 | 0.66 | 11.9 |
| Example 5-6 | I1 | 16.4 | 0.87 | 0.65 | 9.2 |
| Example 5-7 | J1 | 19.7 | 0.98 | 0.54 | 10.4 |
| Example 5-8 | KI | 16.4 | 0.85 | 0.64 | 8.9 |
| Comparative | PEDOT:PSS | 14.5 | 0.80 | 0.57 | 6.6 |
| Example 5-1 | | | | | |

As a result of the evaluations, it is apparent that the polyimide material-containing charge transporting compositions of the invention may be employed also in perovskite solar cells.

1. A charge transporting composition for forming a charge transporting thin film in an organic photoelectric conversion device,
which composition comprises a charge transporting substance and an organic solvent,
wherein the charge transporting substance includes at least one type of polyimide polymer selected from the group consisting of polyimide precursors obtained from a diamine component having a structure of formula (1) or (2) below 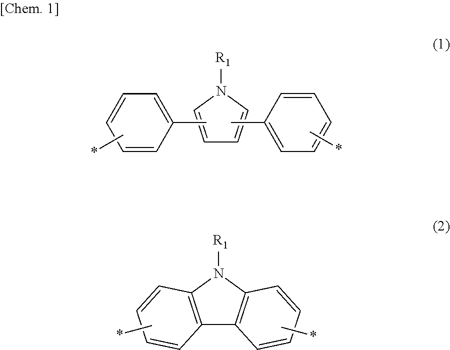
(wherein R¹ is a hydrogen atom or a monovalent organic group, _{*} represents a site that bonds with another group, and any hydrogen atom forming the benzene ring may be substituted with a monovalent organic group) and a tetracarboxylic acid component, esters of the polyimide precursor, and imidization products of the polyimide precursor.

2. The charge transporting composition of claim 1, wherein R¹ is a hydrogen atom, an alkyl group of 1 to 5 carbon atoms, a fluoroalkyl group of 1 to 5 carbon atoms or a tert-butoxycarbonyl group.

3. The charge transporting composition of claim 1, further comprising a charge transporting substance other than the polyimide polymer.

4. The charge transporting composition of claim 3, wherein the other charge transporting substance is of at least one type selected from the group consisting of polythiophene derivatives and polyaniline derivatives.

5. The charge transporting composition of claim 4, wherein the other charge transporting substance is of at least one type selected from the group consisting of polythiophene derivatives containing recurring units of formula (3) below and polyaniline derivatives containing recurring units of formula (4) below 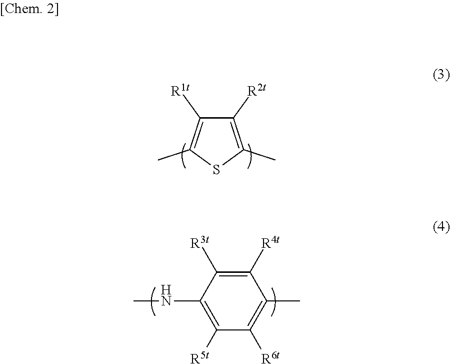
(wherein R^{1t} and R^{2t} are each independently a hydrogen atom, an alkyl group of 1 to 40 carbon atoms, a fluoroalkyl group of 1 to 40 carbon atoms, an alkoxy group of 1 to 40 carbon atoms, a fluoroalkoxy group of 1 to 40 carbon atoms, an aryloxy group of 6 to 20 carbon atoms, —O—[Z—O]ₚ—R^{e}, a sulfonic acid group, a sulfonate group or a sulfonic ester group, or R^{1t} and R^{2t} are bonded to each other, forming —O—Y—O— in which Y is an alkylene group of 1 to 40 carbon atoms that may include an ether bond and may be substituted with a sulfonic group, a sulfonate group or a sulfonic ester group; Z is an alkylene group of 1 to 40 carbon atoms which may be substituted with a halogen atom, p is an integer of 1 or more, and R^{e} is a hydrogen atom, an alkyl group of 1 to 40 carbon atoms, a fluoroalkyl group of 1 to 40 carbon atoms or an aryl group of 6 to 20 carbon atoms; and
R^{3t} to R^{6t} are each independently a hydrogen atom, an alkyl group of 1 to 40 carbon atoms, a fluoroalkyl group of 1 to 40 carbon atoms, an alkoxy group of 1 to 40 carbon atoms, a fluoroalkoxy group of 1 to 40 carbon atoms, a hydroxyl group, a carboxyl group, a sulfonic group, a sulfonate group or a sulfonic ester group).

6. The charge transporting composition of claim 1 for use as a hole collecting layer in an organic photoelectric conversion device.

7. The charge transporting composition of claim 6, wherein the organic photoelectric conversion device is an organic thin-film solar cell, a perovskite solar cell, a dye-sensitized solar cell or an optical sensor.

8. A charge transporting thin film obtained from the charge transporting composition of claim 1.

9. The charge transporting thin film of claim 8, which charge transporting thin film is a hole collecting layer in an organic photoelectric conversion device.

10. An organic photoelectric conversion device comprising the charge transporting thin film of claim 8.

11. The organic photoelectric conversion device of claim 10, which organic photoelectric conversion device is an organic thin film solar cell, a perovskite solar cell, a dye-sensitized solar cell or an optical sensor.
